(19) United States
(12) Patent Application Publication
(10) Pub. No.: US 2025/0151631 A1
(43) Pub. Date: May 8, 2025

(54) BIDIRECTIONAL LASER TUNING OF JOSEPHSON JUNCTIONS

(71) Applicant: International Business Machines Corporation, Armonk, NY (US)

(72) Inventors: Eric Zhang, Sleepy Hollow, NY (US); James B Hannon, Mahopac, NY (US); Jared Barney Hertzberg, Yorktown Heights, NY (US); Russell A. Budd, North Salem, NY (US); Sami Rosenblatt, White Plains, NY (US); Jason S. Orcutt, Katonah, NY (US)

(21) Appl. No.: 18/501,196

(22) Filed: Nov. 3, 2023

(51) Int. Cl. H10N 60/12; H10N 60/01

(52) U.S. Cl. CPC H10N 60/12; H10N 60/0884; H10N 60/0912

(57) ABSTRACT

A calibration process comprises performing laser annealing calibration operations on first Josephson junctions using different combinations of at least laser power settings and anneal times, determining junction resistance shifts of the first Josephson junctions as a result of the laser annealing calibration operations, and utilizing the determined junction resistance shifts of the first Josephson junctions to determine calibration data for configuring laser annealing operations for bidirectional laser tuning of second Josephson junctions corresponding to the first Josephson junctions.

### BACKGROUND

This disclosure relates generally to techniques for tuning Josephson junction devices and, in particular, laser annealing techniques for tuning junction resistances of Josephson junctions. A quantum computing system can be implemented using superconducting circuit quantum electrodynamics (cQED) architectures that are constructed using quantum circuit components such as, e.g., superconducting quantum bits (e.g., fixed-frequency transmon quantum bits), superconducting quantum interference devices (SQUIDs), and other types of superconducting devices which comprise Josephson junction devices. In particular, superconducting quantum bits (qubits) are electronic circuits which are implemented using components such as superconducting tunnel junction devices (e.g., Josephson junctions), inductors, and/or capacitors, etc., and which behave as quantum mechanical anharmonic (non-linear) oscillators with quantized states, when cooled to cryogenic temperatures. A fixed-frequency qubit, such as a transmon qubit, has a transition frequency (denoted f₀₁) which corresponds to an energy difference between a ground state |0 [symbol] and a first excited state |1 [symbol] of the qubit. It is known that the transition frequency f₀₁ of a qubit can be estimated from the resistance (denoted R_{J}) of the Josephson junction of the qubit.

A solid-state quantum processor can include multiple superconducting qubits that are arranged in a given lattice structure (e.g., square lattice, heavy hexagonal lattice) to enable quantum information processing through quantum gate operations (e.g., single-qubit gate operations and multi-qubit gate operations) in which quantum information is generated and encoded in computational basis states (e.g., |0 [symbol] and |1 [symbol] ) of single qubits, superpositions of the computational basis states of single qubits, and/or entangled states of multiple qubits. Continuing technological advances in quantum processor design are enabling the rapid scaling of both the physical number of superconducting qubits and the computational capabilities of quantum processors. Indeed, while current state-of-the art quantum processors have greater than 50 qubits, it is anticipated that future quantum processors will have a much larger number of qubits, e.g., on the order of hundreds or thousands of qubits, or more.

Scaling the number of qubits (e.g., fixed frequency transmon qubits) in a qubit lattice, while maintaining high-fidelity quantum gate operations, remains a key challenge for quantum computing. For example, as superconducting quantum processors scale to larger numbers of qubits, frequency crowding within a qubit lattice becomes increasingly problematic since the transition frequencies of the qubits need to be precisely controlled to minimize gate errors that can arise from lattice frequency collisions (e.g., improper detuning between superconducting qubits can reduce the fidelity of multi-qubit gate entanglement operations). Due to semiconductor processing variabilities, however, the transition frequencies of superconducting qubits as fabricated can deviate from design targets.

In this regard, laser annealing techniques can be used to adjust qubit frequencies post-fabrication and thereby selectively tune fixed-frequency qubits of a given qubit lattice into desired frequency patterns. In particular, laser annealing techniques can be utilized to increase collision-free yield of fixed-frequency qubit lattices by selectively trimming (i.e., tuning) individual qubit frequencies, post-fabrication, by enabling localized thermal annealing the Josephson junctions of the qubits to thereby adjust and stabilize the junction resistance R_{J} of the respective Josephson junctions (and correspondingly, the respective qubit transition frequencies f₀₁) with high precision. The tuning of qubit transition frequencies through laser annealing, however, is non-trivial due to, e.g., inherent variabilities of the laser anneal process itself and/or the equipment that is utilized to perform such laser annealing, post fabrication, to tune the qubit transition frequencies in a given qubit lattice.

### SUMMARY

Exemplary embodiments of the disclosure include techniques for generating and utilizing bidirectional tuning calibration data for configuring laser annealing operations for laser tuning Josephson junctions.

For example, an exemplary embodiment includes a method which comprises performing laser annealing calibration operations on first Josephson junctions using different combinations of at least laser power settings and anneal times, determining junction resistance shifts of the first Josephson junctions as a result of the laser annealing calibration operations, and utilizing the determined junction resistance shifts of the first Josephson junctions to determine calibration data for configuring laser annealing operations for bidirectional laser tuning of second Josephson junctions corresponding to the first Josephson junctions.

Advantageously, the calibration process is configured to perform laser annealing calibration operation on Josephson junctions to generate tuning calibration data which is representative of laser tuning characteristics of the Josephson junctions (e.g., Josephson junctions of quantum bit devices), wherein the calibration data can be used to configure laser tuning operations (e.g., selecting target combinations of laser power settings, laser anneal times, and laser beam illumination patterns etc.) to enable bidirectional laser tuning of corresponding Josephson junctions to increase or decrease respective junction resistance towards respective target junction resistances, while allowing correction of junction resistance undershooting or overshooting tuning errors.

Another exemplary embodiment includes a system which comprises a laser annealing apparatus, and a control system operatively coupled to the laser annealing apparatus. The control system is configured to control the laser annealing apparatus to perform a calibration process The calibration process comprises performing laser annealing calibration operations on first Josephson junctions using different combinations of at least laser power settings and anneal times, determining junction resistance shifts of the first Josephson junctions as a result of the laser annealing calibration operations, and utilizing the determined junction resistance shifts of the first Josephson junctions to determine calibration data for configuring laser annealing operations for bidirectional laser tuning of second Josephson junctions corresponding to the first Josephson junctions.

In another exemplary embodiment, as may be combined with the preceding paragraphs, the laser annealing calibration operations are performed on the first Josephson junctions using different combinations of laser power settings, anneal times, and laser beam illumination patterns.

In another exemplary embodiment, as may be combined with the preceding paragraphs, the determined junction resistance shifts of the first Josephson junctions are utilized to determine calibration data which corresponds to a first tuning profile for configuring a laser annealing operation to decrease a resistance of at least one of the second Josephson junctions, and to determine calibration data which corresponds to a second tuning profile for configuring a laser annealing operation to increase a resistance of at least another of the second Josephson junctions.

In another exemplary embodiment, as may be combined with the preceding paragraphs, the determined junction resistance shifts of the first Josephson junctions are utilized to determine a negative tuning range for the first tuning profile, and to determine a positive tuning range for the second tuning profile.

In another exemplary embodiment, as may be combined with the preceding paragraphs, the determined junction resistance shifts of the first Josephson junctions are utilized to determine a negative tuning rate for the first tuning profile, and to determine a positive tuning rate for the second tuning profile.

In another exemplary embodiment, as may be combined with the preceding paragraphs, the determined junction resistance shifts of the first Josephson junctions are utilized to determine calibration data which corresponds to a third tuning profile for configuring a laser annealing operation to forward-shift a resistance of at least one of the second Josephson junctions following a decrease of the resistance of the at least one of the second Josephson junctions using the first tuning profile.

In another exemplary embodiment, as may be combined with the preceding paragraphs, the determined junction resistance shifts of the first Josephson junctions are utilized to determine calibration data which corresponds to a fourth tuning profile for configuring a laser annealing operation to reverse-shift a resistance of at least one of the second Josephson junctions following an increase of the resistance of the at least one of the second Josephson junctions using the second tuning profile.

Another exemplary embodiment includes a system which comprises a laser annealing apparatus, and a control system operatively coupled to the laser annealing apparatus. The control system is configured to control the laser annealing apparatus to perform a laser annealing process to tune Josephson junctions on a quantum chip. In performing the laser annealing process, the control system is configured to: calibrate the laser annealing apparatus to perform a first laser annealing process based on a first combination of at a laser power setting and an anneal time, to laser tune a first Josephson junction to decrease a resistance of the first Josephson junction below an initial resistance of the first Josephson junction; and calibrate the laser annealing apparatus to perform a second laser annealing process based on a second combination of at least a laser power setting and an anneal time, to laser tune a second Josephson junction to increase a resistance of the second Josephson junction above an initial resistance of the second Josephson junction.

Other embodiments will be described in the following detailed description of exemplary embodiments, which is to be read in conjunction with the accompanying figures.

### BRIEF DESCRIPTION OF THE DRAWINGS

FIG. 1 schematically illustrates a laser annealing system for tuning Josephson junctions, according to an exemplary embodiment of the disclosure.

FIG. 2A illustrates a bidirectional tuning curve for laser tuning Josephson junctions, according to an exemplary embodiment of the disclosure.

FIG. 2B illustrates a graph of a negative tuning regime of a bidirectional tuning curve, according to an exemplary embodiment of the disclosure.

FIG. 2C illustrates a graph of positive tuning regimes and reverse-shift tuning regimes of a plurality of calibration curves obtained for different combinations of a plurality of laser power settings and anneal times, according to an exemplary embodiment of the disclosure.

FIG. 2D illustrates a graph of a reverse-shift tuning regime of a bidirectional tuning curve, according to an exemplary embodiment of the disclosure.

FIG. 3A schematically illustrates a process for laser annealing a quantum device using a laser beam illumination pattern, according to an exemplary embodiment of the disclosure.

FIG. 3B schematically illustrates a process for laser annealing a quantum device using a laser beam illumination pattern, according to another exemplary embodiment of the disclosure.

FIG. 3C schematically illustrates a process for laser annealing a quantum device using a laser beam illumination pattern, according to another exemplary embodiment of the disclosure.

FIG. 3D schematically illustrates a process for laser annealing a quantum device using a laser beam illumination pattern, according to another exemplary embodiment of the disclosure.

FIG. 3E schematically illustrates a process for laser annealing a quantum device using a laser beam illumination pattern, according to another exemplary embodiment of the disclosure.

FIG. 3F schematically illustrates a process for laser annealing a quantum device using a laser beam illumination pattern, according to another exemplary embodiment of the disclosure.

FIG. 3G schematically illustrates a process for laser annealing a quantum device using a laser beam illumination pattern, according to another exemplary embodiment of the disclosure.

FIG. 4 illustrates a flow diagram of a calibration process for obtaining calibration data for use in bidirectional laser tuning of Josephson junctions, according to an exemplary embodiment of the disclosure.

FIG. 5A illustrates a flow diagram of a process for performing laser annealing calibration tests on Josephson junctions to obtain calibration data, according to an exemplary embodiment of the disclosure.

FIG. 5B illustrates a flow diagram of a process for analyzing calibration data obtained from laser annealing calibration tests to determine/generate bidirectional tuning curves and associated calibration parameters for different combinations of laser power settings, anneal times, and laser beam illumination patterns, according to an exemplary embodiment of the disclosure.

FIG. 5C is a graph which illustrates an exemplary calibration tuning curve for a negative tuning regime, according to an exemplary embodiment of the disclosure.

FIG. 5D is a graph which illustrates an exemplary calibration tuning curve for a forward-shift tuning regime, according to an exemplary embodiment of the disclosure.

FIG. 5E is a graph which illustrates exemplary calibration tuning curves for positive tuning regimes, according to an exemplary embodiment of the disclosure.

FIG. 5F is a graph which illustrates exemplary calibration tuning curves for positive tuning regimes, according to another exemplary embodiment of the disclosure.

FIGS. 6A, 6B, 6C, and 6D illustrate methods for utilizing tuning calibration data to determine target combinations of a laser power setting, anneal time, and laser beam illumination pattern, for calibrating initial laser annealing operations for partial tuning of Josephson junctions to their respective target junction resistances, according to exemplary embodiments of the disclosure.

FIG. 7A illustrates a bidirectional tuning curve for laser tuning Josephson junctions, according to another exemplary embodiment of the disclosure.

FIG. 7B is a flow diagram of a method for analyzing calibration data obtained from laser annealing calibration tests to generate bidirectional tuning curves and associated calibration parameters, according to an exemplary embodiment of the disclosure.

FIG. 8A illustrates graphs of exemplary tuning curves which have portions that exhibit intermediate behaviors that do not fall within desired bidirectional tuning regimes, according to exemplary embodiments of the disclosure.

FIG. 8B is a flow diagram of a method for analyzing calibration data obtained from laser annealing calibration tests to identify bidirectional tuning regimes, according to an exemplary embodiment of the disclosure.

FIG. 9A illustrates a flow diagram of a method for tuning Josephson junctions, according to an exemplary embodiment of the disclosure.

FIG. 9B schematically illustrates a process for aligning electrical probes to contact pads of a Josephson junction of quantum bit to perform an in-situ junction resistance measurement, according to an exemplary embodiment of the disclosure.

FIG. 9C illustrates a flow diagram of a method for tuning Josephson junctions, according to another exemplary embodiment of the disclosure.

FIG. 10 illustrates a flow diagram of a method for utilizing bidirectional tuning during a laser tuning process to correct for tuning errors in reaching target resistances of Josephson junctions, according to an exemplary embodiment of the disclosure.

FIG. 11 graphically depicts Monte Carlo simulations which illustrate an improvement in qubit frequency tuning that can be achieved using bidirectional correction tuning of Josephson junctions, according to an exemplary embodiment of the disclosure.

FIG. 12 schematically illustrates an exemplary qubit lattice comprising a heavy-hexagonal qubit lattice, according to an exemplary embodiment of the disclosure.

FIG. 13 illustrates a flow diagram of a method for generating a frequency tuning plan, according to an exemplary embodiment of the disclosure.

FIG. 14 illustrates a flow diagram of a method for tuning Josephson junctions of qubit devices of a qubit lattice based on a tuning plan, according to an exemplary embodiment of the disclosure.

FIG. 15 schematically illustrates an exemplary architecture of a computing environment for implementing a control system that is configured to control a laser annealing system for tuning Josephson junctions, according to an exemplary embodiment of the disclosure.

### DETAILED DESCRIPTION

Exemplary embodiments of the disclosure will now be described in further detail with regard to techniques for generating laser tuning calibration data (e.g., calibration tuning parameters) which is utilized to configure laser annealing operations for bidirectional laser tuning Josephson junctions, e.g., laser tuning Josephson junctions of superconducting qubits. In addition, exemplary embodiments will be discussed in further detail with regard to techniques for utilizing the laser tuning calibration data to generate frequency tuning plans for frequency collision avoidance in multi-qubit lattices of a given topology (e.g., a heavy-hexagonal lattice, a square lattice, and the like) as well as techniques for performing LASIQ (Laser Annealing of Stochastically Impaired Qubits) tuning operations to tune transition frequencies of superconducting qubits by laser tuning junction resistances of the qubit Josephson junctions.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs. In addition, the terms “about” or “substantially” as used herein with regard to, e.g., percentages, ranges, etc., are meant to denote being close or approximate to, but not exactly. For example, the term “about” or “substantially” as used herein implies that a small margin of error may be present, such as 1% or less than the stated amount.

It is to be further understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUS), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

Further, the term “quantum chip” as used herein is meant to broadly refer to any device which comprises qubits and possibly other quantum devices. For example, a quantum chip can be semiconductor die which comprises an array (lattice) of qubits, which is fabricated on a wafer comprising multiple dies, and which can be diced (cut) from the wafer using a die singulation process to provide a singulated die. In some instances, a quantum chip can be a wafer with multiple dies. In the context of quantum computing, a quantum chip may comprise one or more processors for a quantum computer.

Moreover, the term “shot” as used herein denotes a laser anneal operation that is performed by applying laser power to a target element (e.g., Josephson junction) for a specified duration (anneal time) to tune the target element. In the context of exemplary embodiments of the disclosure as discussed herein, laser tuning methods are provided to tune junction resistances of Josephson junctions in a progressive and incremental manner wherein multiple “shots” are applied to a given Josephson junction to tune the junction resistance of the Josephson junction to a target junction resistance, which is to be contrasted with conventional approaches that tune a Josephson junction to a target junction resistance using only a single laser shot.

The term “iterate” or “iteratively” used herein and in the context of a laser annealing process is meant to refer to the process which comprises a single “shot” along with associated control, measurement and computation by a LASIQ computer system and apparatus to determine a target anneal time and power for performing the anneal shot. A laser annealing iteration, or LASIQ iteration, therefore refers to the entire process by which a Josephson junction is measured, the anneal power and time is determined, and the anneal shot is performed. In this sense, a single iteration involves an entire sequence of the laser annealing system and apparatus as it pertains to one step of a progressive approach to a resistance target for one Josephson junction. The tuning of one junction to completion (i.e., reaching its target resistance) may therefore be said to progress “iteratively.” The term “iterative process” as used herein, is meant to generally refer to a set of iterations, as applicable to one or more qubits, or the like, comprising Josephson junctions, whereby the one or more qubits are tuned with the purpose of approaching their respective targets.

The term “progressive” or “progressively” as used herein and in the context of a laser annealing process, is meant to refer to the gradual approach of shifting a junction resistance of a Josephson junction to a respective target resistance. Such a progressive approach is a result of multiple annealing iterations, each of which include a laser shot to alter the junction resistance in the desired direction towards the target resistance. Additionally, such a progressive approach is asymptotic, in the sense that the tuning rate nominally decreases as the junction resistance of a given Josephson junction approaches nearer to its respective target resistance.

The term “adaptive” or “adaptively” as used herein and in the context of a laser annealing process, is meant to refer to the appropriate selection of laser annealing parameters, including such parameters as laser annealing time and annealing power, as it pertains to a laser shot, to allow the Josephson junction resistances to monotonically and asymptotically approach their respective resistance targets. The adaptive nature of the laser annealing iterations is achieved using methods described herein, whereby the laser anneal time and power are selected based on historical reconstruction of the tuning progression of the specific junction. The methods described herein account for the rate of historical tuning of the specific junction being tuned, thereby mitigating the risk of missing resistance targets (e.g., by using laser shots that have excess time such that the junction resistance is tuned beyond the desired resistance target).

The term “round-robin” as used herein and in the context of a laser annealing process for tuning the Josephson junctions of qubits, is meant to refer to a tuning process in which the Josephson junctions of, e.g., all qubits on a multi-qubit device undergo the laser annealing process in succession, and which may be followed by another round-robin or multiple round-robins in succession. Such round-robins may be continuously performed until all qubits on the multi-qubit device reach their respective targets. For example, a singulated quantum chip may comprise a number of qubit devices (e.g., 100 qubits, denoted Q1, Q2, Q3, . . . , Q100) comprising Josephson junctions. In an exemplary embodiment of a tuning method, Q1 will first be tuned with one or more annealing iterations, as desired. The process will proceed to Q2, where one or more annealing iterations may be performed, as desired. The process will then proceed to Q3, etc., until finally Q100 is tuned with one or more annealing iterations, as desired. The entire process from Q1 to Q100 is defined as one round-robin. After this first round-robin, the process may return to Q1, and will repeat again until Q100 is reached. The process of successive round-robins may provide a means of time control and delay between iterations or sets of iterations, such that the Josephson junctions may be permitted to relax to their final junction resistances prior to the next annealing iteration or set of iterations.

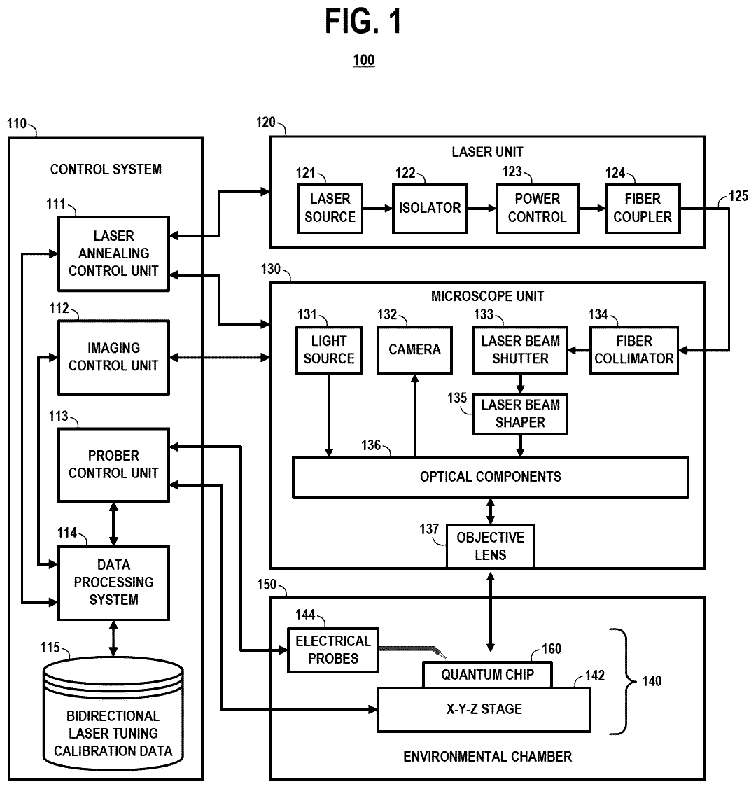

FIG. 1 schematically illustrates a laser annealing system 100 for tuning Josephson junctions, according to an exemplary embodiment of the disclosure. In some embodiments, the laser annealing system 100 is configured to implement LASIQ (Laser Annealing of Stochastically Impaired Qubits) tuning methods for laser annealing of Josephson junctions of qubits, post-fabrication, to adjust and stabilize the junction resistances R_{J} and thereby selectively tune the individual qubit frequencies via laser thermal annealing of the respective Josephson junctions. As schematically shown in FIG. 1, the laser annealing system 100 comprises a control system 110, a laser unit 120, an optical fiber 125, a microscope unit 130, a prober unit 140, and optional environmental chamber 150.

The control system 110 comprises a laser annealing control unit 111, an imaging control unit 112, a prober control unit 113, a data processing system 114, and a database of bidirectional laser tuning calibration data 115. The laser unit 120 comprises a laser source 121, an isolator 122, a laser power control block 123, and a fiber coupler 124. The microscope unit 130 comprises a light source 131, a camera 132, a laser beam shutter 133, a fiber collimator 134, a laser beam shaper 135, a plurality of optical components 136, and an objective lens 137. The prober unit 140 comprises an X-Y-Z stage 142, and electrical probes 144. A quantum chip 160 (or any other similar device under test) can be mounted to the X-Y-Z stage. In some embodiments, the quantum chip comprises a lattice of superconducting qubits, where each superconducting qubit comprises at least one respective Josephson junction which can be annealed using the laser annealing system 100 to tune the junction resistance and, thus, tune the transition frequency of the superconducting qubit, post-fabrication.

In some embodiments, the laser unit 120 and the microscope unit 130 comprise modular units that are coupled together via the optical fiber 125. In some embodiments, the optical fiber 125 comprises a single-mode (SM) polarization-maintaining (PM) optical fiber, which is configured to preserve a linear polarization of linearly polarized light that is injected into the optical fiber 125 by the laser unit 120 and propagated to the microscope unit 130. The microscope unit 130 comprises a modular optical unit which comprises visible light and laser optical components. The microscope unit 130 can be integrated onto the prober unit 140 (e.g., a wafer-scale prober). In this regard, in some embodiments, the laser unit 120, the microscope unit 130, and the prober unit 140 can be physically coupled/attached to each other to form an integrated laser annealing apparatus which is configured to perform laser anneal operations for tuning junction resistances of Josephson junctions, as well as performing in-situ junction resistance measurements, under the control of the control system 110. In some embodiments, the control system 110 is operatively/communicatively coupled to the laser unit 120, the microscope unit 130, and the prober unit 140 via wires and/or wirelessly. The control system 110 comprises hardware and/or software for automated control of various operations of the laser unit 120, the microscope unit 130, and the prober unit 140 of the laser annealing system 100.

The laser unit 120 is configured to generate a laser beam that is used by the microscope unit 130 to generate a laser beam pattern which comprises a single or multi-spot beam pattern for laser annealing a given Josephson junction. In some embodiments, the laser source 121 comprises a solid-state diode pump to generate laser energy, and a laser head to generate a focused laser beam from the laser energy emitted from the solid-state diode pump. In some embodiments, the diode pump comprises a 532 nanometer (nm) (frequency doubled) diode-pumped solid-state laser (e.g., a second harmonic generation (SHG) laser). In some embodiments, the power level of the laser source 121 (e.g., solid-state diode pump) can be adjusted by the control system 110. For example, the power level of the laser source 121 can be set to one of a plurality of different power level settings (e.g., lower power, medium power, high power settings). The isolator 122 is configured to provide polarization cleanup and optical isolation to mitigate unwanted feedback to the laser head of the laser source 121.

The laser power control block 123 is configured to actively control and calibrate the power of the focused laser beam. For example, in some embodiments, the laser power control block 123 comprises a half-wave plate, and a polarizing beam-splitter (PBS) coupled to a dump. Th half-wave plate is configured to shift the polarization direction of the laser beam output from the isolator 122. The laser power control block 123 further comprises a power monitor which comprises, e.g., an optical wedge that is configured to divert some laser beam power to a silicon photodiode. The silicon photodiode generates an electrical signal that is indicative of the laser power level, and the electrical signal is feedback to the control system 110 (e.g., the laser annealing control unit 111), the control system 110 generates control signals that are applied to the laser power control block 123 to adjustably control the laser power, as directed, for laser tuning of Josephson junctions. More specifically, in some embodiments, the power level of the laser beam can be coarsely adjusted by controlling the power output of the laser source 121, while the power level of the laser beam can be finely adjusted by operation of the laser power control block 123.

For example, in some embodiments, the half-wave plate of the laser power control block 123 is configured to shift the polarization direction of the laser beam output from the isolator 122, and the half-wave plate comprises an adjustable rotation, which can be electronically-controlled via the laser annealing control unit 111 to adjust a total attenuation by rotating the polarization incident on the polarizing beam splitter to the desired power level. In some embodiments, the polarizing beam splitter of the laser power control block 123 comprises an optical filter that allows a specific polarization of light waves associated with the laser beam to pass through the optical filter and blocks light waves of other polarizations, to thereby generate a laser beam with well-defined polarized light.

The polarized laser light generated by the laser unit 120 is coupled into the optical fiber 125 (e.g., single-mode polarizing-maintaining optical fiber) via the fiber coupler 124, and propagates to the microscope unit 130. In the microscope unit 130, the fiber collimator 134 (e.g., collimating lens) is configured to transform the laser light which is output from the optical fiber 125 into a free-space collimated beam. In some embodiments, the microscope unit 130 comprises a power monitor which comprises, e.g., a beam sampler (e.g., beam splitter) and photodiode, to monitor the power of the collimated laser beam to enable precise exposure control downstream from the power control/adjustment mechanisms provided by the laser unit 120.

Furthermore, in the microscope unit 130, the laser beam shutter 133 comprises an electronic shutter that is operated under control of, e.g., the laser annealing control unit 111 of the control system 110, to control the time duration of laser exposure when annealing a given Josephson junction. For example, the laser beam shutter 133 can be opened for a given duration of time when annealing a target Josephson junction to allow annealing laser beams to be projected onto the quantum chip 160 in proximity to the target Josephson junction, and then automatically close after the given duration of time. In this regard, the laser power level and the pulse duration (laser exposure) can be controlled to achieve a desired change (e.g., decrease) in the resistance of the annealed Josephson junction.

The laser beam shaper 135 is configured to split the collimated laser beam (which passes through the laser beam shutter 133) into two or more laser beams with slightly different angles relative to one another. In some embodiments, the laser beam shaper 135 comprises a diffractive optical element (DOE), such as a diffractive beam splitter which splits a single laser beam into several beams (diffraction orders) in a predefined configuration. The diffractive beam splitter comprises a holographic optical element that imparts a precise angle (e.g., a 0.5 degree shift) to the incoming laser beam in plus and minus angular directions relative to a reference plane, to thereby generate a plurality of outgoing laser beams.

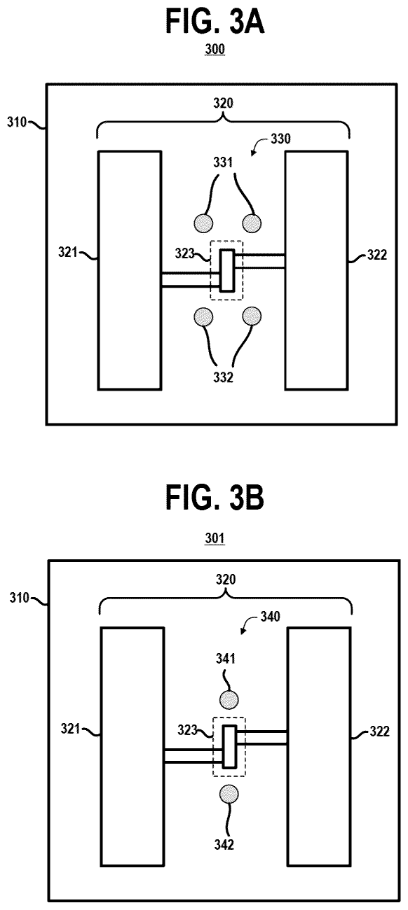

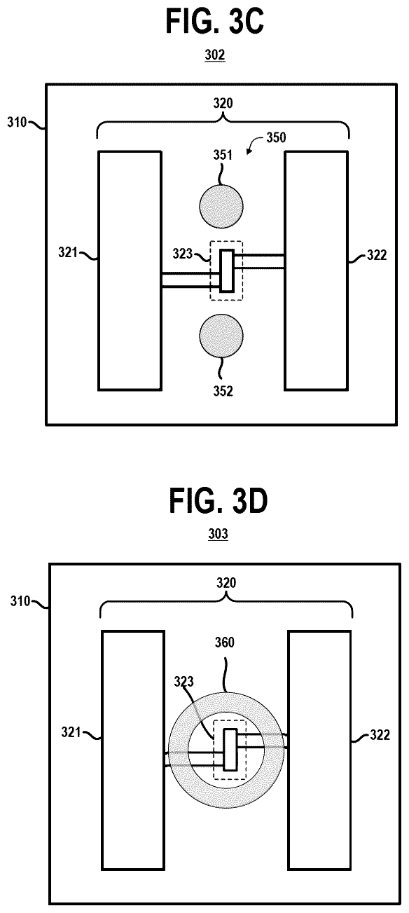

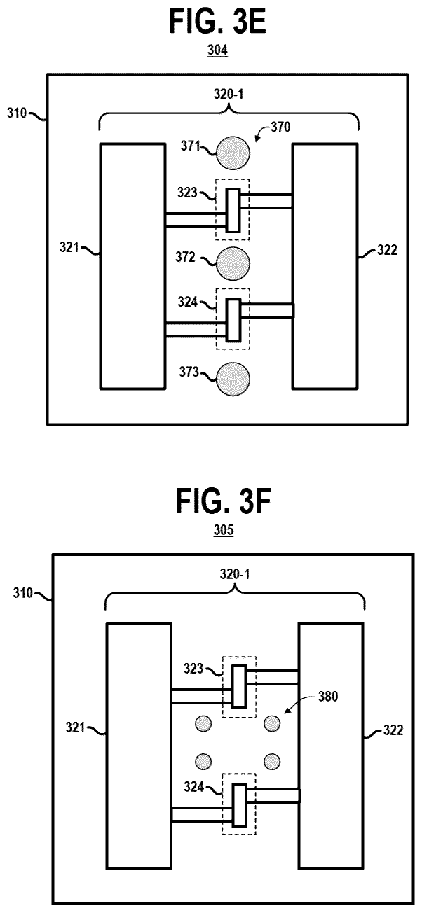

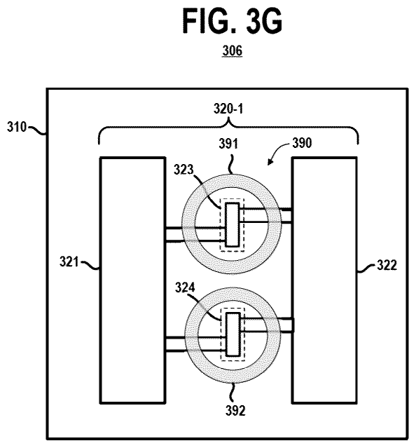

The number of laser beams generated by the laser beam shaper 135 can vary depending on the given application. For example, in some embodiments, laser beam shaper 135 comprises a 2-by-2 diffractive beam splitter, which splits the single collimated laser beam into four separate laser beams, which results in a final quad-spot illumination pattern that is projected onto the surface of the quantum chip 160 at a target location. In some embodiments, the laser beam shaper 135 can be switched either manually or automatically with a different diffractive beam splitter (e.g., a plurality of DOEs on a rotary stage) to obtain a different laser beam illumination pattern, as desired. In this regard, different diffractive beam splitters can be selected for use to generate any desired number (e.g., 2, 3, 5, 6, etc.) of laser beams with defined illumination patterns tailored to different applications. Various exemplary embodiments of laser beam illumination patterns will be described in further detail in conjunction with, e.g., FIGS. 3A-3G.

The microscope unit 130 implements the light source 131 and the camera 132 for illuminating and viewing target features (e.g., qubits and corresponding Josephson junctions) on the surface of the quantum chip 160 within a given field of view (FOV) of the microscope unit 130. In some embodiments, the light source 131 comprises any suitable light generating device including one or more light emitting diodes (LEDs) with desired photonic wavelengths, a monochromatic light source, etc. The light source 131 together with some of the optical components 136 in the optical viewing path implement Kohler illumination to create uniform illumination of the target features in the FOV of the microscope unit 130 and to ensure that an image of the light source 131 is not visible in the resulting images captured by the camera 132.

In some embodiments, the camera 132 comprises a charge-coupled device (CCD) image sensor, or an infrared (IR) complementary metal oxide semiconductor (CMOS) image sensor. The camera 132 is utilized to capture images of a target region on the surface of the quantum chip 160 to facilitate, e.g., aligning the electrical probes 144 to contact electrodes when performing in-situ Josephson junction resistance measurements, aligning the laser beam pattern onto the target region when performing laser annealing operations, etc. For example, in some embodiments, the Josephson junction of a given qubit is aligned to the center of the FOV of the microscope unit 130 using pattern recognition to, e.g., a Josephson junction template image.

The optical components 136 include various types of optical components for directing, reflecting, focusing, modifying, and shaping, etc., the optical signals (e.g., laser beams for annealing, and visible light/IR light for viewing) as needed for the given application. For example, the optical components 136 include components such as a mirror, beam splitters, filters, polarizers, and various lenses such as a tube lens, an objective lens, relay lenses, etc.). The objective lens 137 is the lens that is located closest to the device under test (quantum chip 160) and serves to provide the base magnification for generating a magnified image that is viewed by the camera 132, and to project the annealing laser beam pattern (e.g., quad-spot pattern) onto the surface of the quantum chip 160. In some embodiments, the objective lens 137 comprises a long working distance (WD) objective lens. In an exemplary non-limiting embodiment, the objective lens 137 (together with an optional second objective lens) is configured to condense the laser beams and multi-spot pattern by 4×, while providing 20× image magnification.

The prober unit 140 is configured to automatically move the position of the quantum chip 160 during a laser annealing process to align a target Josephson junction of a given qubit within the FOV of the microscope unit 130 to perform an in-situ Josephson junction resistance measurement and a laser anneal of the target Josephson junction. In particular, the quantum chip 160 is mounted to the automated X-Y-Z stage 142 which is controllably moved in three dimensions to align features of the quantum chip 160 within the FOV of the microscope unit 130 and enable contact between the electrical probes 144 and contact pads on the quantum chip 160. For example, in some embodiments, during a laser anneal process, a target Josephson junction of a given qubit is aligned to the center of the FOV of the microscope unit 130 using an automated pattern recognition process in which features of an image captured by the camera 132 are automatically aligned to corresponding features of a template image to ensure proper positioning of the target Josephson junction and associated contact pads. In particular, an alignment process is performed to ensure accurate registration between the contact pads of the target Josephson junction and the electrical probes 144 when performing an in-situ Josephson junction resistance measurement. In addition, an alignment process is performed to ensure a proper alignment of the target Josephson junction and a laser beam illumination pattern when performing a laser anneal operation.

As noted above, the electrical probes 144 are implemented to perform in-situ Josephson junction resistance measurements during a laser anneal process. In particular, in-situ Josephson junction resistance measurements are performed in between laser annealing operations (shots) to track the tuning progress of the Josephson junctions of the qubits during a multi-step anneal process in which the Josephson junctions are progressively tuned. In some embodiments, the electrical probes 144 comprise two pairs of probes, which are configured to perform a 4-wire resistance measurement (or Kelvin resistance measurement) to more precisely measure the junction resistance of a Josephson junction. In general, a 4-wire (Kelvin) resistance measurement involves determining the resistance of a given Josephson junction by measuring a current (I) flow through the junction as well as a voltage (V) drop across the junction, and determining the junction resistance R_{J} from Ohm's Law, i.e., R_{J}=V/I.

In some embodiments, the electrical probes 144 comprise a probe card that is mechanically mounted in a fixed position to the prober unit 140. In some embodiments, the integration of the microscope unit 130 and the prober unit 140 is configured to ensure that a sample imaging plane and a laser focal plane are substantially identical, while a probing plane is displaced from the sample imaging plane by a present amount, e.g., 70 microns, 80 microns, etc. In this configuration, the electrical probes 144 are fixedly displaced from the image plane, and the Z-position of the X-Y-Z stage 142 (with the quantum chip 160 mounted thereon) is moved into a default contact position to make electrical contact between the electrical probes 144 and target contact pads on the quantum chip 160, to perform an in-situ Josephson junction resistance measurement.

In some embodiments, the prober unit 140 is housed or otherwise disposed within the optional environmental chamber 150 to control an ambient environment during laser annealing, wherein different ambient environments impact the laser annealing progression differently. For example, in some embodiments, the laser annealing system 100 may comprise an environmental gas control system which is coupled to the environmental chamber 150 and which is configured to inject a mixture of one or more gases into the environmental chamber 150 to control the annealing environment. More specifically, in some embodiments, the environmental gas control system may comprise a gas dilution unit which is connected to a plurality of gas cylinders which store different gases (e.g., nitrogen, dry air, etc.), wherein the gas dilution unit can mix different gases at various concentrations and inject the mixed gases into the environmental chamber 150, as desired, to provide a given gas environment for laser annealing. In addition, the environmental gas control system comprises a vacuum system coupled to the environmental chamber 150 to evacuate anneal gases from the chamber or otherwise evacuate air from the environmental chamber 150 to perform laser annealing in a vacuum atmosphere.

Moreover, in some embodiments, a temperature control system is coupled to the X-Y-Z stage 142 (e.g., wafer chuck) to control the temperature of the X-Y-Z stage 142 on which the quantum chip 160 is mounted. The X-Y-Z stage 142 may be temperature controlled to allow high-temperature anneals (e.g., bulk anneals) or low-temperature probing for low-noise electrical resistance measurements. For example, in some embodiments, the X-Y-Z stage 142 can be temperature controlled in a range of −60° C. to 300° C.

As noted above, various functions of the laser unit 120, the microscope unit 130, and the prober unit 140 are automatically controlled by the control system 110. In some embodiments, the laser annealing control unit 111, the imaging control unit 112, and the prober control unit 113, comprise respective hardware interfaces for interfacing with the laser unit 120, the microscope unit 130, and the prober unit 140, as needed, to generate and apply control signals to components of such units 120, 130, and 140, and to receive and process signals (e.g., data, measurements, feedback controls signals, etc.) received from components of such units 120, 130, and 140. The data processing system 114 comprises one or more processors that execute software programs/routines to control laser annealing, imaging, and prober operations by processing data received from the control units 111, 112, and 113 (e.g., to perform automated pattern recognition for active alignments, perform junction resistance measurement computations, etc.), and generating and outputting control signals to cause the control units 111, 112, and 113, to control the operations of the laser unit 120, the microscope unit 130, and the prober unit 140 in a coordinated manner, when performing laser annealing and in-situ junction resistance measurements, as discussed herein.

For example, in some embodiments, the laser annealing control unit 111 is configured to control operation of components of the laser unit 120, such as the laser source 121 and the laser power control block 123, to adjust the power level of the laser beam output from the laser unit 120. In addition, the laser annealing control unit 111 is configured to control the operation of the components of the microscope unit 130 for laser annealing operations. For example, the laser annealing control unit 111 is configured to control the operation of the laser beam shutter 133 to control the duration of laser exposure when laser tuning a given Josephson junction. Further, in some embodiments, the laser annealing control unit 111 is configured to control the laser beam shaper 135, e.g., to switch the diffractive beam splitter settings and corresponding laser illumination patterns.

Further, in some embodiments, the imaging control unit 112 is configured to control the operation of the light source 131, the camera 132, and one or more of the optical components 136 (e.g., tube lens) that make up the image path of the microscope unit 130. For example, the imaging control unit 112 can generate camera control signals to cause the camera 132 to capture images within the FOV of the microscope unit 130 and send images to the imaging control unit 112. The imaging control unit 112 can be configured to preprocess the image data into a suitable format for processing by the data processing system 114 to perform automated pattern recognition functions to perform laser alignment and electrical probe alignment operations as discussed herein.

Moreover, in some embodiments, the prober control unit 113 is configured to control operations of the prober unit 140. For example, the prober control unit 113 comprises hardware for generating test voltages that are applied to the electrical probes for performing junction resistance measurements, e.g., for a 4-wire (Kelvin) resistance measurement, the prober control unit 113 may comprise current and voltage measurement circuitry, which is coupled to the electrical probes 144, and configured to measure current that flows through a Josephson junction as a result of applying a test voltage to the electrical probes, as well as measure a voltage across the Josephson junction. The measured currents and voltages can be digitized and sent to the data processing system 114 for computing junction resistances. In addition, the prober control unit 113 comprises control elements to precisely control movement and positioning of the X-Y-Z stage 142.

In some embodiments, the data processing system 114 executes a calibration process by performing laser annealing operations on Josephson junctions of representative hardware, using different combinations of a plurality of laser power settings, anneal times, and laser beam illumination patterns, to generate and persistently store bidirectional laser tuning calibration data 115. In some embodiments, the bidirectional laser tuning calibration data 115 is obtained by performing a calibration process on representative hardware which, in some embodiments, can be test (dummy) Josephson junctions that reside on the same quantum chip to be tuned, and in other embodiments, can be Josephson junctions of qubits that are formed on a sister chiplet from the same fabrication process. The bidirectional laser tuning calibration data 115 is analyzed using statistical methods to fit the tuning calibration data to bidirectional tuning curves, wherein the bidirectional tuning curves are utilized to determine tuning rates and maximum tuning ranges (e.g., maximum positive and negative tuning ranges) for Josephson junctions under different combinations of laser power settings, anneal times, and laser beam illumination patterns. The tuning curves are utilized by the data processing system 114 to select a target combination of a laser power setting, anneal time, and laser beam illumination pattern, as desired, for a target tuning rate and maximum tuning range for laser annealing Josephson junctions of the given quantum chip, post fabrication. In some embodiments, the tuning curves are used to predict an initial laser anneal operation (initial shot) for tuning a given Josephson junction to a certain target (e.g., 50% to target) on a first shot. The calibration process ensures a smooth and rapid approach to a target tuning for a given Josephson junction, while mitigating risk of both undershooting and overshooting the tuning.

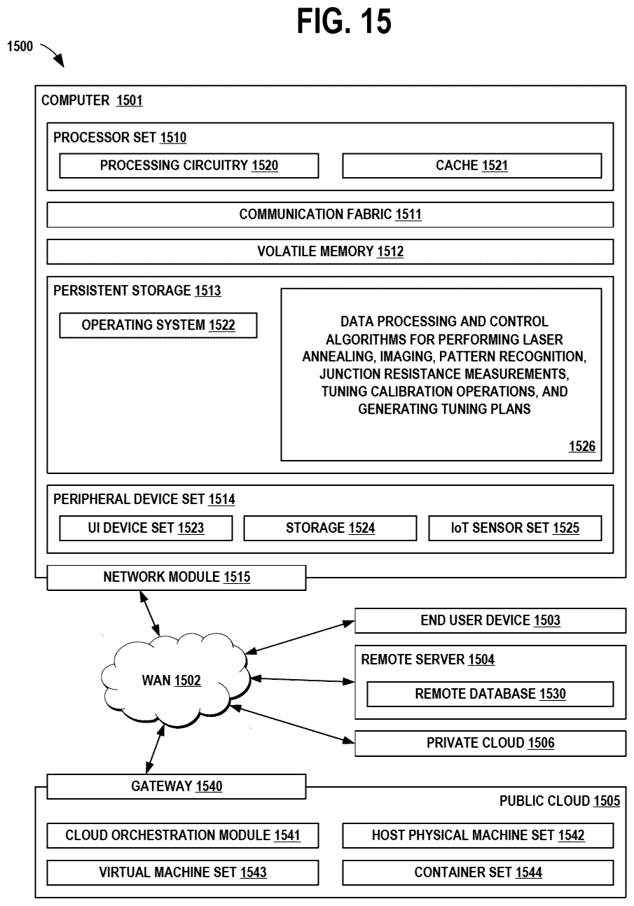

In some exemplary embodiments, the control system 110 for the laser annealing system 100 may be implemented using any suitable computing system architecture which is configured to implement methods to support the automated control processes as described herein by executing computer readable program instructions that are embodied on a computer program product which includes a computer readable storage medium (or media) having such computer readable program instructions thereon for causing a processor to perform control methods as discussed herein. An exemplary architecture of a computing environment for implementing a control system that is configured to control the laser annealing apparatus for tuning Josephson junctions, will be discussed in further detail below in conjunction with FIG. 15.

It is to be appreciated that the exemplary laser annealing system 100 of FIG. 1 can be utilized to perform exemplary calibration processes (as described herein) for generating calibration data (e.g., calibration tuning parameters) for laser tuning Josephson junctions, e.g., laser tuning Josephson junctions of superconducting qubits, and other associated methods for generating and implementing tuning plans for frequency collision avoidance in multi-qubit lattices and performing LASIQ tuning operations to tune the transition frequencies of superconducting qubits by tuning junction resistances of the qubit Josephson junctions using the exemplary calibration and laser tuning techniques as discussed herein.

The exemplary calibration methods discussed herein are configured to generate and process calibration data to extract tuning curves (e.g., bidirectional tuning curves) based on different combinations of laser power settings, anneal times, and laser beam illumination patterns. The tuning curves provide information (e.g., calibration parameters) that is used for bidirectional tuning of junction resistances of Josephson junctions in forward directions (e.g., increase junction resistance) and reverse directions (e.g., decrease junction resistance), as desired, based on appropriate selections of annealing power, anneal time, and laser beam illumination pattern. For example, the bidirectional tuning curves are utilized to determine calibration parameters (e.g., tuning rates, maximum/minimum tuning ranges, laser beam illumination patterns) for different tuning regimes to thereby enable bidirectional tuning of Josephson junctions through positive junction resistance shifts and/or negative junction resistance shifts, as needed to reach target junction resistances of the Josephson junctions. In addition, the tuning curves provide information that can be used for generating LASIQ tuning plans for tuning qubit transition frequencies through bidirectional tuning of respective Josephson junctions of the qubits.

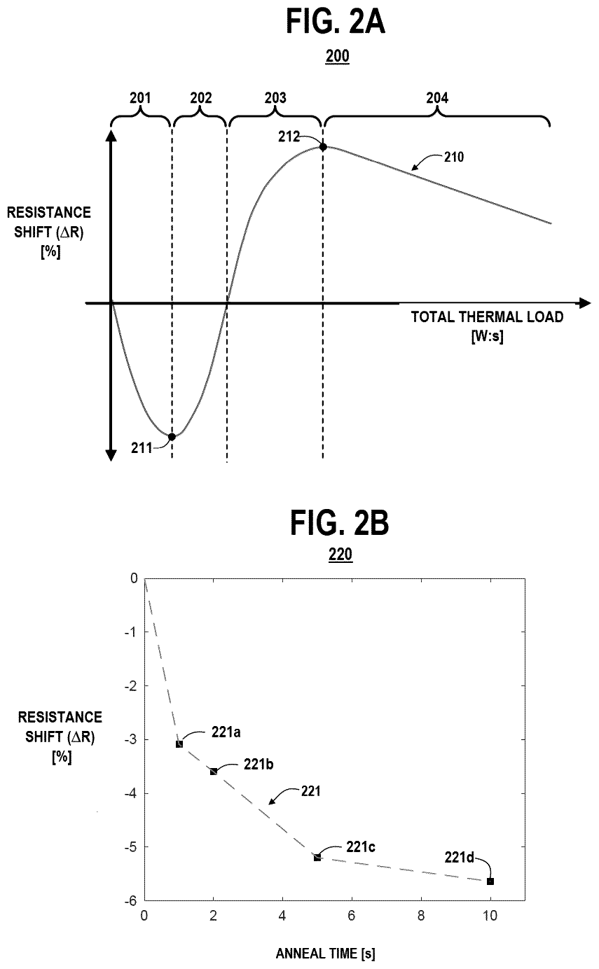

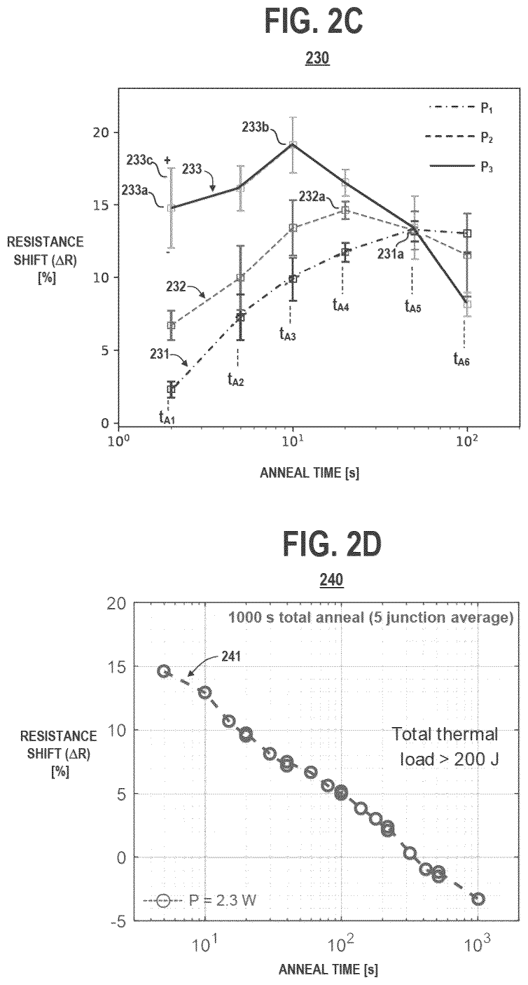

FIG. 2A illustrates a bidirectional tuning curve for laser tuning Josephson junctions, according to an exemplary embodiment of the disclosure. In particular, FIG. 2A illustrates a graph 200 of an exemplary bidirectional tuning curve 210, wherein the graph 200 illustrates an amount of junction resistance shift (ΔR) % as function of total thermal load in watt-seconds (i.e., joules) for four different tuning regimes (alternatively, tuning profiles) including a negative tuning regime 201, a forward-shift tuning regime 202, a positive tuning regime 203, and a reverse-shift tuning regime 204 (alternatively and synonymously referred to herein as negative tuning profile 201, a forward-shift tuning profile 202, a positive tuning profile 203, and a reverse-shift tuning profile 204). It is to be noted that term ΔR denotes a difference between an initial junction resistance (denoted Rᵢₙᵢₜᵢₐₗ) of given Josephson junction before laser annealing, and a current junction resistance (denoted R_{current}) of the given Josephson junction after performing a laser annealing operation at given combination of a laser power setting, anneal time, and laser beam illumination pattern, i.e., ΔR=R_{current}−Rᵢₙᵢₜᵢₐₗ. In this regard, the Y-axis of the graph 200 represents a “resistance shift percentage” which is determined as

$$Δ R \% = \frac{Δ R}{{R}_{i n i t i a l}} \times 100 \% = \frac{{R}_{c u r r e n t} - {R}_{i n i t i a l}}{{R}_{i n i t i a l}} \times 100 \% .$$

It is to be noted that the term “current junction resistance” as used herein and in conjunction with the notation R_{current} is meant to denote a junction resistance measured in the sense of occurring in or existing at a present time, or a most recently measured junction resistance.

The negative tuning regime 201 of the bidirectional tuning curve 210 illustrates that a controlled negative junction resistance shift can be achieved by laser annealing a Josephson junction at a relatively low laser anneal power (e.g., about 20 joules or less) for a given anneal time. In the negative tuning regime 201, the junction resistance is shown to monotonically decrease to a maximum negative junction resistance shift (e.g., ΔR of approximately −6.0%) as represented by point 211 on the bidirectional tuning curve 210. In other words, the point 211 represent a maximum negative tuning range (or maximum negative resistance shift) for the exemplary bidirectional tuning curve 210. In addition, FIG. 2A illustrates that the negative tuning regime 201 comprises a tuning rate which corresponds to the slope of the bidirectional tuning curve 210 in the negative tuning regime 201 (e.g., a negative tuning rate corresponding to a negative slope).

The forward-shift tuning regime 202 of the bidirectional tuning curve 210 illustrates that a controlled positive junction resistance shift can be achieved by laser annealing a Josephson junction at a relatively higher laser anneal power (e.g., about 50 joules or less) for a given anneal time. In the forward-shift tuning regime 202, the junction resistance is shown to monotonically increase over time by applying the appropriate laser anneal power. In some embodiments, the forward-shift tuning regime 202 can be utilized to perform a corrective laser tuning operation to correct for an overshoot (e.g., passed negative target resistance shift) that occurs when tuning a given Josephson junction in the negative tuning regime 201.

The positive tuning regime 203 of the bidirectional tuning curve 210 illustrates that a controlled positive junction resistance shift can be achieved by laser annealing a Josephson junction at a relatively higher laser anneal power (e.g., about 100 joules) for a given anneal time. In the positive tuning regime 203, the junction resistance is shown to monotonically increase to a maximum junction resistance shift (e.g., ΔR=+15.0%) as represented by point 212 on the bidirectional tuning curve 210. In other words, the point 212 represent a maximum positive tuning range (or maximum positive resistance shift) for the exemplary bidirectional tuning curve 210. In addition, FIG. 2A illustrates that the positive tuning regime 203 comprises a tuning rate which corresponds to the slope of the bidirectional tuning curve 210 in the positive tuning regime 203 (e.g., a positive tuning rate corresponding to a positive).

The reverse-shift tuning regime 204 of the bidirectional tuning curve 210 illustrates that a controlled negative junction resistance shift can be achieved by laser annealing a Josephson junction at a relatively higher thermal load (e.g., greater than 100 joules) using, e.g., a laser power level greater than 2.0 watts and an anneal time that is greater than 100 seconds. In the reverse-shift tuning regime 204, the junction resistance is shown to monotonically decrease over time by applying the appropriate laser anneal power and anneal time. In some cases, in the reverse-shift tuning regime 204, the junction resistances of Josephson junctions can continue to decrease in the negative direction until reaching, and even decreasing below, the initial junction resistances of the Josephson junctions. In some embodiments, the reverse-shift tuning regime 204 can be utilized to perform a corrective laser tuning operation to correct for an overshoot (e.g., passed positive target resistance shift) that occurs when tuning a given Josephson junction in the positive tuning regime 203. In particular, the reverse-shift tuning regime 204 can be utilized to correct tuning errors and imprecisions adaptively, by changing the tuning targets within the bounds available with the reverse-shift tuning regime 204. In some instances, the reverse-shift tuning regime 204 may be used at the outset to achieve negative resistance tuning (e.g., −ΔR %), although at the expensive of higher laser powers and anneal times, which can be prohibitive.

FIG. 2B illustrates a graph 220 of a negative tuning regime of a bidirectional tuning curve, according to an exemplary embodiment of the disclosure. In particular, FIG. 2B illustrates a negative tuning curve 221 which represents a negative junction resistance shift (ΔR) % as function of anneal time [s] for a given thermal load (e.g., about 20 joules or less), which can be utilized for tuning a Josephson junction in a negative tuning regime of a bidirectional tuning curve. A thermal load of about 20 joules or less can be achieved, for example, by applying a laser anneal power of about 1.5 W or less for about 10 seconds or less (for a given laser beam illumination pattern). For example, the exemplary negative tuning curve 221 of FIG. 2B represents a negative junction resistance shift (ΔR) % as function of anneal time [s] over period of time from 0 to 10 seconds at a laser anneal power level of 1.1 W.

FIG. 2B illustrates a plurality of points 221a, 221b, 221c, and 221d which define the negative tuning curve 221, where each point 221a, 221b, 221c, and 221d represents a different amount of negative junction resistance shift ΔR that can be achieved for different anneal time when applying the given laser anneal power (e.g., 1.1 W). For example, the point 221a represents a negative junction resistance shift ΔR of about −3.0% can be achieved when applying the given laser anneal power for a period of 1 second. The point 221b represents that a negative junction resistance shift ΔR of about −3.5% can be achieved when applying the given laser anneal power for a period of 2 seconds. The point 221c represents that a negative junction resistance shift ΔR of about −5.0% can be achieved when applying the given laser anneal power for a period of 5 seconds. The point 221d represents that a negative junction resistance shift ΔR of about −6.0% can be achieved when applying the given laser anneal power for a period of 10 seconds. Further, in the exemplary embodiment of FIG. 2B, the point 221d represents a maximum negative junction resistance shift ΔR of about −6.0% (or maximum negative tuning range), which can be achieved based on the given laser power setting and laser beam illumination pattern used to obtain the calibration data for the exemplary negative tuning curve 221.

The exemplary negative tuning curve 221 in FIG. 2B shows that laser tuning a Josephson junction to a target junction resistance can be performed using a negative tuning regime in which the junction resistance monotonically decreases in a predicable manner for a given combination of a laser power setting, an anneal time, and a laser beam illumination pattern. When laser tuning Josephson junction in a negative tuning regime, a relatively low level of laser anneal power would be needed, and could be implemented for tuning Josephson junction based on tuning plans that do not exceed a maximum negative tuning range, e.g., ΔR of about −6.0%, as represented by the exemplary negative tuning curve 221.

FIG. 2C illustrates a graph of positive tuning regimes and reverse-shift tuning regimes of a plurality of calibration curves obtained for different combinations of a plurality of laser power settings and anneal times, according to an exemplary embodiment of the disclosure. In particular, FIG. 2C is a graph 230 of a plurality of calibration curves 231, 232, and 233 which represent an amount of junction resistance shift (ΔR) % as a function of anneal time t_{A} (e.g., discrete anneal times t_{A1}, t_{A2}, t_{A3}, t_{A4}, t_{A5}, and t_{A6}) for different laser power levels (e.g., P₁, P₂, and P₃) with the same laser beam illumination pattern. For example, the first calibration curve 231 (represented by a dashed-dotted line) illustrates an amount of junction resistance shift (ΔR) % obtained for groups of Josephson junctions laser annealed at a low laser power setting P₁ (e.g., 1.80 W) for respective anneal times t_{A1}, t_{A2}, t_{A3}, t_{A4}, t_{A5}, and t_{A6}. The second calibration curve 232 (represented by a dashed line) illustrates an amount of junction resistance shift (ΔR) % obtained for groups of Josephson junctions laser annealed at a medium laser power setting P₂ (e.g., 2.0 W) for respective anneal times t_{A1}, t_{A2}, t_{A3}, t_{A4}, t_{A5}, and t_{A6}, ranging from t_{A1}=2 s to t_{A6}=100 s. The third calibration curve 233 (represented by a solid line) illustrates an amount of junction resistance shift (ΔR) % obtained for groups of Josephson junctions laser annealed at a high laser power setting P₃ (e.g., 2.2 W) for respective anneal times t_{A1}, t_{A2}, t_{A3}, t_{A4}, t_{A5}, and t_{A6}.

Moreover, each point (represented by a square block) of the calibration curves 231, 232, and 233 corresponds to a given group of test Josephson junctions (e.g., 5 test Josephson junctions) and represents an average ΔR % obtained for the given group of test Josephson junctions at a given combination of a laser power setting and anneal time. For example, a point 233a of the calibration curve 233 represents that given group of test Josephson junctions laser annealed at the laser power setting P₃ for anneal time of tai had an average junction resistance shift (ΔR) % of approximately 15%. In this regard, assuming that each point on each of the calibration curves 231, 232, and 233 correspond to a different group of 5 test Josephson junctions, the calibration data shown in FIG. 2C is obtained using 90 test Josephson junctions divided into 18 groups of 5 test Josephson junctions. As further shown in FIG. 2C, each point of the calibration curves 231, 232, and 233 comprises a corresponding error bar (e.g., error bar 233c for point 233a of calibration curve 233) which represents an amount of variability of the ΔR % data obtain for the group of test Josephson junctions calibrated at the given combination of the laser power setting, anneal time, and laser beam illumination pattern, corresponding to the given point.

The calibration curves 231, 232, and 233 illustrate an exemplary tuning progression as a function of anneal time wherein at a given anneal time, progressively faster tuning (i.e., greater average junction resistance shift (ΔR) %) is achieved at higher laser power settings. Further, the calibration curves 231, 232, and 233 illustrate an exemplary maximum positive tuning range that is achieved at each of the given laser power levels P₁, P₂, and P₃. In particular, a point 233b of the calibration curve 233 represents a maximum tuning range of ˜19% that is achieved at the high laser power setting P₃ and anneal time t_{A3}. Further, a point 232a of the calibration curve 232 represents a maximum tuning range of ˜14% that is achieved at the medium laser power setting P₂ and anneal time t_{A4}. Moreover, a point 231a of the calibration curve 231 represents a maximum tuning range of ˜12% that is achieved at the low laser power setting P₁ and anneal time t_{A5}. These calibration tuning curves represent an exemplary tuning progression whereby the maximum tuning range may be dependent upon the anneal power used during the junction tuning process. In general, the tuning range and tuning rate behavior is dependent upon the exact material composition, conformation, fabrication processes, and the like, and is most practically determined through an empirical means such as the calibration method shown in FIG. 2C.

The beginning portions of the calibration curves 231, 2320, and 233, starting from the initial points (at anneal time t_{A1}) up to the points 231a, 232a, and 233b (representing the maximum positive tuning ranges), represent “positive tuning regimes” in which the junction resistances of the Josephson junctions increase with laser annealing. On the other hand, the portions of the calibration curves 231, 232, and 233 following the points 231a, 232a, and 233b represent the reverse-shift tuning regimes in which the junction resistances of the Josephson junction plateau and start to decrease. In some embodiments, when laser tuning Josephson junctions, the positive tuning regimes of the calibration curves 231, 232, and 233 can be utilized for positive tuning of Josephson junction, while the negative-shift tuning regimes of the calibration curves 231, 232, and 233 can be used, e.g., to correct for resistance tuning overshoots resulting from positive tuning error. The calibration data shown in FIG. 2C can be analyzed to generate bidirectional tuning curves using techniques as explained in further detail below.

The exemplary calibration curves 231, 232, and 233 of FIG. 2C show that laser tuning a Josephson junction to a target junction resistance can be performed using a positive tuning regime in which the junction resistance monotonically increases in a predicable manner for a given combination of a laser power setting, an anneal time, and a laser beam illumination pattern. In particular, laser tuning a Josephson junction in the positive tuning regime can be performed using intermediate thermal loads, e.g., from about 20 joules to about 200 joules. Such intermediate thermal loads can be achieved, for example, using laser anneal power levels of about 2 W in a range of about 1 second to about 100 seconds. The positive tuning regimes of the exemplary calibration curves 231, 232, and 233 of FIG. 2C show that different laser power levels can be used to accelerate or decelerate the tuning (e.g., using a higher laser power level for faster tuning). Further, the exemplary calibration curve 233 of FIG. 2C shows that a maximum positive junction resistance shift ΔR (or maximum positive tuning range) of ΔR ˜18% can be achieved using the higher laser power level P₁.

Next, FIG. 2D illustrates a graph 240 of a reverse-shift tuning regime of a bidirectional tuning curve, according to an exemplary embodiment of the disclosure. In particular, FIG. 2D illustrates a reverse-shift tuning curve 241 which represents a negative junction resistance shift (−ΔR) % as function of anneal time [s] for a given thermal load (e.g., greater than 200 joules), which can be utilized for negative resistance shift tuning a Josephson junction (e.g., correcting for overshoots in a positive tuning regime. The exemplary reverse-shift tuning curve 241 comprises a plurality of points (represented as circles) at respective anneal times. Each point on the reverse-shift tuning curve 241 represents an average of the ΔR % calibration data for a group of 5 test Josephson junctions that were annealed at the same combination of laser power setting, anneal time, and laser beam illumination pattern. The reverse-shift tuning curve 241 represents calibration data that was obtained by performing laser anneal operations for groups of Josephson junctions at a laser power level of 2.3 W but at different anneal times from about 20 seconds to 1000 seconds. The exemplary reverse-shift tuning curve 241 in FIG. 2D shows that laser tuning a Josephson junction to a target junction resistance can be performed using a negative-shift tuning regime in which the junction resistance monotonically decreases in a predicable manner for a given combination of a laser power setting, anneal time, and laser beam illumination pattern, under relatively high thermal loads e.g., greater than 200 joules.

In some embodiments, as noted above, tuning calibration data is generated based on, e.g., different laser beam illumination patterns. The different laser beam illumination patterns can be used for various purposes. For example, different laser beam illumination patterns provide different thermal profiles for laser annealing, wherein the different laser beam illumination patterns can be used during calibration operation to achieve different laser tuning curves for quantum devices (e.g., qubits) having the same Josephson junction geometry. In addition, different laser beam illumination patterns can be used to provide different thermal profiles for laser annealing quantum devices (e.g., qubits) which have different Josephson junction geometries. FIGS. 3A-3G schematically illustrate different types of laser illumination patterns that can be used to provide different thermal profiles for laser annealing and tuning quantum devices (e.g., quantum bits) that have different Josephson junction geometries, according to exemplary embodiments of the disclosure.

For example, FIG. 3A schematically illustrates a process 300 for laser annealing a quantum device using a laser beam illumination pattern, according to an exemplary embodiment of the disclosure. In particular, FIG. 3A illustrates an exemplary FOV 310, a superconducting qubit 320, and a quad-spot laser beam pattern 330. In some embodiments, the FOV 310 represents the area of the object that is imaged by the microscope unit 130 (FIG. 1), wherein the size of the FOV is generally determined by the magnification of the objective lens 137. In the exemplary camera-objective architecture of the microscope unit 130, the FOV of the objective lens is applied to an image sensor (e.g., focal plane array) of the camera 132. Since the image sensor is rectangular in shape, the images captured by the microscope unit 130 have a rectangular FOV, as shown in FIG. 3A, which does not capture the full circular FOV from the objective lens 137.

In FIG. 3A, the superconducting qubit 320 comprises a transmon qubit comprising a capacitor and Josephson junction connected in parallel. In particular, the superconducting qubit 320 comprises a first superconducting pad 321, a second superconducting pad 322, and a Josephson junction 323 coupled to, and disposed between, the first and second superconducting pads 321 and 322. The first and second superconducting pads 321 and 322 comprise electrodes of a coplanar parallel-plate capacitor structure of the superconducting qubit 320. The Josephson junction 323 functions as a non-linear inductor which, when shunted with the capacitor formed by the first and second superconducting pads 321 and 322, forms an anharmonic LC oscillator with individually addressable energy levels (e.g., two lowest energy level corresponding to the ground state |0 [symbol] and the first excited state |1 [symbol] ) with a given transition frequency f₀₁.

FIG. 3A schematically illustrates an exemplary laser anneal process 300 for tuning the resistance of the Josephson junction 323 using a quad-spot laser beam pattern 330. The quad-spot laser beam pattern 330 comprises four (4) spots which correspond to, e.g., four laser beams generated by the laser beam shaper 135 (FIG. 1) implemented using a 2-by-2 diffractive beam splitter generate 4 laser beams that are projected onto the surface of the quantum chip 160 via the microscope unit 130. The quad-spot laser beam pattern 330 comprises two laser spots 331 positioned on one side (e.g., above) of the Josephson junction 323, and two laser spots 332 positioned on an opposite side (e.g., below) the Josephson junction 323. The quad-spot laser beam pattern 330 is configured to illuminate (and heat) regions of the upper surface of the quantum chip 160 in proximity to the Josephson junction 323, but not directly illuminate the Josephson junction 323. In other embodiments, other types of laser beam illumination patterns can be utilized to laser anneal the Josephson junction 323. For example, the different laser beam illumination patterns include, e.g., a 1-spot pattern, a 2-spot pattern, 3-spot pattern, a 6-spot pattern, etc., depending on the application and/or the geometry of the features that are being laser annealed.

For example, FIG. 3B schematically illustrates a process 301 for laser annealing a quantum device using a laser beam illumination pattern, according to another exemplary embodiment of the disclosure. It is to be noted that FIG. 3B is similar to FIG. 3A except that FIG. 3B schematically illustrates an exemplary dual-spot laser beam pattern 340 which comprises a first laser beam spot 341 positioned on one side (e.g., above) of the Josephson junction 323, and a second laser beam spot 342 positioned on an opposite side (e.g., below) the Josephson junction 323. The dual-spot laser beam illumination pattern 340 is configured to illuminate (and heat) regions of the upper surface of the quantum chip 160 in proximity to the Josephson junction 323, but not directly illuminate the Josephson junction 323.

Next, FIG. 3C schematically illustrates a process 302 for laser annealing a quantum device using a laser beam illumination pattern, according to another exemplary embodiment of the disclosure. It is to be noted that FIG. 3C is similar to FIG. 3B in that FIG. 3C schematically illustrates an exemplary dual-spot laser beam illumination pattern 350 which comprises a first laser beam spot 351 positioned on one side (e.g., above) of the Josephson junction 323, and a second laser beam spot 352 positioned on an opposite side (e.g., below) the Josephson junction 323. However, the first and second laser beam spots 351 and 352 of the dual-spot laser beam illumination pattern 350 are larger in diameter than the first and second laser beam spots 341 and 342 of the dual-spot laser beam pattern 340 of FIG. 3B. In this regard, the first and second laser beam spots 351 and 352 of the laser beam illumination pattern 350 are configured to directly illuminate (and heat) a large area of the substrate surface on opposing sides of the Josephson junction 323.

Further, FIG. 3D schematically illustrates a process 303 for laser annealing a quantum device using a laser beam illumination pattern, according to another exemplary embodiment of the disclosure. FIG. 3D schematically illustrates an exemplary annular laser beam illumination pattern 360 (or ring-shaped laser beam illumination pattern) which is configured to illuminate (heat) a ring-shaped area that surrounds the Josephson junction 323, but without directly illuminating the Josephson junction 323 with laser energy. In some embodiments, such an annular laser beam illumination pattern may be achieved using a spiral phase plate with a selected topological charge to engineer the relative dimensions of the annulus.

It is to be noted that while FIGS. 3A, 3B, 3C and 3D schematically illustrate a superconducting qubit 320 comprising a single Josephson junction 323, other types of superconducting qubits or quantum devices can have two or more Josephson junctions, wherein the two or more Josephson junctions can be laser annealed concurrently using a suitable laser illumination pattern. For example, some quantum devices, such as tunable qubits or qubits couplers, comprise a SQUID, wherein the SQUID comprises a pair of Josephson junctions which are connected in parallel to form a superconducting loop (referred to as SQUID loop) through which an external magnetic flux ϕ can be threaded to tune the operations of the quantum devices. In this regard, the Josephson junctions of a SQUID can be laser annealed and tuned concurrently by utilizing a suitable laser illumination pattern that is configured to heat the substrate regions surrounding the two Josephson junctions of the SQUID.

For example, FIG. 3E schematically illustrates a process 304 for laser annealing a quantum device using a laser beam illumination pattern, according to another exemplary embodiment of the disclosure. In particular, FIG. 3E illustrates an exemplary flux-tunable superconducting qubit 320-1 which is similar to the superconducting qubit 320 of FIGS. 3A-3D, except that flux-tunable superconducting qubit 320-1 comprises two Josephson junctions 323 and 324 which collectively comprise a SQUID, and are connected in parallel between the first and second superconducting pads 321 and 322 to form a superconducting loop through which a magnetic flux is threaded to tune the operating frequency of the flux-tunable superconducting qubit 320-1. In addition, FIG. 3E schematically illustrates an exemplary three-spot laser beam illumination pattern 370 which comprises a first laser beam spot 371 positioned on one side (e.g., above) of the Josephson junction 323, and a second laser beam spot 372 positioned between the two Josephson junctions 323 and 324, and a third laser beam spot 373 positioned on an opposite side (e.g., below) the Josephson junction 324. In this regard, the three-spot laser beam pattern 370 is implemented and configured to concurrently laser tune the two Josephson junctions 323 and 324 of the flux-tunable superconducting qubit 320-1.

Next, FIG. 3F schematically illustrates a process 305 for laser annealing a quantum device using a laser beam illumination pattern, according to another exemplary embodiment of the disclosure. In particular, FIG. 3F illustrates process 305 for laser annealing the exemplary flux-tunable superconducting qubit 320-1 using a quad-spot laser beam pattern 380 in which a pattern of four laser beam spots is positioned between the two Josephson junctions 323 and 324. In this regard, the quad-spot laser beam pattern 380 is implemented and configured to concurrently laser tune the two Josephson junctions 323 and 324 of the flux-tunable superconducting qubit 320-1.

Moreover, FIG. 3G schematically illustrates a process 306 for laser annealing a quantum device using a laser beam illumination pattern, according to another exemplary embodiment of the disclosure. In particular, FIG. 3G illustrates process 306 for laser annealing the exemplary flux-tunable superconducting qubit 320-1 using a dual-annular laser beam pattern 390 which comprises a first annular laser beam pattern 391 and a second annular laser beam pattern 392. As schematically shown in FIG. 3G, the first annular laser beam pattern 391 is configured and positioned to surround the first Josephson junction 323, and the second annular laser beam pattern 392 is configured and positioned to surround the second Josephson junction 324. In this regard, the dual-annular laser beam pattern 390 can be implemented and configured to concurrently laser tune the first and second Josephson junctions 323 and 324 of the flux-tunable superconducting qubit 320-1.

It is to be appreciated that a wide variety of laser illumination patterns and geometries can be implemented for laser annealing and tuning Josephson junctions that occur in various geometries, e.g., single-junction or multi-junction configurations for a variety of quantum devices, e.g., fixed-frequency superconducting qubits, flux-tunable superconducting qubits, flux-tunable couplers that control interactions between quantum bits, etc. The exemplary laser beam illumination geometries shown in FIGS. 3A-3G are configured to provide different thermal profiles for laser annealing and tuning Josephson junction with different power levels depending on the illumination geometry. For example, comparing the exemplary illumination geometries of FIGS. 3A and 3B, the exemplary quad-spot laser beam pattern 330 in FIG. 3A has the benefit of providing a more stable thermal profile in the vicinity of the junction as compared to the dual-spot laser beam pattern 340 of FIG. 3B, due to a more even spatial distribution of laser spots around the junction. However, the dual-spot laser beam may be utilized with a lower laser energy level as compared to the quad-spot laser beam pattern 330 of FIG. 3A, as the exemplary quad-spot laser beam pattern 330 comprises additional laser spots to distribute and apply laser energy over a wider area, which therefore requires more laser power to achieve the same temperature in the vicinity of the Josephson junction 323. In any event, the resistance of a Josephson junction may be adjusted to a target junction resistance by a number of factors including, e.g., laser power, exposure time, laser illumination pattern, laser-to-junction alignment, all of which is precisely controlled for proper laser tuning. In this regard, the exemplary calibration techniques as discussed herein are configured to generate calibration data for different combinations of a plurality of laser power settings, anneal times, and laser beam illumination patterns, to enable proper selection of laser tuning calibration parameter for precise laser tuning of Josephson junctions.

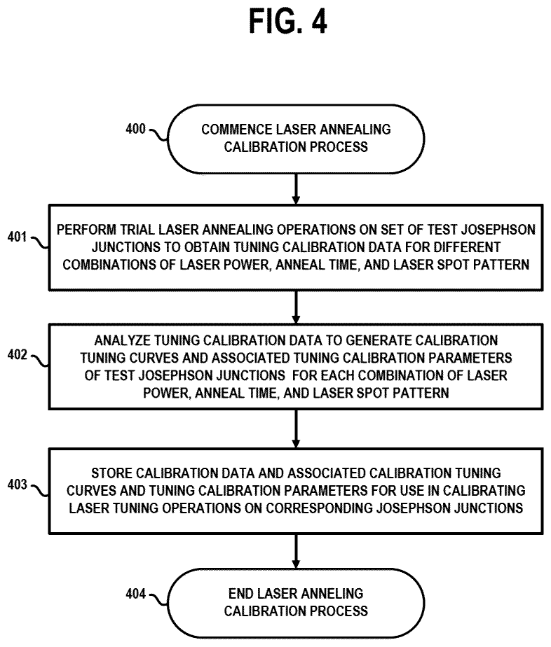

As noted above, the exemplary calibration techniques as discussed herein are configured to obtain tuning calibration data by performing trial laser anneal operations on representative hardware comprising Josephson junction (e.g., qubits with Josephson junctions), and utilize the tuning calibration data to determine various laser tuning calibration parameters including, e.g., tuning rates and maximum tuning ranges for various combinations of different laser power settings, anneal times, and laser beam illumination patterns, to enable bidirectional tuning of Josephson junctions. For example, FIG. 4 illustrates a flow diagram of a calibration process for obtaining calibration data for use in bidirectional laser tuning of Josephson junctions, according to an exemplary embodiment of the disclosure. In some embodiments, FIG. 4 illustrates a calibration process that can be performed using the laser annealing system 100 of FIG. 1 with the control system 110 executing a calibration algorithm.

Referring to FIG. 4, a quantum chip is placed on the X-Y-Z stage 142 of the prober unit 140, and the control system 110 commences an automated calibration process (block 400). The quantum chip comprises a set of test Josephson junctions which are representative of actual Josephson junctions that are to be laser tuned using the calibration data obtained from the calibration process. In some embodiments, the quantum chip is a test chip, e.g., a sister chiplet from a same wafer having quantum devices and Josephson junctions that were fabricated using the same fabrication processes (e.g., junction evaporation process) as the Josephson junctions on the actual quantum chip. In this regard, the Josephson junctions on the test chip (e.g., sister chiplet) are deemed to correspond to the Josephson junctions on the actual chip which are to be tuned by laser annealing operations that are configured using the calibration data obtained from the calibration operations performed on the test Josephson junctions on the test chip, since the test Josephson junctions and the actual Josephson junctions are fabricated using the same or similar processes. In this regard, the test Josephson junctions are assumed to have the same, or substantially the same, or similar laser tuning characteristics as the Josephson junctions on the actual chip which are to be tuned by laser annealing operations that are configured using the calibration data obtained from the calibration operations performed on the test Josephson junctions on the test chip.

In other embodiments, the calibration process may be implemented using a collection of test Josephson junction devices that reside on the same quantum chip which has the actual Josephson junctions that are to be tuned. For example, the collection of Josephson junctions can be a dedicated test array of Josephson junctions that are formed on the quantum chip and located, e.g., in the kerf of the quantum chip. In this regard, the collection of test Josephson junctions on the quantum chip correspond to the actual Josephson junctions on the same quantum chip, which are to be laser tuned by laser annealing operations that are configured using the calibration data obtained from the calibration operations performed on the test Josephson junctions on the same quantum chip. Since the collection of test Josephson junctions and the actual Josephson junctions (residing on the same quantum chip) are fabricated using the same fabrication processes, the test Josephson junctions and actual Josephson junction (to be laser tune) will have the same, or substantially the same, or similar tuning characteristics.

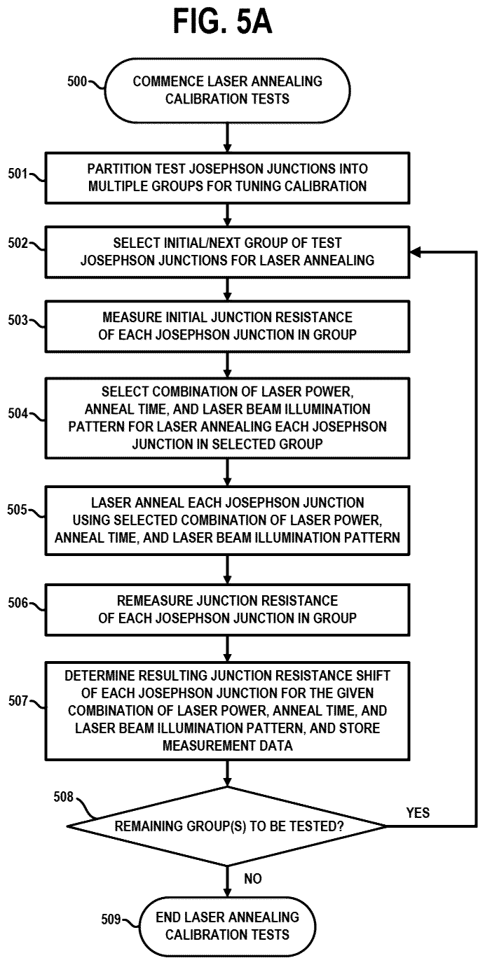

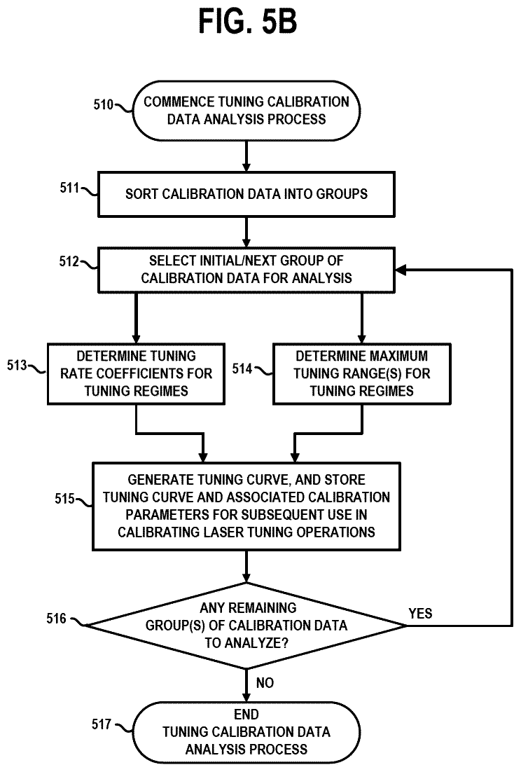

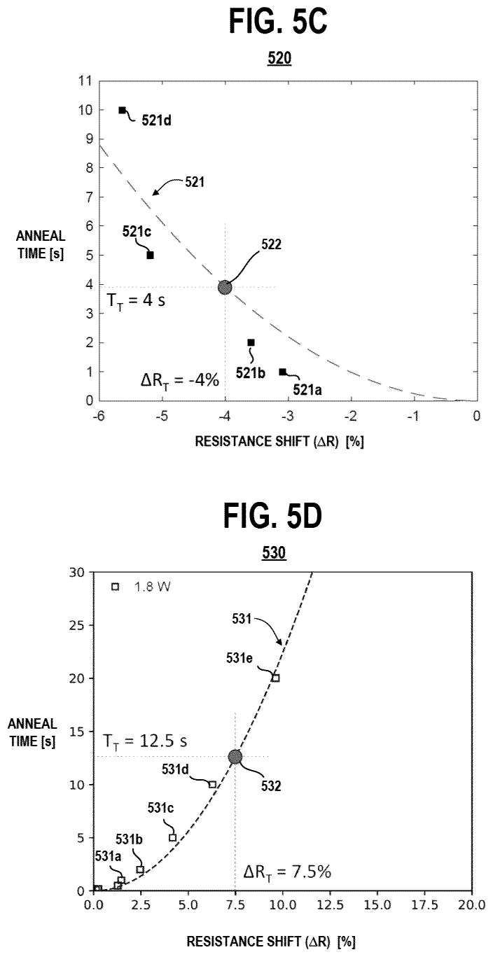

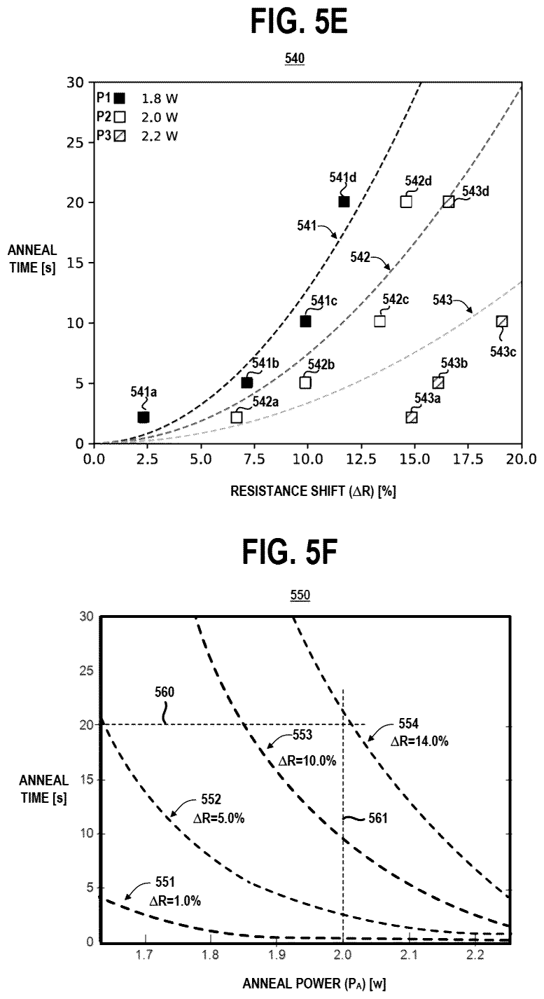

The calibration process proceeds by performing a series of trial laser anneal operations on a set of test Josephson junctions to obtain calibration data for different combinations of a plurality of laser power settings, anneal times, and laser beam illumination patterns (block 401). For example, in some embodiments, the calibration process is performed by selecting a plurality of discrete laser power settings, e.g., 1.2 watts (W), 1.60 W. 1.80 W, and 2.0 W, and a plurality of anneal times for each laser power setting, e.g., a set of anneal times 0.5 s, 1.0 s, 2.0 s, 5.0 s, 10.0 s, 20.0 s, and 100 s for each of the discrete laser power settings (e.g., 1.60 watts at anneal times of 0.5 s, 1.0 s, 2.0 s, 5.0 s, 10.0 s, 20.0 s, and 100 s, etc.). In addition, in some embodiments, each power/anneal time combination for the calibration process is performed using two or more different laser beam illumination patterns. For each combination of laser power, anneal time, and laser beam illumination pattern, laser annealing operations are performed on a respective group of trial Josephson junctions (e.g., 3-10 Josephson junctions per group) to obtain a statistically significant amount of tuning calibration data. An exemplary calibration process for laser annealing the collection of test Josephson junctions to obtain tuning calibration data will be discussed in further detail below in conjunction with FIG. 5A.

The calibration process analyzes the tuning calibration data to generate calibration tuning curves (e.g., bidirectional tuning curves) and associated calibration parameters (e.g., maximum tuning ranges, tuning rates, etc.) for the test Josephson junctions, for each combination of laser power, anneal time, and laser beam illumination pattern (block 402). As explained in further detail below, the tuning curves and associated calibration parameters for respective combinations of laser power/anneal time/laser beam illumination pattern, provide information to enable bidirectional tuning (e.g., negative resistance shift tuning, positive resistance shift tuning) in different tuning regimes (e.g., tuning regimes 210, 202, 203, and 204, FIG. 2A). The calibration data, calibration tuning curves and associated calibration parameters (e.g., maximum tuning ranges, tuning rates, etc.) for each respective combination of laser power, anneal time, and laser beam illumination pattern are persistently stored (block 403) and the calibration process terminates (block 404). The persistently stored tuning curves and calibration parameters are subsequently utilized for calibrating laser tuning operations that are to be performed on Josephson junctions to tune the respective junction resistances to respective target junction resistances, using laser tuning processes discussed in further detail below.

FIGS. 5A and 5B illustrate a flow diagram of a calibration process for obtaining calibration data for use in bidirectional laser tuning of Josephson junctions, according to another exemplary embodiment of the disclosure. The calibration process flow of FIGS. 5A and 5B is based on the high-level calibration process flow of FIG. 4. In particular, FIG. 5A illustrates an exemplary process for performing laser annealing calibration tests on Josephson junction to obtain calibration data, and FIG. 5B illustrates an exemplary process for analyzing the calibration data (obtained from the laser annealing calibration tests) to determine/generate bidirectional tuning curves and associated calibration parameters (e.g., maximum tuning ranges, tuning rates, etc.) for different combinations of laser power settings, anneal times, and laser beam illumination patterns. In some embodiments, FIG. 5A illustrates laser annealing calibration tests that can be performed using the laser annealing system 100 of FIG. 1 with the control system 110 executing a calibration algorithm.

In particular, referring now to FIG. 5A, a quantum chip is placed on the X-Y-Z stage 142 of the prober unit 140, and the control system 110 commences a calibration process to perform automated laser annealing calibration tests (block 500). As noted above, the quantum chip comprises a collection of test Josephson junctions which are representative of actual Josephson junctions that are to be laser tuned using the calibration data obtained from the calibration process, wherein the quantum chip can be a sister chiplet or a quantum chip having a collection of test Josephson junctions that reside (e.g., in a kerf region) on the same quantum chip which has the Josephson junctions that are to be tuned.

The collection of test Josephson junctions are partitioned into multiple groups for tuning calibration (block 501). The number of groups will correspond to the number of different combinations of discrete laser power settings, anneal times, and laser beam illumination patterns that are selected for the laser annealing calibration tests. For example, assuming that the laser annealing calibration tests are performed using four (4) discrete laser power settings, P₁, P₂, P₃, and P₄ (e.g., P₁=1.20 W, P₂=1.80 W, P₃=2.0 W, P₄=2.2 W), seven (7) different anneal times (e.g., 0.5 s, 1.0 s, 2.0 s, 5.0 s, 10.0 s, 20.0 s, and 100 s) for each discrete laser power setting, and two (2) different laser beam illumination patterns for each combination of laser power setting and anneal time, the collection of test Josephson junctions would be partitioned into (4×7×2) 56 test groups, wherein each test group would have a desired number of test Josephson junctions (e.g., 3, 4, 5, 6, 7 etc.) to obtain a given amount of calibration data with statistical significance. In some embodiments, the different combinations of power level settings, anneal times, and laser beam illumination patterns would be selected to obtain sufficient calibration data to determine calibration parameters for, e.g., the four exemplary tuning regions as shown in FIG. 2A, including a negative tuning region, a forward-shift tuning region, a positive tuning region, and a reverse-shift tuning region, to thereby enable bidirectional laser tuning of Josephson junctions.

The calibration process selects an initial group of test Josephson junctions for laser annealing to obtain calibration data (block 502) and proceeds to perform in-situ resistance measurements to measure an initial junction resistance (Rᵢₙᵢₜᵢₐₗ) of each test Josephson junction of the given group (block 503). For example, in some embodiments, the in-situ resistance measurements are performed using a 4-wire (Kelvin) resistance measurement process, as discussed in further detail below. The calibration process selects a given combination of laser power, anneal time, and laser beam illumination pattern for laser annealing each test Josephson junction in the selected group (block 504). For example, for a given calibration iteration, the calibration process can select the low laser power setting P₁, anneal time t_{A1}=0.5 s, and a first type of laser beam illumination pattern (e.g., quad-spot laser beam pattern 330, FIG. 3A) as the initial selection, wherein for each subsequent calibration iteration on remaining groups test Josephson junction, the calibration process can select a different combination of laser power setting, anneal time, and laser beam illumination pattern (e.g., e.g., laser power setting P₁, anneal time t_{A2}=1.0, quad-spot laser beam pattern, and so on).

The calibration process proceeds to laser anneal each test Josephson junction of the given group, in succession, at the selected combination of laser power, anneal time, and laser beam illumination pattern (block 505). Next, in-situ resistance measurements are performed to remeasure the junction resistances of each test Josephson junction of the given group to determine the current junction resistance R_{current} of each test Josephson junctions following the laser anneal operations (block 506). In some embodiments, a given time delay is imposed after the laser annealing operations (block 505) before remeasuring the junction resistances (block 606) to allow the test Josephson junctions to settle to a stable resistance state following the completion of a laser annealing of the test Josephson junctions. The time delay can be on the order of, e.g., a minute (or minutes), or an hour (or hours), etc., or any time as needed to allow the test Josephson junctions to settle to a stable resistance state following the completion of a laser annealing.

Following the resistance remeasurements (block 506), the resistance measurement data (e.g., Rᵢₙᵢₜᵢₐₗ and R_{current}) for each test Josephson junctions of the given group is used to determine an amount of junction resistance shift that occurs as a result of the laser annealing the test Josephson junctions at the given combination of laser power, anneal time, and laser beam illumination patter (block 507). For example, as noted above, in some embodiments, the amount of junction resistance shift ΔR for a given test Josephson junction is determined as: ΔR=R_{current}−Rᵢₙᵢₜᵢₐₗ (and with a “resistance shift percentage” determined as:

$$Δ R \% = \frac{Δ R}{{R}_{i n i t i a l}} \times 100 \% ) .$$

The resistance measurement data (e.g., Rᵢₙᵢₜᵢₐₗ, R_{current} and computed ΔR) for each test Josephson junction at the given combination of laser power, anneal time, and laser beam illumination pattern is stored (block 507) for subsequent access and analysis. In some embodiments, the calibration process computes an average of the measured junction resistance shift percentages ΔR % for all Josephson junctions in the group, wherein the average junction resistance shift percentage ΔR_{avg} % is stored for subsequent calibration analysis.

Next, the calibration process determines whether there are one or more remaining groups of test Josephson junctions to perform laser annealing calibration tests using other combinations of laser power, anneal time, and laser beam illumination pattern (block 508). If there are one or more are one or more remaining groups of test Josephson junctions to be tested (affirmative determination in block 508), the calibration process selects a next group of test Josephson junctions (return to block 502) and repeats the laser annealing calibration test (repeat block 503, 504, 505, 506, and 507) on the next selected group of test Josephson junctions using a next selected combination of laser power, anneal time, and laser beam illumination pattern. On the other hand, if there are no remaining groups of test Josephson junctions to be tested (negative determination in block 508), the laser annealing calibration tests are ended (block 509).

At the completion of the laser annealing calibration tests of FIG. 5A, the calibration process comprises a collection of computed ΔR data or ΔR % data, which is utilized to compute calibration tuning parameters/metrics, e.g., (i) compute tuning curves that represent tuning rates of the test Josephson junctions for the each of the laser power settings as a function of anneal time (for different laser beam illumination patterns), and (ii) determine maximum tuning ranges (e.g., maximum negative ΔR % (of negative tuning regime) and maximum positive ΔR % (of positive tuning regime)) for each of the laser power settings. For example, referring to FIG. 5B, the calibration process commences a tuning calibration data analysis process (block 510) to compute tuning curves and calibration parameters for each of the laser power settings and associated laser beam illumination patterns.

As an initial step, the calibration process accesses and sorts the calibration data acquired for each test group of Josephson junctions into groups of calibration data (block 511). For example, in some embodiments, for each combination of laser power setting and laser beam illumination pattern, the calibration process aggregates the resistance shift data resulting from laser annealed groups of test Josephson junctions at each of the different anneal times but at the same combination of laser power setting and laser beam illumination pattern. In other words, this sorting process results in multiple groups of calibration data for analysis, where each group of calibration data comprises an aggregation of the resistance shift data of test Josephson junctions obtained from performing laser annealing operations on the test Josephson junctions for the various laser anneal times at a given combination of laser power setting and laser beam illumination pattern. The sorting of the calibration data into groups of calibration data allows the calibration data to be fitted to tuning curves (e.g., bidirectional tuning curves) for each combination of laser power setting and laser beam illumination pattern for use in calibrating laser tuning operation.

The calibration process selects an initial (or next) group of calibration data for analysis (block 512). For example, the initial group of calibration data can include the resistance shift data (ΔR data) associated with groups of test Josephson junctions that were laser annealed using the same combination of power level setting (e.g., P₁=1.20 W) and laser beam illumination pattern (e.g., quad-spot laser beam pattern), but at different anneal times (e.g., 0.5 s, 1.0 s, 2.0 s, 5.0 s, 10.0 s, 20.0 s, and 100 s). The group of calibration data is analyzed to determine tuning rate coefficients for one or more tuning regimes for the given combination of laser power setting and laser beam illumination pattern (block 513) and to determine maximum tuning ranges for one or more tuning regimes for the given combination of laser power setting and laser beam illumination pattern (block 514). In some embodiments, the tuning rate coefficients and maximum tuning ranges are determined based average junction resistance shift percentage data (ΔR_{avg} %) that is computed using the measured junction resistance shift percentage data (ΔR %) of the test Josephson junctions, for each of the different anneal times at the given combination of laser power setting and laser beam illumination pattern.

For example, assume that the given group of calibration data comprises the ΔR % data for the test Josephson junctions that were laser annealed at the same power level setting (e.g., P₁=1.20 W) and laser beam illumination pattern (e.g., quad-spot laser beam pattern). The measured ΔR % data for each of the test Josephson junctions that were laser annealed with an anneal time of 0.5 s (at the given combination of power level setting (e.g., P₁=1.20 W) and laser beam illumination pattern (e.g., quad-spot laser beam pattern)) is utilized to determine the ΔR_{avg} % for the given anneal time 0.5 s at the given combination of power level setting and laser beam illumination pattern. In addition, the measured ΔR % data for each of the test Josephson junctions that were laser annealed with an anneal time of 1.0 s (at the given combination of power level setting (e.g., P₁=1.20 W) and laser beam illumination pattern (e.g., quad-spot laser beam pattern)) is utilized to determine the ΔR_{avg} % for the given anneal time of 1.0 s at the given combination of power level setting and laser beam illumination pattern. The same ΔR_{avg} % is computed for the remaining anneal times (e.g., 2.0 s, 5.0 s, 10.0 s, 20.0 s, and 100 s) the corresponding ΔR % data for the groups of test Josephson junctions that were laser annealed with at the corresponding anneal times.

The ΔR_{avg} % data of the Josephson junctions, which is determined (from the calibration data ΔR %) for each of the different laser anneal times for the same combination of laser power setting and laser beam illumination pattern, is utilized to determine tuning rates for one or more tuning regimes (e.g., negative tuning region and/or positive tuning regime, etc.), as well as determine maximum tuning ranges (e.g., maximum negative tuning range and/or maximum positive tuning range). In some embodiments, the maximum negative tuning range for a given combination of laser power setting and laser beam illumination pattern corresponds to the greatest negative ΔR_{avg} % obtained for a given group of test Josephson for a given anneal time at the given combination of laser power setting and laser beam illumination pattern. Similarly, the maximum positive tuning range for a given combination of laser power setting and laser beam illumination pattern corresponds to the greatest positive ΔR_{avg} % obtained for a given group of test Josephson for a given anneal time at the given combination of laser power setting and laser beam illumination pattern.

Furthermore, in some embodiments, the ΔR_{avg} % parameters for the respective anneal times (at the given combination of power level setting and laser beam illumination pattern) each represent a tuning rate coefficient corresponding to a given anneal time for the given combination of power level setting and laser beam illumination pattern. The tuning rate coefficients of the different ΔR_{avg} % parameters within a given tuning regime (e.g., positive tuning regime) can be utilized to estimate a tuning rate for the given tuning regime.

In some embodiments, the ΔR_{avg} % parameters that are determined for the different anneal times at the given combination of power level setting and laser beam illumination pattern are utilized to compute a tuning curve (e.g., bidirectional tuning curve) for the given combination of laser power setting and laser beam illumination pattern. For example, in some embodiments, the tuning curve for a given laser power setting is determined using a curve fitting process to fit the ΔR_{avg} % data points of the different anneal times for the given laser power setting to a curve using a polynomial curve fitting process (e.g., a second order (or higher order) polynomial curve fitting process). In other embodiments, the tuning curve for a given laser power setting is determined using a nonlinear regression process to fit the ΔR_{avg} % data points for the given laser power setting to a curve using, for example, a logarithmic, or inverse exponential curve. Moreover, in some embodiments, the maximum tuning range(s) (e.g., maximum negative and/or positive tuning range) for the given combination laser power setting and laser beam illumination pattern can be determined using an interpolation function (polynomial, logarithmic, or the like) where the maximum value(s) may be extracted from the extrema(s) of the tuning curve that is computed using a linear or nonlinear regression curve fitting process.

In some embodiments, the calibration process utilizes the ΔR_{avg} % data points of the different anneal times for the given combination of power level setting and laser beam illumination pattern to generate a tuning curve (e.g., bidirectional tuning curve) for the given combination of power level setting and laser beam illumination pattern. The calibration process persistently stores the tuning curve and associated calibration parameters (e.g., tuning rate coefficients and maximum tuning ranges) that are derived from the ΔR_{avg} % data, for subsequent use in calibrating laser tuning operations (block 515). For example, in some embodiments, the tuning curve and associated calibration parameters are stored in a database of calibration data (e.g., database of bidirectional laser tuning calibration data 115, FIG. 1).

If there are any remaining groups of calibration data to be analyzed (affirmative determination in block 516), the calibration process selects the next group of calibration data for analysis (return to block 512), and the process steps 513, 514, and 515 are repeated for the next selected group of calibration data. The tuning calibration data analysis process terminates (block 517) after all groups of calibration data have been analyzed. At the completion of the tuning calibration data analysis process, the tuning calibration database can have computed tuning curves associated calibration parameters for each combination of laser power setting and laser beam illumination pattern.

FIGS. 5C, 5D, 5E, and 5F are graphs which illustrate tuning curves that can be generated using calibration data, according to exemplary embodiments of the disclosure. For example, FIG. 5C is a graph 520 which illustrates an exemplary calibration tuning curve 521 for a negative tuning regime, according to an exemplary embodiment of the disclosure. In particular, the graph 520 depicts the exemplary calibration tuning curve 521 providing a negative junction resistance shift (ΔR %) as a function of anneal time (s) for a given combination of laser power level (e.g., 1.2 W) and laser beam illumination pattern (e.g., quad-spot laser beam pattern). In an exemplary embodiment, the calibration tuning curve 521 is computed using a curve fitting process to fit a plurality of ΔR_{avg} % data points 521a, 521b, 521c, and 521d to a polynomial curve using a second order polynomial curve fitting process. In particular, in some embodiments, each data point 521a, 521b, 521c, and 521d corresponds to a respective ΔR_{avg} % that is computed from a collection of ΔR % calibration data obtained for respective groups of test Josephson junctions that were laser annealed for the anneal times 1.0 s, 2.0 s, 5.0 s, and 10.0 s, respectively, for the given combination of laser power setting and laser beam illumination pattern.

In other words, by way of example, the data point 521a represents the ΔR_{avg} % that is computed using the ΔR % calibration data obtained for a group of test Josephson junctions that were laser annealed for an anneal time of 1.0 s using the given combination of combination of laser power setting and laser beam illumination pattern. Similarly, the data point 521b represents the ΔR_{avg} % that is computed using the ΔR % calibration data obtained for a group of test Josephson junctions that were laser annealed for the anneal time of 2.0 s using the given combination of combination of laser power setting and laser beam illumination pattern.

FIG. 5C illustrates an exemplary point 522 on the calibration tuning curve 521, which intersects the X-axis at a value of ΔR %=−4.0, and which intersects the Y-axis at an anneal time of 4.0 s. In this regard, FIG. 5C illustrates an exemplary process for utilizing the calibration tuning curve 521 in a negative tuning regime to determine that performing a laser tuning process on a given Josephson junction for target anneal time (T_{T}) of about 4.0 seconds at the given combination of laser power setting and laser beam illumination pattern (represented by the calibration tuning curve 521) will result in a target resistance shift of ΔR %=−4.0 of the junction resistance of the given Josephson junction.

Next, FIG. 5D is a graph 530 which illustrates an exemplary calibration tuning curve 531 for a positive tuning regime, according to an exemplary embodiment of the disclosure. In particular, the graph 530 depicts the exemplary calibration tuning curve 531 providing a positive junction resistance shift (ΔR %) as a function of anneal time (s) for a given combination of laser power level (e.g., 1.8 W) and laser beam illumination pattern (e.g., quad-spot laser beam pattern). In an exemplary embodiment, the calibration tuning curve 531 is computed using a curve fitting process to fit a plurality of ΔR_{avg} % data points, e.g., data points 531a, 531b, 531c, 531d, and 531e to a polynomial curve using a second order polynomial curve fitting process. In particular, in an exemplary embodiment, each data point 531a, 531b, 531c, 531d, and 531e corresponds to a respective ΔR_{avg} % that is computed from a collection of ΔR % calibration data obtained for respective groups of test Josephson junctions that were laser annealed for the anneal times 1.0 s, 2.0 s, 5.0 s, 10.0 s, and 20.0 s, respectively, for the given combination of laser power setting and laser beam illumination pattern.

In other words, by way of example, the data point 531a represents the ΔR_{avg} % that is computed using the ΔR % calibration data obtained for a group of test Josephson junctions that were laser annealed for an anneal time of 1.0 s using the given combination of combination of laser power setting and laser beam illumination pattern. Similarly, the data point 531b represents the ΔR_{avg} % that is computed using the ΔR % calibration data obtained for a group of test Josephson junctions that were laser annealed for the anneal time of 2.0 s using the given combination of combination of laser power setting and laser beam illumination pattern.

FIG. 5D illustrates an exemplary point 532 on the calibration tuning curve 531, which intersects the X-axis at a value of ΔR %=7.5, and which intersects the Y-axis at an anneal time of 12.5 s. In this regard, FIG. 5D illustrates an exemplary process for utilizing the calibration tuning curve 531 in a positive tuning regime to determine that performing a laser tuning process on a given Josephson junction for a target anneal time of about 12.5 seconds at the given combination of laser power setting and laser beam illumination pattern (represented by the calibration tuning curve 531) will result in a positive resistance shift ΔR %=7.5 in the junction resistance of the given Josephson junction.

Next, FIG. 5E is a graph 540 which illustrates exemplary calibration tuning curves 541, 542, and 543 for a positive tuning regime, according to an exemplary embodiment of the disclosure. In particular, the graph 540 depicts a set of calibration tuning curves 541, 542, and 543 that each provide a positive junction resistance shift (ΔR %) as a function of anneal time (s) for a different laser power level (e.g., P₁, P₂, and P₃) using the same laser beam illumination pattern (e.g., quad-spot laser beam pattern). For example, the calibration tuning curve 541 represents an amount of junction resistance shift (ΔR) % as a function of anneal time at a low laser power setting P₁ (e.g., 1.80 W) using the given laser beam illumination pattern. The calibration tuning curve 542 represents an amount of junction resistance shift (ΔR) % as a function of anneal time at a medium laser power setting P₂ (e.g., 2.0 W) using the given laser beam illumination pattern. The calibration tuning curve 543 represents an amount of junction resistance shift (ΔR) % as a function of anneal time at a high laser power setting P₃ (e.g., 2.2 W) using the given laser beam illumination pattern.

In an exemplary embodiment, the calibration tuning curve 541 is computed using a curve fitting process to fit a plurality of ΔR_{avg} % data points 541a, 541b, 541c, and 541d to a polynomial curve using a second order polynomial curve fitting process, wherein each data point 541a, 541b, 541c, and 541d corresponds to a respective ΔR_{avg} % that is computed from a collection of ΔR % calibration data obtained for respective groups of test Josephson junctions that were laser annealed for the anneal times 2.0 s, 5.0 s. 10.0 s, and 20.0 s respectively, for the combination of laser power setting P₁ and given laser beam illumination pattern. In addition, the calibration tuning curve 542 is computed using a curve fitting process to fit a plurality of ΔR_{avg} % data points 542a, 542b, 542c, and 542d to a polynomial curve using a second order polynomial curve fitting process, wherein each data point 542a, 542b, 542c, and 542d corresponds to a respective ΔR_{avg} % that is computed from a collection of ΔR % calibration data obtained for respective groups of test Josephson junctions that were laser annealed for the anneal times 2.0 s, 5.0 s, 10.0 s, and 20.0 s respectively, for the combination of laser power setting P₂ and given laser beam illumination pattern. Similarly, the calibration tuning curve 543 is computed using a curve fitting process to fit a plurality of ΔR_{avg} % data points 543a, 543b, 543c, and 543d to a polynomial curve using a second order polynomial curve fitting process, wherein each data point 543a, 543b, 543c, and 543d corresponds to a respective ΔR_{avg} % that is computed from a collection of ΔR % calibration data obtained for respective groups of test Josephson junctions that were laser annealed for the anneal times 2.0 s, 5.0 s, 10.0 s, and 20.0 s respectively, for the combination of laser power setting P₃ and given laser beam illumination pattern.

The exemplary calibration tuning curves shown in the graphs 520, 530, and 540 can be used to estimate a given anneal time that is needed at a given laser power setting to tune a Josephson junction to a target ΔR %, as will be discussed in further detail below. In some embodiments, the exemplary calibration tuning curves shown in the graphs 520, 530, and 540 may be determined using at least a portion of the existing tuning range data from laser annealing calibration tests, and correspond in part to the calibration turning curves shown in the graphs 220, 230, and 240, in a manner where the scaling of anneal time is linearized such that the depicted second-order curve fitting process may be accurately performed. In other embodiments, the calibration tuning curves shown in the graphs 520, 530, and 540 may be determined using new tuning range data obtained from a separate set of laser annealing calibration tests, using another set of test (dummy) Josephson junctions that reside on the same quantum chip to be tuned, or in other embodiments, can be Josephson junctions of qubits that are formed on a sister chiplet from the same fabrication process.

It is to be noted that FIGS. 5C, 5D, and 5E illustrate exemplary embodiments of tuning curves which correspond to a plurality of discrete laser powers, wherein laser power can be selected based on a desired anneal time and ΔR %. In other embodiments, tuning curves can be generated and utilized to represent tuning calibration data in other ways. For example, FIG. 5F depicts a graph 550 which illustrates exemplary calibration tuning curves for a positive tuning regime, according to an exemplary embodiment of the disclosure. In particular, the graph 550 illustrates a plurality of calibration tuning curves 551, 552, 553, and 554, which represent junction resistance shift (ΔR) % (or tuning %) as a function of anneal time (Y-axis) and laser power (X-axis) for a given laser beam illumination pattern. For example, the first calibration tuning curve 551 represents a value of ΔR %=1.0% as a function of anneal time and laser power. The second calibration tuning curve 552 represents a value of ΔR %=5.0% as a function of anneal time and laser power. The third calibration tuning curve 553 represents a value of ΔR %=10.0% as a function of anneal time and laser power. The fourth calibration tuning curve 554 represents a value of ΔR %=14.0% (e.g., maximum tuning range) as a function of anneal time and laser power.

The graph 550 of calibration tuning curves 551, 552, 553, and 554 can be used to select an anneal time and laser power based on a target ΔR %, or select a laser power based on a desired anneal time and a target ΔR %. For example, FIG. 5F illustrates a horizontal dashed line 560 which represents a selected anneal time of 20 seconds. The points at which the horizontal dashed line 560 intersect the respective calibration tuning curves 552, 553, and 554 of respective ΔR % values can be used to determine the laser power to achieve a desired ΔR %. Essentially, the graph 550 allows any combination of laser power and anneal time to be selected to achieve the same ΔR %. As an example, by selecting a target laser power, e.g., 2.0 W, the anneal times to achieve each of the ΔR % values represented by the calibration tuning curves 551, 552, 553, and 554 can be determined by the points at which a vertical line 561 at the selected power level 2.0 intersects the calibration tuning curves 551, 552, 553, and 554.

It is to be appreciated that the exemplary calibration techniques as discussed herein are designed to obtain tuning calibration parameters which represent laser tuning characteristics of Josephson junctions. While Josephson junctions on a given quantum chip typically tune at different rates, the tuning rates of such Josephson junctions are generally similar. In this regard, the tuning calibration data that is obtained by measuring and analyzing changes in junction resistances of test Josephson junctions as a function of different combinations of laser power, anneal time, and laser beam illumination pattern, provides a good baseline of calibration information that can be utilized to calibrate laser annealing operations to laser tune actual Josephson junctions that are fabricated using the same or similar processes of the test Josephson junctions. The tuning calibration parameters obtained from laser annealing groups of test Josephson junctions using different combinations of laser power, anneal time, and laser beam illumination pattern can be utilized in a process to generate a frequency tuning plan for LASIQ tuning of superconducting qubits which comprises Josephson junctions with tuning characteristics that are the same or similar to the test Josephson junctions, as represented by the tuning calibration data and parameters. The frequency tuning plan specifies respective target resistance (denoted R_{target}) values for the Josephson junctions of the qubits to achieve respective target transition frequencies of the qubits as specified by the frequency tuning plan. The frequency tuning plan is generated to perform LASIQ tuning of the transition frequencies of superconducting qubits to avoid frequency collisions in the qubit lattice when performing gate operations (e.g., single gate operations, multi-gate operations (e.g., two-qubit gate entanglement operations, etc.) on a quantum chip (e.g., quantum processor). Exemplary embodiments for generating and analyzing frequency tuning plans for LASIQ tuning of superconducting qubits will be discussed in further detail below.

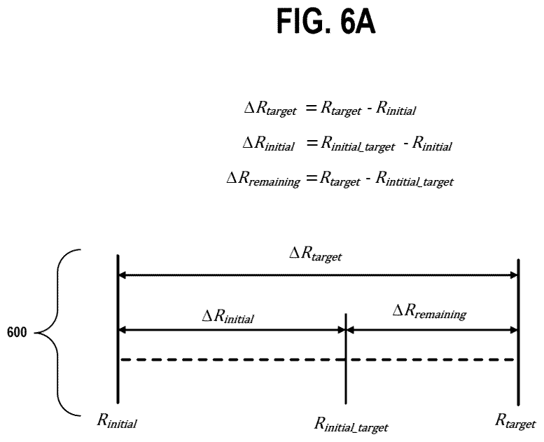

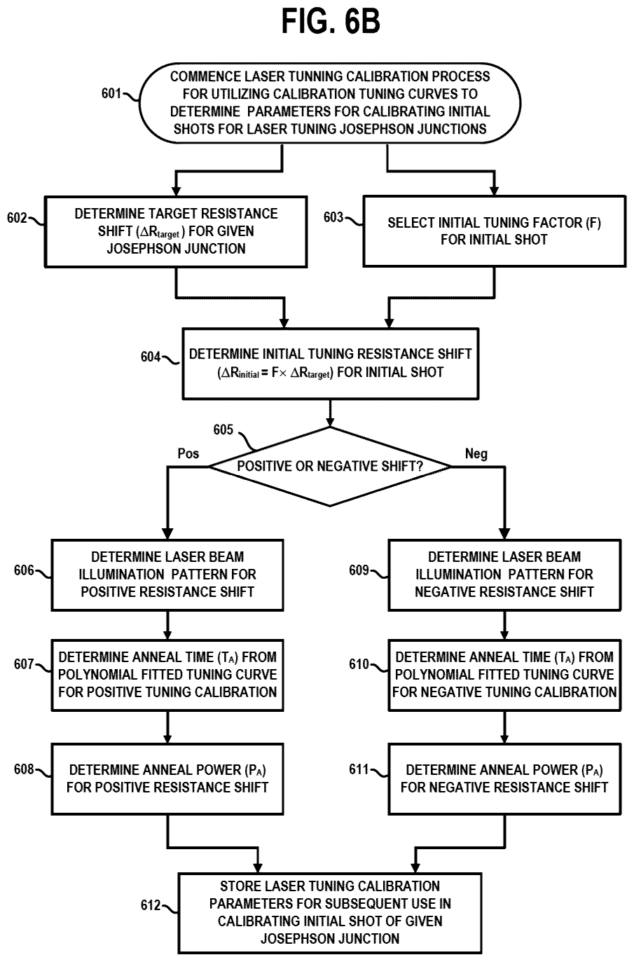

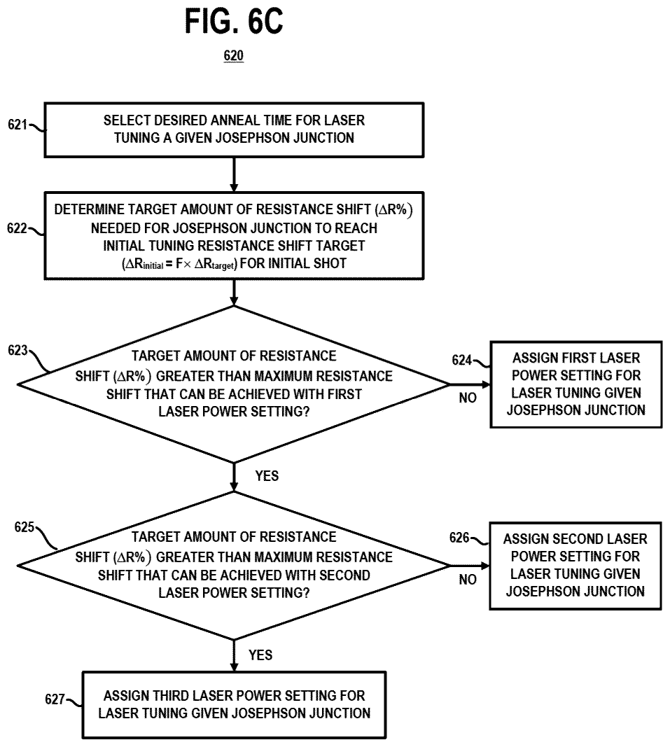

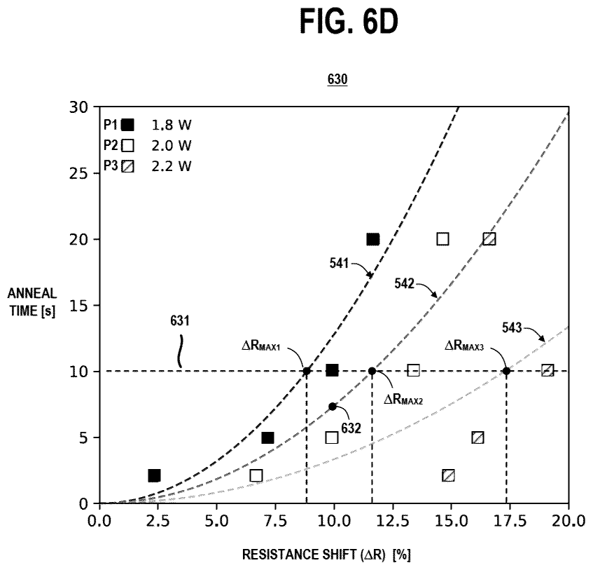

FIGS. 6A, 6B, 6C, and 6D illustrate methods for utilizing tuning calibration data (e.g., tuning curves and associated tuning calibration parameters) to determine target combinations of laser power, anneal time, and laser beam illumination pattern, for calibrating initial laser annealing operations (initial “shots”) for partially tuning Josephson junctions to their respective target junction resistances. The initial “shot” of a given Josephson junction is calibrated to shift the junction resistance of the Josephson junction from an initial junction resistance (denoted Rᵢₙᵢₜᵢₐₗ) to an initial target junction resistance (denoted R_{initial_target}) to achieve an “initial tuning resistance shift” (denoted ΔRᵢₙᵢₜᵢₐₗ). In some embodiments, the “initial tuning resistance shift” is computed as:

$$Δ {R}_{initial} = F \times Δ {R}_{target} ,$$

where F denotes a specified initial tuning factor F (or initial resistance shift tuning factor), and where ΔR_{target} denotes a difference between the target junction resistance (R_{target}) and the initial measured junction resistance (Rᵢₙᵢₜᵢₐₗ) of the Josephson junction before the initial anneal operation (i.e., ΔR_{target}=R_{target}−Rᵢₙᵢₜᵢₐₗ). The initial tuning factor F can be set to any desired value to achieve a partial tuning shift which corresponds to a percentage of the total resistance shift to the target junction resistance (R_{target}) of the given Josephson junction. For example, the initial tuning factor can be set to, e.g., F=25%, 30%, 50%, 75%, 80%, or 90%, etc., depending on the confidence level of the tuning precision. For example, F may be selected to ensure that the risk of overshoot does not exceed a threshold value (for example, 0.1%).

FIG. 6A is a diagram 600 which schematically illustrates relationships between various parameters that are utilized to determine an initial tuning resistance shift ΔRᵢₙᵢₜᵢₐₗ for a given Josephson junction, according to an exemplary embodiment of the disclosure. In particular, the diagram 600 illustrates the following parameters: (i) ΔR_{target}=R_{target}−Rᵢₙᵢₜᵢₐₗ; (ii) ΔRᵢₙᵢₜᵢₐₗ=R_{initial_target}−Rᵢₙᵢₜᵢₐₗ; and (iii) ΔR_{remaining}=R_{target}−R_{initial_target}. As shown in FIG. 6A, the initial tuning resistance shift ΔRᵢₙᵢₜᵢₐₗ represent a portion (e.g., percentage) of a total resistance shift (portion of ΔR_{target}) from the initial measured junction resistance Rᵢₙᵢₜᵢₐₗ of the Josephson junction to the target resistance R_{target} of the Josephson junction, which is achieved by calibrating the initial laser annealing operation (initial shot) to partially tune the Josephson junction by an amount that corresponds to the initial tuning resistance shift ΔRᵢₙᵢₜᵢₐₗ=F×ΔR_{target}. In some embodiments, an initial tuning factor of F=50% is chosen to appreciably tune the Josephson junction towards its target junction resistance R_{target}, while mitigating the risk of overshooting R_{target}.

In some embodiments, the computed value of ΔRᵢₙᵢₜᵢₐₗ is utilized to determine a resistance shift percentage ΔR % which, in turn, can be used to determine a given combination of laser power, anneal time, and illumination pattern, to calibrate the initial laser tuning operation (initial shot) to achieve the initial tuning resistance shift ΔRᵢₙᵢₜᵢₐₗ given the initial junction resistance Rᵢₙᵢₜᵢₐₗ. For example, in some embodiments, the ΔR % for the initial shot is computed as:

$$Δ R \% = \frac{Δ {R}_{initial}}{{R}_{initial}} \times 100 \% = \frac{{R}_{initial \_ target} - {R}_{initial}}{{R}_{initial}} \times 100 \% .$$

For example, assume that for a given Josephson junction, Rᵢₙᵢₜᵢₐₗ=10 kΩ, R_{target}=12 kΩ, and ΔR_{target}=R_{target}−Rᵢₙᵢₜᵢₐₗ=2 kΩ. Assuming a tuning factor F is set to 0.5 (or 50%), the initial tuning resistance shift ΔRᵢₙᵢₜᵢₐₗ will be computed as ΔRᵢₙᵢₜᵢₐₗ=F×ΔR_{target}=0.5×2 kΩ=1 kΩ. In this instance, given that ΔRᵢₙᵢₜᵢₐₗ=R_{initial_target}−Rᵢₙᵢₜᵢₐₗ, then R_{initial_target}=11 kΩ. Next, the amount of junction resistance shift ΔR % needed to shift the junction resistance of the given Josephson junction from Rᵢₙᵢₜᵢₐₗ=10 kΩ to R_{initial_target}=11 kΩ for the initial “shot” is determined as:

$$Δ R \% = \frac{{R}_{initial \_ target} - {R}_{i n i t i a l}}{{R}_{i n i t i a l}} \times 100 \% = \frac{11 - 10}{10} \times 100 \% = 10 \% .$$

As noted above, the resistance shift percentage ΔR %=10% can then be used to determine a given combination of laser power, anneal time, and laser beam illumination pattern, to calibrate the initial laser tuning operation (initial shot) to achieve resistance shift percentage ΔR %=10% and, thus, reach the initial tuning resistance shift ΔRᵢₙᵢₜᵢₐₗ for the Josephson junction.

Next, FIG. 6B illustrates a flow diagram of a method for utilizing laser tuning calibration data to determine laser annealing parameters for performing initial laser tuning operations on Josephson junctions, according to an exemplary embodiment of the disclosure. More specifically, FIG. 6B illustrates a method for utilizing bidirectional tuning calibration data to determine parameters for calibrating initial laser tuning operations (initial shots) to be performed on Josephson junctions to achieve positive resistance shifts or negative resistance shifts, as needed. In some embodiments, FIG. 6B illustrates a laser tuning calibration process that is commenced, e.g., by the control system 110 of FIG. 1, for utilizing calibration tuning curves and associated calibration data to determine parameters for calibrating the initial “shots” for laser tuning respective Josephson junctions (block 601). In some embodiments, the laser tuning calibration process of FIG. 6B is performed to determine initial laser tuning shots for a plurality of Josephson junctions based on, e.g., a frequency tuning plan which specifies a respective target resistance shift (ΔR_{target}=R_{target}−Rᵢₙᵢₜᵢₐₗ) for each of the Josephson junctions that are to be laser tuned. For case of explanation, the process flow of FIG. 6B illustrates one iteration for determining parameters for calibrating the initial “shot” for laser tuning a given Josephson junction, although it is to be understood that the process flow would be repeated for each Josephson junction to be tuned according to the given frequency tuning plan.

The laser tuning calibration process determines a target resistance shift ΔR_{target} for the given Josephson junction (block 602) and selects an initial tuning factor F (e.g., F=50%) for the initial shot (block 603). In some embodiments, the target resistance shift ΔR_{target} for the given Josephson junction is specified in a frequency tuning plan. In some embodiments, the initial tuning factor F is selected and globally applied for calibrating the initial laser tuning shot of all Josephson junctions. In other embodiments, the initial tuning factor F for the given Josephson junction can be selected based on factors such as, e.g., the magnitude of the target resistance shift ΔR_{target} for the given Josephson junction, etc.

Next, the laser tuning calibration process determines the initial tuning resistance shift, ΔRᵢₙᵢₜᵢₐₗ=F×ΔR_{target}, for the initial laser tuning operation (initial shot) for the given Josephson junction (block 604). As noted above, the initial tuning resistance shift ΔRᵢₙᵢₜᵢₐₗ is utilized to determine a target ΔR % value that is utilized at least in part to determine a suitable combination of laser power, laser anneal time, and laser beam illumination pattern to utilize for the initial laser tuning operation (initial shot) to achieve the desired initial tuning resistance shift ΔRᵢₙᵢₜᵢₐₗ for the given Josephson junction.

The laser tuning calibration process determines whether a positive resistance shift or a negative resistance shift is needed for the initial resistance shift ΔRᵢₙᵢₜᵢₐₗ (block 605). For example, in some embodiments, the target resistance shift ΔR_{target} for the given Josephson junction will be specified as either negative target resistance shift (−ΔR_{target}) or positive target resistance shift (+ΔR_{target}). A negative target resistance shift (−ΔR_{target}) indicates that the target resistance R_{target} is less than the initially measured resistance Rᵢₙᵢₜᵢₐₗ of the given Josephson junction, while a positive target resistance shift (+ΔR_{target}) indicates that the target resistance R_{target} is greater than the initially measure resistance Rᵢₙᵢₜᵢₐₗ of the given Josephson junction.

If the laser tuning calibration process determines (in block 605) that a positive resistance shift is needed to achieve the initial (positive) tuning resistance shift ΔRᵢₙᵢₜᵢₐₗ, the laser tuning calibration process proceeds to determine a laser beam illumination pattern which is suitable to achieve a positive resistance shift (block 606), determine a suitable anneal time (T_{A}) from a polynomial fitted tuning curve having a positive tuning regime which is suitable to achieve the initial (positive) resistance shift ΔRᵢₙᵢₜᵢₐₗ % (block 607), and determine a suitable laser power setting which provides a laser anneal power (PA) that is suitable to provide a positive resistance shift to achieve the initial (positive) tuning resistance shift ΔRᵢₙᵢₜᵢₐₗ (block 608). On the other hand, if the laser tuning calibration process determines (in block 604) that a negative resistance shift is needed to achieve the initial (negative) tuning resistance shift ΔRᵢₙᵢₜᵢₐₗ, the laser tuning calibration process proceeds to determine a laser beam illumination pattern which is suitable to achieve a negative resistance shift (block 609), determine a suitable anneal time (T_{A}) from a polynomial fitted tuning curve having a negative tuning regime which is suitable to achieve the initial (negative) tuning resistance shift ΔRᵢₙᵢₜᵢₐₗ (block 610), and determine a suitable laser power setting which provides a laser anneal power (PA) that is suitable to provide a negative resistance shift to achieve the initial (negative) tuning resistance shift ΔRᵢₙᵢₜᵢₐₗ (block 611).

The laser tuning calibration process persistently stores the laser tuning calibration parameters for subsequent use in calibrating the initial laser tuning operation (initial shot) for at least partially tuning the given Josephson junction to its target junction resistance (block 611). The laser tuning calibration process (blocks 602-611) is then repeated for each of the remaining Josephson junctions that are identified in the given frequency tuning plan. At the completion of the laser tuning calibration process of FIG. 6B, the target combinations of laser power, anneal time, and illumination pattern, for the initial “shots” of all Josephson junctions in the frequency tuning plan will be determined and persistently stored for subsequent access (block 612), so that the frequency tuning plan and associated laser tuning calibration parameters for the Josephson junctions can be utilized to perform a LASIQ tuning process, as discussed detail below.

Next, FIG. 6C illustrates a flow diagram of method for utilizing tuning calibration data to determine parameters for calibrating initial laser tuning operations (initial shots) for laser tuning Josephson junctions, according to an exemplary embodiment of the disclosure. In some embodiments, FIG. 6C illustrates an exemplary calibration process 620 for implementing the process of blocks 607 and 608 of FIG. 6B to determine laser tuning calibration parameters for positive resistance-shift tuning of a given Josephson junction. For example, an initial step involves selecting a desired anneal time for laser tuning a given Josephson junction (block 621). In some embodiments, it is desirable to laser tune Josephson junctions by performing laser anneal operations using the same anneal time (e.g., 10 seconds). In some embodiments, the anneal time is selected to a maximum anneal time for purposes of, e.g., minimizing throughput of the laser tuning operations, while selecting a power level that can cap the total anneal time to the maximum value. In this regard, in some embodiments, the anneal time for the laser tuning is initially selected (e.g., 10 seconds maximum), and the process proceeds to determine and assign a minimum laser power setting to the given Josephson junction, which is sufficient to achieve a resistance shift percentage ΔR % for the initial laser tuning operation (initial shot) for the given Josephson junction at the selected anneal time.

In particular, as noted above, for the initial laser tuning operation (initial shot), the calibration process 620 determines a target resistance shift percentage ΔR % that is needed for the Josephson junction to reach the initial tuning resistance shift target value of ΔRᵢₙᵢₜᵢₐₗ=F×ΔR_{target} for the initial shot (block 622). As discussed above, the target resistance shift percentage ΔR % for the initial shot is determined as

$$Δ R \% = \frac{Δ {R}_{i n i t i a l}}{{R}_{i n i t i a l}} \times 100 \% .$$

Next, the target resistance shift percentage ΔR % is utilized to determine a given power level setting to assign to the given Josephson junction based on the selected anneal time. For example, a determination is made as to whether the target resistance shift percentage ΔR % for the given Josephson junction is greater than a first maximum junction resistance shift ΔR_{MAX1} that can be achieved with a first (lowest) laser power setting (e.g., P₁=1.8 W) for the selected anneal time (block 623). If it is determined that the target resistance shift percentage ΔR % is not greater than the first maximum junction resistance shift ΔR_{MAX1} (negative determination in block 623), the process assigns the first laser power setting P₁ for laser tuning the given Josephson junction (block 624).

On the other hand, if it is determined that the target resistance shift percentage ΔR % is greater than the first maximum junction resistance shift ΔR_{MAX1} (affirmative determination in block 623), the process proceeds to determine whether the target resistance shift percentage ΔR % for the given Josephson junction is greater than a second maximum junction resistance shift ΔR_{MAX2} that can be achieved with a second (middle) laser power setting (e.g., P₂=2.0 W) for the selected anneal time (block 625). If it is determined that the target resistance shift percentage ΔR % is not greater than the second maximum junction resistance shift ΔR_{MAX2} (negative determination in block 625), the process assigns the second laser power setting P₂ for laser tuning the given Josephson junction (block 626). On the other hand, if it is determined that the target resistance shift percentage ΔR % is greater than the second maximum junction resistance shift ΔR_{MAX2} (affirmative determination in block 625), the process assigns the third (high) laser power setting P₃ for laser tuning the given Josephson junction (block 627).

By way of further example, FIG. 6D illustrates a process of using calibration tuning curves to determine a power level setting for laser annealing a Josephson junction based on a selected anneal time and a target resistance shift percentage ΔR % needed to reach an initial tuning resistance shift target value of ΔRᵢₙᵢₜᵢₐₗ=F×ΔR_{target} for the initial shot, according to an exemplary embodiment of the disclosure. In particular, FIG. 6D illustrates an exemplary process 630 to determine a power level setting based on the exemplary process flow of FIG. 6C using the exemplary calibration tuning curves 541, 542, and 542 as described above in conjunction with FIG. 5E. For example, as shown in FIG. 6D, a horizontal dashed line 631 represents a selected anneal time of 10 seconds (selection in block 621, FIG. 6C). The horizontal dashed line 631 intersects the first calibration tuning curve 541, the second calibration tuning curve 542, and the third calibration tuning curve 543 at respective points ΔR_{MAX1}, ΔR_{MAX2}, and ΔR_{MAX3}, wherein ΔR_{MAX1}<ΔR_{MAX2}<ΔR_{MAX3}.

The point ΔR_{MAX1} represents a maximum amount of junction resistance shift ΔR % that can be achieved for a given Josephson junction by laser tuning the given Josephson junction at the laser power setting P₁ for the anneal time of 10 s. The point ΔR_{MAX2} represents a maximum amount of junction resistance shift ΔR % that can be achieved for a given Josephson junction by laser tuning the given Josephson junction at the middle laser power setting P₂ for the anneal time of 10 s. The point ΔR_{MAX3} represents a maximum amount of junction resistance shift ΔR % that can be achieved for a given Josephson junction by laser tuning the given Josephson junction at the laser power setting P₃ for the anneal time of 10 s.

Assume that a target resistance shift percentage ΔR % of 10% is needed to reach an initial tuning resistance shift target value of ΔRᵢₙᵢₜᵢₐₗ for a given Josephson junction. The tuning calibration curves in FIG. 6D show that the laser power setting P₁ cannot be utilized as ΔR_{MAX1}<ΔR %=10%. On the other hand, the laser power setting P₂ can be utilized since ΔR_{MAX1}>ΔR %=10%. Therefore, FIG. 6D illustrates that the laser power setting P₂ can be selected as a minimum laser power setting to achieve at least ΔR %=10% for an anneal time of 10 s. Once the minimum power level setting (e.g., laser power setting P₂) is determined for the Josephson junction, the anneal time that is needed to achieve the target resistance shift percentage ΔR %=10% for the initial “shot” can be extracted from the calibration tuning curve 542. For example, as shown in FIG. 6D, a point 632 on the calibration tuning curve 542 shows that the target resistance shift percentage ΔR %=10% can be achieved by laser annealing the Josephson junction for an anneal time of about 7.5 seconds at the given power level setting P₂.

In other embodiments, a fractional tuning for the first laser annealing operation (initial shot) or any “shot” in the iterative tuning process, can be determined using probability distributions of resistance shift to minimize tuning time and/or minimize possibility of overshoot. For example, the exemplary methods of FIG. 6A-6D describe an exemplary embodiment for determining and utilizing a target combination of laser power and anneal time to perform an initial laser anneal operation on a given Josephson junction to achieve an initial junction resistance shift ΔRᵢₙᵢₜᵢₐₗ=R_{initial_target}−Rᵢₙᵢₜᵢₐₗ that is about 50% of the resistance shift to reach the target junction resistance R_{target} of the given Josephson junction. However, there exists some random variation to the amount by which a given “shot” will shift the junction resistance. For example, a given “shot” that is expected to provide a ΔRᵢₙᵢₜᵢₐₗ that reaches 50% to R_{target} may actually result in, e.g., a 47% or a 59% shift. Such variation can be accounted for using the exemplary calibration techniques as discussed herein, along with other statistical methods. For example, if the calibration process indicates a large variability of the initial junction resistance shift, the ΔR % which was initially selected to be 50% may be selected to be less, such that the risk of overshooting the target resistance is significantly mitigated.

For the calibration curves and parameters as shown in FIG. 2C, the error bars (e.g., error bare 233c) provide means for computing other statistical parameters (e.g., median, median absolute deviation) and constructing a corresponding map of statistical variation. The first map can represent the median ΔR to be expected as a function of anneal power and anneal time. The second, or corresponding map, represents the statistical variation to be expected as a function of anneal power and anneal time. Variation is characterized by an error bar, standard deviation, statistical distribution or other well-known methods of statistics and probability.

In some embodiments, a map of statistical variation is generated using an exemplary process, as follows. When performing a calibration process such as shown in FIG. 5A, the same combination of laser power setting, anneal time, and laser beam illumination pattern is used to perform laser anneal operation on each of multiple identical Josephson junctions (e.g., 7 measurements on 7 Josephson junctions). From the several measured values of ΔR, the process determines a median and statistical variation for that particular laser power and anneal time, in terms of, e.g., standard deviation, histogram, statistical distribution, or other well-known statistical methods. Alternatively, when calibration data of ΔR at various combination of, e.g., laser power settings and anneal times is fit to find a tuning curve (as in FIG. 5E), the curve-fitting process can estimate the statistical variation of ΔR as a function of laser power and anneal time, in terms of a goodness-of-fit parameter or confidence interval. In some embodiments, a single calibration value of ΔR at a particular laser power and anneal time may be used to estimate both the median and statistical variation of ΔR at that power and time. For instance, some well-known statistical distributions such as the Poisson distribution have a statistical variance equal to the mean of the distribution.

The median and variation in ΔR parameters are then used as follows. Before a given “shot”, the process determines what likelihood of overshoot is acceptable. For example, the process may be configured to determine that an acceptable likelihood of overshoot is no more than 0.1% chance of overshooting the target resistance. The calibration process then chooses the combination of laser power and anneal time exposure time, such that the median and statistical variation permit no more than 0.1% chance of overshooting the target resistance. For example, if the statistical distribution is a Gaussian (or Normal) distribution, then the initial resistance of the Josephson junction, plus the ΔR of that shot (as known from the median ΔR calibration map), plus three standard-deviations of ΔR (as known from the statistical-variation calibration map) must be less than the final target junction resistance. Alternatively, if, for example, the calibration process is configured to accept no more than 2% chance of overshoot, then the criterion changes to two standard-deviations of ΔR, etc.

In most cases, an initial shot to reach a 50% resistance shift to the target junction resistance will satisfy any reasonable requirement for chance of overshoot. Alternatively, the process can be configured to choose a maximum number of allowable times to “shoot” a given Josephson junction. This also represents a maximum amount of time for the tuning. For instance, if a given Josephson junction is to be “shot” no more than one time, then the initial junction resistance of the given Josephson junction plus the ΔR achieved for the “shot” should equal the final target junction resistance, i.e., an initial shot of 100% shift in resistance to the target junction resistance. However, in such a case, a 50% likelihood of overshoot can be expected, which may not be desirable for certain applications.

As noted above, the different tuning regimes 201, 202, 203 and 204 of the bidirectional tuning curve 210 as shown in FIG. 2A can be individually obtained using different power levels, anneal times, and laser beam illumination patterns. For example, as noted above, FIG. 2B illustrates calibration data of a negative tuning curve 221 which covers a negative tuning regime, wherein the calibration data can be obtained by laser annealing groups of test Josephson junctions with relatively low laser power settings and short anneal times. In addition, FIG. 2C illustrates calibration data of calibration curves 231, 232, and 233 which cover positive tuning regions and at least some portions of reverse-shift tuning regimes, wherein the calibration data can be obtained by laser annealing groups of test Josephson junctions with intermediate laser power settings and intermediate anneal times. On the other hand, FIG. 2D illustrates calibration data of a reverse-shift tuning curve 241 which covers a negative-shift tuning regime, wherein the calibration data can be obtained by laser annealing groups of test Josephson junctions with relatively high laser power settings and long anneal times.

In this regard, in some embodiments, laser annealing calibration tests can be performed on groups of Josephson junctions over a wide range of power level settings and anneal times to obtain groups of calibration that correspond to specific tuning regions. In this instance, different tuning curves can be generated which cover specific tuning regions. On the other hand, in some embodiments, the laser annealing calibration tests can be configured to obtain calibration data for generating bidirectional tuning curves that cover each of the different tuning regimes for a given power level setting and laser beam illumination pattern.

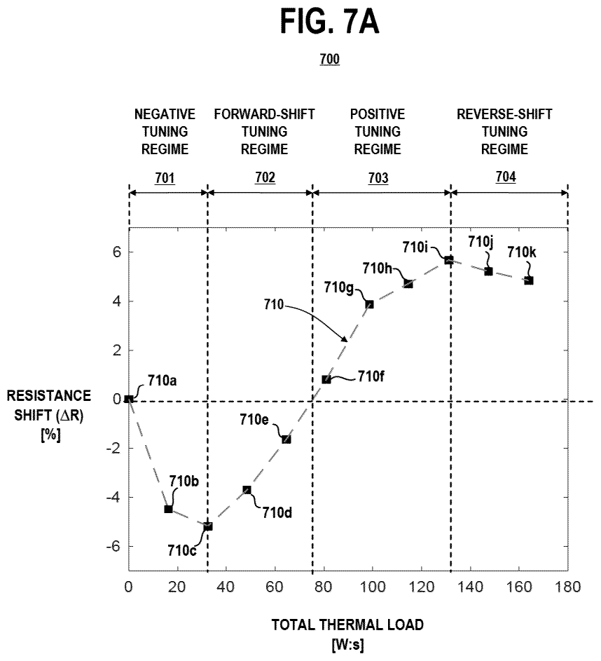

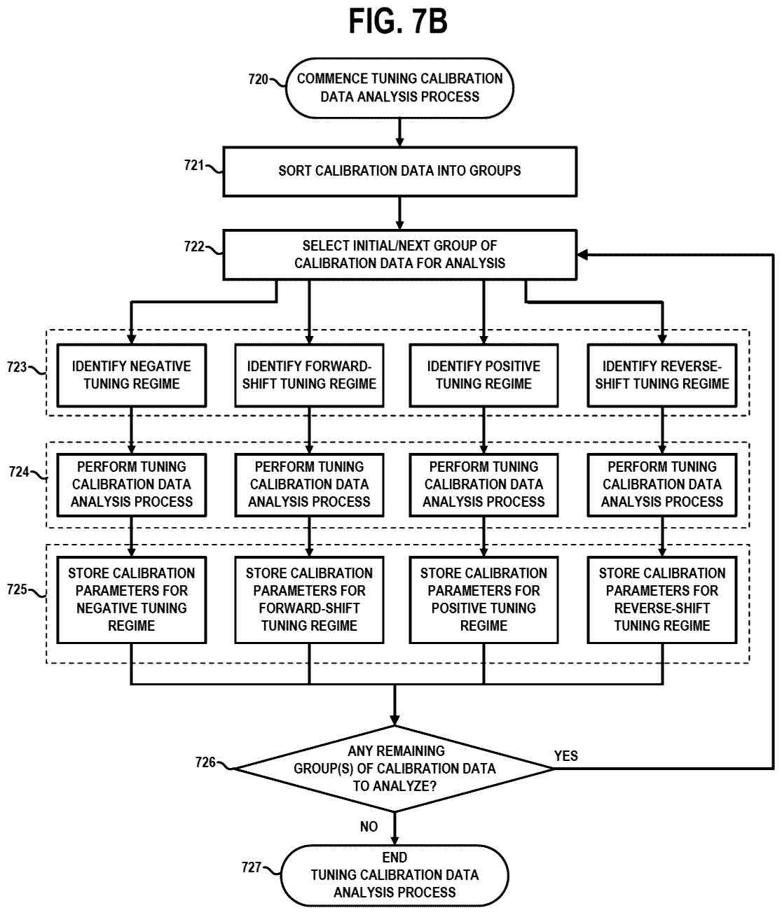

For example, FIG. 7A illustrates a bidirectional tuning curve for laser tuning Josephson junctions, according to another exemplary embodiment of the disclosure. In particular, FIG. 7A illustrates a graph 700 of an exemplary bidirectional tuning curve 710 which covers four different tuning regimes including a negative tuning regime 701, a forward-shift tuning regime 702, a positive tuning regime 703, and a reverse-shift tuning regime 704. In an exemplary embodiment, the bidirectional tuning curve 710 comprises calibration data obtained by performing laser annealing calibration tests on groups of Josephson junctions at the same combination of an intermediate-to-lower power level setting (e.g., 1.6 W) and laser beam illumination pattern (e.g., quad-spot laser beam pattern), but over a wide range of thermal anneal times (e.g., 0.5 seconds to 100 seconds).

In particular, FIG. 7A illustrates a plurality of calibration data points 710a, 710b, 710c, 710d, 710c, 710f, 710g, 710h, 710i, 710j, and 710k, where each calibration data point represents a junction resistance shift percentage ΔR % that is achieved for a different anneal time but at the same combination of laser power level (e.g., 1.6 W) and laser beam illumination pattern (e.g., quad-spot pattern). In particular, each calibration data point 710a-710k represents a respective average junction resistance shift percentage ΔR_{avg} % computed from ΔR % values of a group of test Josephson junctions (e.g., 5 Josephson junctions) that were laser annealed at the same anneal time and at the same combination of laser power level and laser beam illumination pattern.

In the exemplary embodiment of FIG. 7A, the calibration data points 710a, 710b, and 710c define a portion of the bidirectional tuning curve 710 in the negative tuning regime 701. The calibration data points 710d and 710e define a portion of the bidirectional tuning curve 710 in the forward-shift tuning regime 702. The calibration data points 710f, 710g, 710h, and 710i define a portion of the bidirectional tuning curve 710 in the positive tuning regime 703. The calibration data points 710j and 710k define a portion of the bidirectional tuning curve 710 in the reverse-shift tuning regime 704. The calibration data point 710c represents a maximum negative tuning range that is achieved for a given anneal time at the given combination of power level setting and laser beam illumination pattern. The calibration data point 710i represents a maximum positive tuning range that is achieved for a given anneal time at the given combination of power level setting and laser beam illumination pattern.

While FIG. 7A illustrates an exemplary embodiment in which the bidirectional tuning curve 710 covers each of the different tuning regimes 701, 702, 703, and 704, based on calibration data obtained by performing laser annealing calibration tests on groups of Josephson junctions at the same combination of an intermediate-to-lower laser power level setting (e.g., 1.6 W) and laser beam illumination pattern (e.g., quad-spot laser beam pattern), in some instances, it may not be possible to obtain calibration data that covers all four tuning regions for the same combination of laser power level setting and laser beam illumination pattern. For example, in some instances, a given combination of laser power level setting and laser beam illumination pattern may only be able to obtain calibration data that covers the negative tuning, forward-shift, and positive tuning regimes 701, 702, and 703, but not the reverse-shift tuning regime 704. Further, in some instances, a given combination of laser power level setting and laser beam illumination pattern may only be able to obtain calibration data that covers the negative tuning and forward-shift regimes 701 and 702, but not the positive and reverse-shift tuning regimes 703 and 704. Moreover, in some instances, a given combination of laser power level setting and laser beam illumination pattern may only be able to obtain calibration data that covers the positive and reverse-shift regimes 703 and 704, but not the negative and forward-shift tuning regimes 701 and 702.

FIG. 7B is a flow diagram of a method for analyzing calibration data obtained from laser annealing calibration tests to generate bidirectional tuning curves and associated calibration parameters, according to an exemplary embodiment of the disclosure. In some embodiments, FIG. 7B illustrates process for generating a bidirectional tunning curve (such as shown in FIG. 7A) and associated calibration parameters (e.g., tuning rate coefficients, maximum tuning ranges, etc.) by analyzing calibration data that covers all (or at least most) of the different regimes for the same combination of laser power level setting and laser beam illumination patterns.

In some embodiments, FIG. 7B illustrates process that is performed using the laser annealing system 100 of FIG. 1 with the control system 110 executing a calibration algorithm to commence a tuning calibration data analysis process (block 720), where it is assumed that calibration data has been generated by performing laser annealing calibration tests on groups of Josephson junctions at different combinations of laser power level setting, anneal time, and laser beam illumination pattern. It is further assumed that the laser annealing calibration tests were performed using combinations of laser power level setting and laser beam illumination pattern, which were configured to generate groups of calibration data that cover all (or at least most) of the different tuning regimes.

As an initial step, the calibration process accesses and sorts the calibration data acquired for each test group of Josephson junctions into groups of calibration data (block 721). For example, similar to the sorting process discussed above in conjunction with block 511 of FIG. 5B, for each combination of laser power setting and laser beam illumination pattern, the calibration process aggregates the resistance shift data resulting from laser annealing groups of test Josephson junctions at each of the different anneal times but at the same combination of laser power setting and laser beam illumination pattern. The sorting process results in multiple groups of calibration data for analysis, where each group of calibration data comprises an aggregation of the resistance shift data of test Josephson junctions obtained from performing laser annealing operations on the test Josephson junctions for the various laser anneal times at a given combination of laser power setting and laser beam illumination pattern. The sorting of the calibration data into groups of calibration data allows the calibration data within a given group to be fitted to a bidirectional tuning curve which covers all or more of the different tuning regimes for a given combination of laser power setting and laser beam illumination pattern.

The calibration process selects an initial (or next) group of calibration data for analysis (block 722). For example, the initial group of calibration data can include the resistance shift data (ΔR data) associated with groups of test Josephson junctions that were laser annealed using the same combination of power level setting (e.g., 1.6 W) and laser beam illumination pattern (e.g., quad-spot laser beam pattern), over a wide range of different anneal times (e.g., anneal times from 0.5 s to 100 s). The selected group of calibration data is analyzed to identify portions of the calibration data which correspond to the respective tuning regimes, e.g., the negative tuning region, the forward-shift tuning regime, the positive tuning regime, and the reverse-shift tuning regime (block 723). In some instances, the selected group of calibration data will include calibration data that covers each of the tuning regimes. On the other hand, as noted above, in some instances, the selected group of calibration data may include calibration data that covers some of the tuning regimes e.g., only the negative tuning region, forward-shift tuning regime, positive tuning regime.

Next, tuning calibration data analysis processes are performed (block 724) to determine calibration parameters for each of the tuning regimes. For example, as noted above, a calibration data analysis process involves, e.g., computing average junction resistance shift percentage data ΔR_{avg} % for groups of test Josephson junctions that were laser annealed at the same anneal time, laser power setting, and illumination pattern, utilizing the ΔR_{avg} % data to determine calibration parameters, e.g., tuning rate coefficients for the respective tuning regimes, a maximum negative tuning range for the negative tuning regime, a maximum positive tuning range for the positive tuning regime, etc., using the same or similar techniques as discussed above, and fitting the ΔR_{avg} % data to respective tuning curves for each of the tuning regimes, etc. The computed tuning curves and associated calibration parameters for each of the tuning regimes are persistently stored (block 725).

If there are any remaining groups of calibration data to be analyzed (affirmative determination in block 726), the calibration process selects the next group of calibration data for analysis (return to block 722), and the processing stage 723, 724, and 725 are repeated for the next selected group of calibration data. The tuning calibration data analysis process terminates (block 727) after all groups of calibration data have been analyzed. At the completion of the tuning calibration data analysis process (block 720), the tuning calibration database can have a plurality of bidirectional tuning curves, where some or all of the bidirectional tuning curves have calibration parameters that cover all or most of the different tuning regimes (e.g., negative tuning region, forward-shift tuning regime, positive tuning regime, and reverse-shift tuning regime) and corresponding fitted tuning curves. It is to be appreciated that it is advantageous to configure the laser annealing calibration tests to be able to acquire a wide range of calibration data that covers all tuning regimes 701, 702, 703, and 704 for a same combination of laser power setting and laser beam illumination pattern. Indeed, this enables bidirectional laser tuning of Josephson junctions across each of the tuning regimes 701, 702, 703, and 704 for a same combination of laser power level and illumination pattern, thereby minimizing the need to frequently switch between different laser power settings (and possible illumination patterns) when performing bidirectional laser tuning of the actual Josephson junction as part of, e.g., a LASIQ process.

The exemplary bidirectional tuning curve 210 (FIG. 2A) and bidirectional tuning curve 710 (FIG. 7A) illustrate bidirectional tuning curves in which there are relatively smooth tuning curve transitions between the different tuning regimes. It is to be noted, however, that the exact shapes of the tuning curves can depend on various factors including, but not limited to, the structure of the Josephson junctions, the fabrication process implemented to construct the Josephson junctions, etc. In this regard, portions of the tuning curves may exhibit some intermediate behavior and characteristics which are not suitable for use in determining calibration parameters for calibrating laser tuning operation.

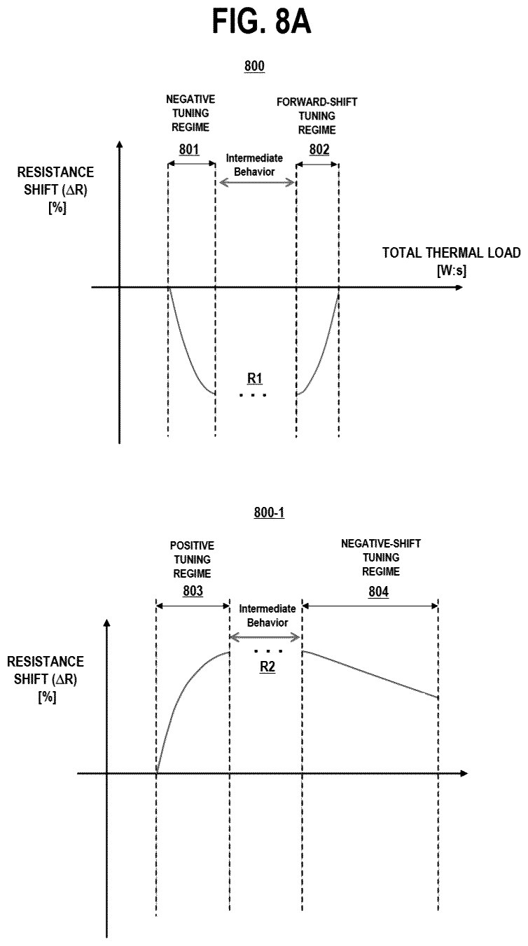

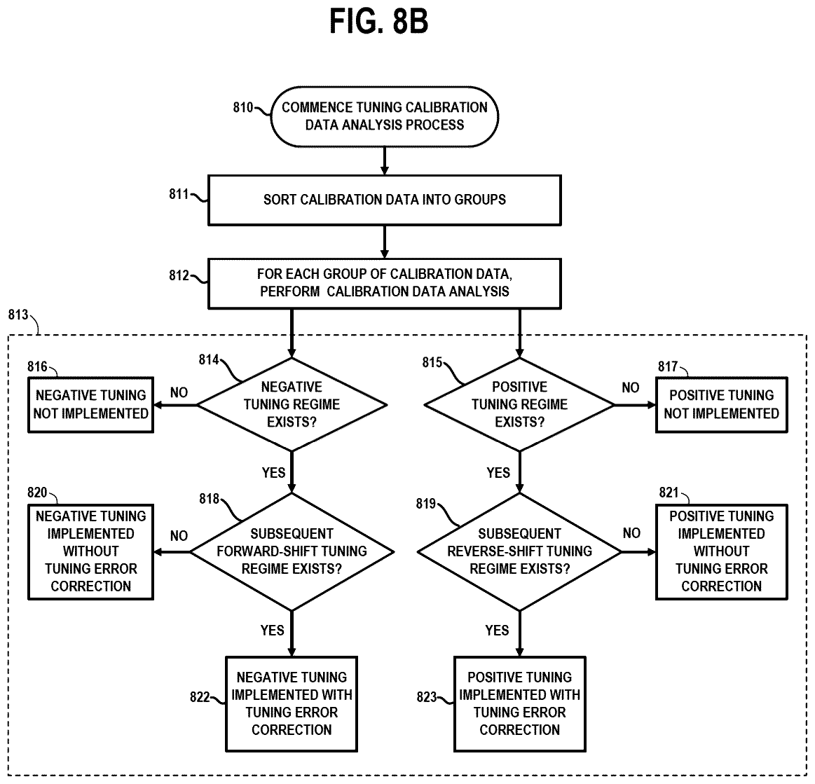

For example, FIG. 8A are graphs of exemplary tuning curves which have portions that exhibit intermediate behaviors that do not fall within a desired one of the bidirectional tuning regimes. In particular, FIG. 8A depicts a graph 800 which illustrates a bidirectional tuning curve that comprises a negative tuning regime 801 and a forward-shift tuning regime 802, and an intermediate regime R1 between the negative tuning regime 801 and forward-shift tuning regime 802 which is deemed to exhibit some undesired intermediate behavior. Moreover, FIG. 8A depicts a graph 800-1 which illustrates a bidirectional tuning curve that comprises a positive tuning regime 803 and a reverse-shift tuning regime 804, and an intermediate regime R2 between the positive tuning regime 803 and the reverse-shift tuning regime 804 which is deemed to exhibit some undesired intermediate behavior. Despite the existence of the undesired intermediate regime R1, the general process of utilizing the forward-shift tuning regime 802 to correct for an overshoot of resistance tuning in the negative tuning regime 801 can be applied, given that a desired forward-shift tuning regime 802 exists subsequent to the negative tuning regime 801, even though the tuning curves of the forward-shift tuning regime 802 and the negative tuning regime 801 are not continuously connected. Similarly, despite the existence of the undesired intermediate regime R2, the general process of utilizing the reverse-shift tuning regime 804 to correct for an overshoot of resistance tuning in the positive tuning regime 803 can be applied, given that a desired reverse-shift tuning regime 804 exists subsequent to the positive tuning regime 803, even though the tuning curves of the reverse-shift tuning regime 804 and the positive tuning regime 803 are not continuously connected. In other words, the intermediate behavior of the intervening regimes R1 and R2 is not problematic as long as a subsequent “correction” regime is accessible.

FIG. 8B is a flow diagram of a method for analyzing calibration data obtained from laser annealing calibration tests to identify bidirectional tuning regions, according to an exemplary embodiment of the disclosure. In particular, FIG. 8B illustrates a tuning calibration data analysis process which is configured to (i) identify negative and positive tuning regions of bidirectional tuning curves and to (ii) identify associated correction tuning regimes that may exist subsequent to negative and positive tuning regions, in instance where there may exist intermediate regimes with undesired tuning behaviors, such as discussed above in conjunction with FIG. 8A.

In some embodiments, FIG. 8B illustrates a process that is performed using the laser annealing system 100 of FIG. 1 with the control system 110 executing a calibration algorithm to commence a tuning calibration data analysis process (block 810), where it is assumed that calibration data has been generated by performing laser annealing calibration tests on groups of Josephson junctions at different combinations of laser power level setting, anneal time, and laser beam illumination pattern. As an initial step, the calibration process sorts the calibration data acquired for each test group of Josephson junctions into groups of calibration data (block 811) using the same or similar sorting techniques as discussed above, the details of which will not be repeated.

A calibration data analysis is performed to analyze each group of calibration data which corresponds to a given combination of laser power level setting and laser beam illumination pattern (block 812). In some embodiments, a calibration data analysis process (block 813) is performed on each group of calibration data. For example, in an exemplary embodiment, the calibration data analysis process (block 813) comprises determining whether a negative tuning regime exists (block 814) and determining whether a positive tuning regime exists (block 815). If it is determined that the given group of calibration data does not comprise a negative tuning regime (negative determination in block 814), then the calibration process determines that negative resistance tuning will not be implemented for the given combination of laser power level setting and laser beam illumination pattern (block 816). Similarly, if it is determined that the given group of calibration data does not comprise a positive tuning regime (negative determination in block 815), then the calibration process determines that positive resistive tuning will not be implemented for the given combination of laser power level setting and laser beam illumination pattern (block 817).

On the other hand, if it is determined that the given group of calibration data does comprise a negative tuning regime (affirmative determination in block 814), the calibration process proceeds to determine whether a subsequent forward-shift tuning regime exists (block 818). Similarly, if it is determined that the given group of calibration data does comprise a positive tuning regime (affirmative determination in block 815), the calibration process proceeds to determine whether a subsequent reverse-shift tuning regime exists (block 819).

If the calibration process determines that a subsequent forward-shift tuning regime does not exist (negative determination in block 818), the calibration process determines that negative resistance tuning can be implemented, but without forward-shift tuning error correction, for the given combination of laser power level setting and laser beam illumination pattern (block 820). Similarly, if the calibration process determines that a subsequent reverse-shift tuning regime does not exist (negative determination in block 819), then the calibration process determines that positive resistance tuning can be implemented, but without reverse-shift tuning error correction, for the given combination of laser power level setting and laser beam illumination pattern (block 821).

On the other hand, if the calibration process determines that a subsequent forward-shift tuning regime does exist (affirmative determination in block 818), the calibration process determines that negative resistance tuning can be implemented with forward-shift tuning error correction, for the given combination of laser power level setting and laser beam illumination pattern (block 822). Similarly, if the calibration process determines that a subsequent reverse-shift tuning regime does exist (affirmative determination in block 819), then the calibration process determines that positive resistance tuning can be implemented with reverse-shift tuning error correction, for the given combination of laser power level setting and laser beam illumination pattern (block 823).

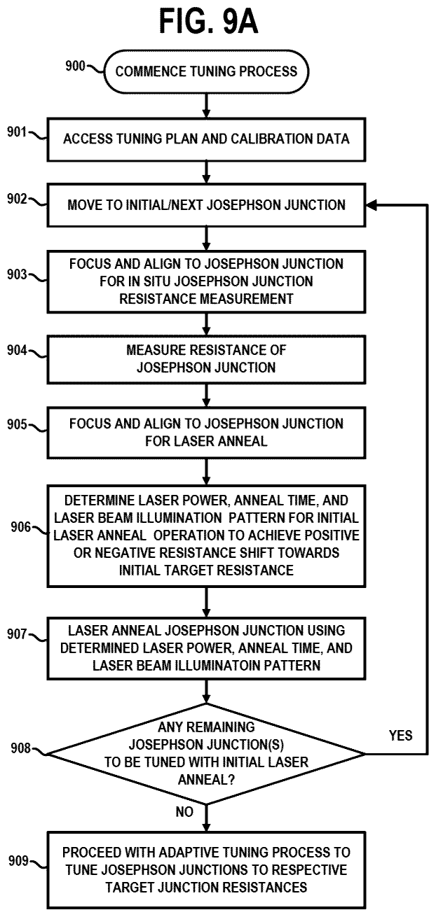

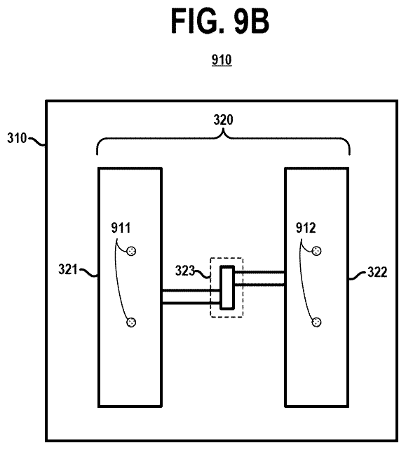

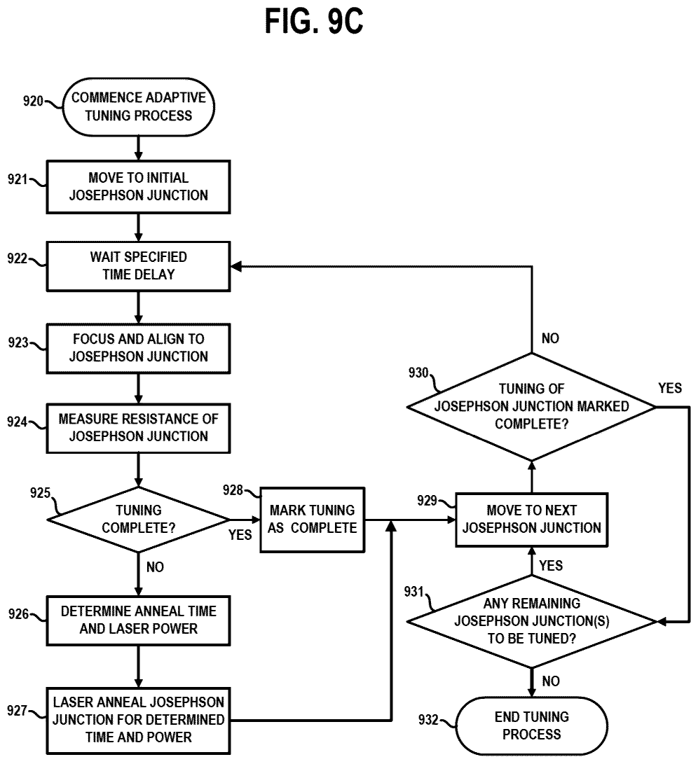

As noted above, the exemplary bidirectional tuning curves and associated tuning calibration parameters are utilized to calibrate laser annealing operations for tuning Josephson junctions to respective target junction resistances. For example, the bidirectional tuning curves and associated tuning calibration parameters can be used to calibrate the initial laser tuning operations (initial shots) that are performed on Josephson junctions to partially tune the Josephson junctions to respective target junction resistances by an amount that corresponds to an initial tuning resistance shift ΔRᵢₙᵢₜᵢₐₗ=F×ΔR_{target}. In some embodiments, an initial tuning factor of F≈50% is chosen to appreciably tune the Josephson junctions toward their target junction resistances R_{target}, while mitigating the risk of overshooting R_{target}. For example, FIG. 9A illustrates a flow diagram of a method for tuning Josephson junctions, according to an exemplary embodiment of the disclosure. In some embodiments, FIG. 9A illustrates an automated tuning process, which can be performed using the laser annealing system 100 of FIG. 1, to laser tune Josephson junctions to respective R_{target} values and thereby tune superconducting qubits in a qubit lattice on a quantum chip to respective target transition frequencies as specified by a frequency tuning plan.

For example, a quantum chip is placed on the X-Y-Z stage 142 of the prober unit 140, and the control system 110 commences an automated laser tuning process (block 900). The quantum chip comprises a plurality of superconducting qubits arranged in a given qubit lattice. The tuning process accesses a frequency tuning plan generated for the given qubit lattice, and tuning calibration data (e.g., bidirectional tuning curves and associated calibration parameters) associated with the Josephson junctions of the superconducting qubits (bock 901). In some embodiments, the frequency tuning plan specifies respective R_{target} values for the Josephson junctions, as well as calibration parameters for determining suitable laser power settings, anneal times, and laser beam illumination patterns for laser annealing the Josephson junctions of the superconducting qubits.

The automated tuning process selects an initial Josephson junction of an initial superconducting qubit in the lattice and moves to the selected Josephson junction (block 902). In particular, the control system 110 moves the X-Y-Z stage 142 to place the initial Josephson junction into the FOV of the microscope unit 130. In particular, the control system 110 moves the X-Y-Z stage 142 to place the initial Josephson junction into the FOV of the microscope unit 130. The tuning process initiates control operations to cause the microscope unit and the probe unit to perform a focus and alignment process to ensure a proper focus to the focal plane and proper alignment of the target Josephson junction within the FOV of the microscope unit 130 for the purpose of performing an in-situ Josephson junction resistance measurement (block 903). The focus ensures that the sample plane (e.g., the plane which contains the target Josephson junction) is at the focal plane (i.e., plane of focus) of the objective lens 137. The focus can be adjusted by adjusting the Z position of the X-Y-Z stage 142. The alignment to the Josephson junction can be performed using a machine learning pattern recognition process to align the Josephson junction to the center of the FOV.

Next, the tuning process proceeds to measure the junction resistance of the target Josephson junction (block 904). In particular, the tuning process measures an initial junction resistance Rᵢₙᵢₜᵢₐₗ of the Josephson junction. In some embodiments, the electrical probes 144 are landed on the contact pads with a fixed displacement distance and overdrive to ensure proper contact (e.g., a stable, low resistance contact). In some embodiments, the electrical probes 144 are vertically moved downward to contact the tips of the electrical probes 144 to the contact pads on the quantum chip. In other embodiments, the positions of the electrical probes 144 remain fixed, and the Z position of the X-Y-Z stage 142 is moved upward so that the contact pads on the quantum chip are moved into contact with the tips of the electrical probes 144 (in which case a second focus and alignment step can be performed subsequent to the junction resistance measurement and prior to the initial laser annealing step as discussed below).

In some embodiments, an in-situ junction resistance measurement is performed by contacting the electrical probes with contact pads of the target Josephson junction and then applying a test DC voltage to the Josephson junction to generate and measure a resulting DC current to determine the junction resistance. In some embodiments, as noted above, the junction resistance is determined using a 4-wire (Kelvin) probe resistance measurement operation, whereby a constant current is passed through the Josephson junction, and a resulting voltage across the Josephson junction is measured, and the junction resistance is determined based on the magnitude of the constant current and the measured voltage. In some or other embodiments, the junction resistance is determined using a 4-wire (Kelvin) probe resistance measurement operation, whereby a constant voltage is sourced across the Josephson junction, and the resulting current is measured, and the junction resistance is determined based on the magnitude of the constant voltage and the measured current. Moreover, in some embodiments, contact resistance and contact stability checks are initially performed, prior to performing the junction resistance measurement, to ensure that the contact resistance is below a given threshold, and to ensure that the contact between the electrical probe and the contact pads of the Josephson junction and stable and not intermittent.

For example, FIG. 9B schematically illustrates a process 910 for aligning electrical probes to contact pads of a Josephson junction of quantum bit to perform an in-situ junction resistance measurement, according to an exemplary embodiment of the disclosure. In some embodiments, FIG. 9B schematically illustrates the process steps that are implemented in blocks 903 and 904 of FIG. 9A. In particular, FIG. 9B schematically an exemplary FOV 310 and superconducting qubit 320, as discussed above in conjunction with FIG. 3A, and an exemplary process 910 aligning and contacting a plurality of electrical probes 911 and 912 (e.g., probe tips) with the first and second superconducting pads 321 and 322 of the superconducting qubit 320. In particular, FIG. 9B illustrates an electrical probe configuration to implement a 4-wire (Kelvin) resistance measurement, wherein the electrical probes 911 comprise two probes that make contact to the first superconducting pad 321, and wherein the electrical probes 912 comprise two probes that make contact to the second superconducting pad 322. In this embodiment, the first and second superconducting pads 321 and 322 of the superconducting qubit 320 serve as the contact pads of the Josephson junction 323 on which the electrical probes 911 and 912 are landed to perform an in-situ junction resistance measurement.

In some embodiments, a template image is used to perform a pattern recognition alignment process to align the electrical probes 911 and 912 for contact to the first and second superconducting pads 321 and 322 of the superconducting qubit 320. In some embodiments, the template image that is used to perform the pattern recognition alignment process comprises an image of the entirety of the superconducting qubit 320 including first and second superconducting pads 321 and 322, and the Josephson junction 323. In other embodiments, the template image that is used to perform the pattern recognition alignment process comprises an image of the Josephson junction 323.

Referring again to FIG. 9A, Next, the tuning process initiates control operations to cause the microscope unit 130 and the prober unit 140 to perform a focus and alignment process to ensure a proper focus to the focal plane and proper alignment of the target Josephson junction within the FOV of the microscope unit 130 for the purpose of performing a laser anneal operation (block 905). The tuning process proceeds to determine a target combination of laser power, anneal time, and laser beam illumination pattern to configure the initial laser anneal operation (initial shot) in a manner that is sufficient to achieve a partial tuning of the Josephson junction (block 906) via either a positive resistance shift (increase junction resistance) or a negative resistance shift (decrease junction resistance), as needed, to shift the resistance of the Josephson junction by an initial tuning resistance shift ΔRᵢₙᵢₜᵢₐₗ=F×ΔR_{target}, where ΔRᵢₙᵢₜᵢₐₗ=R_{initial_target}−Rᵢₙᵢₜᵢₐₗ.

For a positive resistance tuning, R_{initial_target}=Rᵢₙᵢₜᵢₐₗ+ΔRᵢₙᵢₜᵢₐₗ. On the other hand, for a negative resistance tuning, R_{initial_target}=Rᵢₙᵢₜᵢₐₗ−ΔRᵢₙᵢₜᵢₐₗ. In some embodiments, as noted above, the initial tuning factor F is selected to be F≈50% to appreciably tune the Josephson junction towards its target junction resistance R_{target}, while mitigating the risk of overshooting R_{target} on the initial laser annealing shot. Moreover, as noted above, the computed value of ΔRᵢₙᵢₜᵢₐₗ is utilized to determine a resistance shift percentage ΔR % which, in turn, can be used to determine a given combination of laser power, anneal time, and laser beam illumination pattern, to calibrate the initial laser tuning operation (initial shot) to achieve the initial tuning resistance shift ΔRᵢₙᵢₜᵢₐₗ (based on the measured initial junction resistance Rᵢₙᵢₜᵢₐₗ, and the computation

$$Δ R \% = \frac{Δ {R}_{i n i t i a l}}{{R}_{i n i t i a l}} \times 100 \% ) .$$

The tuning process performs the initial laser anneal operation (initial shot) on the given Josephson junction using the determined combination of laser power setting, anneal time, and laser beam illumination pattern, to achieve the desired amount of positive resistance shift to target, or negative resistance shift to target, for the initial shot (block 907). After completion of the initial laser anneal operation for the given Josephson junction, the tuning process determines whether there are any remaining Josephson junctions that need to be initially tuned to their respective initial tuning resistance shift ΔRᵢₙᵢₜᵢₐₗ using an initial laser anneal operation (block 908). If there are one or more Josephson junctions that need to be to be tested (affirmative determination in block 908), the tuning process selects a next Josephson junction of a next superconducting qubit to be tuned (return to block 902) and repeats the laser tuning operations (repeat blocks 903, 904, 905, 906, and 907).

On the other hand, if it is determined that there are no remaining Josephson junctions that need to be tuned to their respective initial tuning resistance shift ΔRᵢₙᵢₜᵢₐₗ using an initial laser anneal operation (negative determination in block 908), the tuning process proceeds to tune each Josephson junction to its respective target junction resistance R_{target} using an adaptive tuning process (block 908). At the completion of the adaptive tuning process, it is assumed that each Josephson junction comprises junction resistance which is at the target junction resistance R_{target} or near the target junction resistance R_{target} within some specified threshold percentage of the target junction resistance R_{target}, i.e.,

$$\frac{\vert {R}_{t a r g e t} - {R}_{c u r r e n t} \vert}{{R}_{t a r g e t}} \leq x ( e . g . , x = 0.003 ( or 0.3 \% ) ) .$$

With each Josephson junction having a junction resistance which is at or near its target junction resistance R_{target}, it is assumed that each corresponding superconducting qubit has been tuned successfully and within a corresponding bound of precision to its respective target transition frequency.

In some embodiments, an adaptive tuning process (block 909) comprises an iterative laser tuning process for tuning the junction resistances of the Josephson junctions by implementing an asymptotic tuning methodology in which Josephson junctions of, e.g., qubits on a given multi-qubit device are adaptively and progressively tuned in an incremental manner to progressively shift junction resistances towards respective target junction resistances of the Josephson junctions. In some embodiments, adaptive and progressive tuning of a given Josephson junction is implemented by adaptively determining the anneal time (tₛₕₒₜ) for a given tuning iteration at a given laser power level based on a function of (i) an amount of resistance shift remaining (ΔR_{remaining}) to reach the target junction resistance, and (ii) a total amount of anneal time spent for previous laser anneal iterations applied to the Josephson junction.

For example, an exemplary function for determining an anneal time (tₛₕₒₜ) for a given “shot” at a given laser power level is expressed as:

$${t}_{shot} ( {N}_{A} ) = \frac{Δ {R}_{t a r g e t} - Δ R}{Δ {R}_{t a r g e t}} \cdot {\sum }_{i = 1}^{{N}_{A} - 1} {t}_{shot} ( i ) for [ {N}_{A} > 1 ] ,$$

where N_{A} denotes an anneal number (or “shot” number), where, as noted above, ΔR_{target} denotes a difference between a target junction resistance (R_{target}) of a given Josephson junction and an initial measured resistance (denoted Rᵢₙᵢₜᵢₐₗ) of the given Josephson junction before the initial anneal operation (at N_{A}=0), and where ΔR denotes a difference between Rᵢₙᵢₜᵢₐₗ and a currently measured junction resistance (denoted R_{current}) of the given Josephson junction, which is measured in a given iteration before applying the next “shot” based on the computed anneal time tₛₕₒₜ for the given iteration. In other words, ΔR_{target}=R_{target}−Rᵢₙᵢₜᵢₐₗ, ΔR=R_{current}−Rᵢₙᵢₜᵢₐₗ, and ΔR_{remaining}=R_{target}−R_{current}. In the context of an adaptive tuning process, the parameter R_{current} denotes a current junction resistance that is measured at the beginning of each successive iteration of the adaptive tuning process, and the computation tₛₕₒₜ is performed for each successive iteration of the adaptive tuning process to determine a target anneal time for performing the laser anneal operation for given iteration. As noted above, the laser power level that is used in each iteration is the laser power level that was initially selected to perform the initial laser annealing operation (block 906, FIG. 9A). Note also that the exemplary function for determining anneal time (tₛₕₒₜ) for a given shot is valid for both positive and negative resistance tuning. That is, the ratio of ΔR_{remaining} and ΔR_{target} is always positive regardless of the directionality of tuning, as long as the junction resistance has not yet reached its target value.

In the exemplary function for computing tₛₕₒₜ, the ratio

$$\frac{Δ {R}_{t a r g e t} - Δ R}{Δ {R}_{t a r g e t}} = \frac{Δ {R}_{r e m a i n i n g}}{Δ {R}_{t a r g e t}}$$

provides a weight factor that represents a percentage of the amount of a remaining amount of resistance shift needed to reach the target junction resistance R_{target} of the given Josephson junction based on the total resistance shift needed to reach the target junction resistance R_{target} starting from the initial measured junction resistance Rᵢₙᵢₜᵢₐₗ of the given Josephson junction. In addition, the summation Σᵢ₌₁^{N}^{_{A}}⁻¹ tₛₕₒₜ (i) provides weight factor based on the sum total time of all anneal times (total amount of all determined tₛₕₒₜ times) of all previous “shots” applied to the given Josephson junction. It is to be noted that the exemplary function for tₛₕₒₜ provides a linear combination of weight factors based on a product of ΔR_{remaining} and the total historical anneal time. In other embodiments, a function for computing tₛₕₒₜ can be based on other parameters and/or based on a non-linear function of the parameters ΔR_{remaining} and the total historical anneal time and/or other parameters, depending on, e.g., the application and/or the tuning characteristics of the Josephson junction as determined based on the associated tuning calibration data obtained using the calibration techniques as discussed herein.

Based the exemplary parameters of the function tₛₕₒₜ, at a given iteration of the tuning process, if the measured junction resistance indicates that there is a relatively large amount of resistance shift still needed to reach the target junction resistance R_{target}, the determined anneal time, tₛₕₒₜ, will be weighted (by the ratio

$$\frac{Δ {R}_{r e m a i n i n g}}{Δ {R}_{t a r g e t}} )$$

to be longer. On the other hand, if there is a relatively small amount of resistance shift needed to reach the target junction resistance R_{target}, the anneal time, tₛₕₒₜ, will be weighted (by the ratio

$$\frac{Δ {R}_{r e m a i n i n g}}{Δ {R}_{t a r g e t}} )$$

to be shorter. As another example, if the summation Σᵢ₌₁^{N}^{_{A}}⁻¹ tₛₕₒₜ (i) at a given iteration (e.g., at a given N_{A}) of the tuning process indicates a relatively large total amount of annealing has been performed on the given Josephson junction, this provides an indication that the given Josephson junction is tuning slowly, so that the next anneal time, tₛₕₒₜ, will be weighted (by the sum total anneal time) to be relatively long. On the other hand, if the summation Σᵢ₌₁^{N}^{_{A}}⁻¹ tₛₕₒₜ (i) at a given iteration of the tuning process indicates a relatively small total duration of annealing has been performed on the given Josephson junction, this provides an indication that the given Josephson junction is tuning relatively fast, so that the next anneal time, tₛₕₒₜ, will be weighted (by the sum total anneal time) to be relatively short.

FIG. 9C illustrates a flow diagram of a method for tuning Josephson junctions, according to another exemplary embodiment of the disclosure. In particular, FIG. 9C illustrates an exemplary adaptive tuning process as described above which comprises, for a given Josephson junction, adaptively determining the anneal time (tₛₕₒₜ) for a given tuning iteration at a given laser power level based on a function of (i) an amount of resistance shift remaining (ΔR_{remaining}) to reach the target junction resistance of the given Josephson junction, and (ii) a total amount of anneal time spent for previous laser anneal iterations applied to the given Josephson junction. In some embodiments, the process of FIG. 9C can be utilized to implement the adaptive tuning process in block 909 of FIG. 9A.

Referring to FIG. 9C, the control system 110 (FIG. 1) commences an adaptive tuning process (block 920) wherein, in some embodiments, as noted above, the adaptive tuning process is commenced subsequent to completing the laser tuning process of FIG. 9A in which the Josephson junctions are partially tuned via the respective initial laser tuning operations (initial shots) calibrated to achieve the respective initial tuning (positive or negative) resistance shifts: ΔRᵢₙᵢₜᵢₐₗ=F×ΔR_{target}. The adaptive tuning process selects an initial Josephson junction of a qubit and moves to the initial Josephson junction (block 921) so that the initial Josephson junction is placed into the FOV of the microscope unit 130. Before proceeding with in-situ junction resistance measurement and laser tuning operations for the initial Josephson junction, an initial time delay can be implemented in the tuning process (block 922) to provide sufficient time for the junction resistances of the Josephson junctions to settle to a stable resistance state for purposes of accommodating aging resistance shifts, which may occur post-fabrication, or due to any post-fabrication process.

In addition, during subsequent iterations, a specified time delay (block 922) may be implemented to account for post-tuning resistance shifts. For example, Josephson junctions may undergo aging drift due to various material relaxation processes, which result in the junction resistances shifting or drifting slightly over time. The time delay (in block 922) can be selected to allow these relaxation processes to satisfactorily progress such that the junction resistance settles closer to their final value, thus giving a more accurate junction resistance measurement and progression towards a target junction resistance. In some embodiments, the time delay can be on the order of, e.g., a minute (or minutes), or an hour (or hours), etc., or any time as needed to allow the Josephson junctions to settle to a stable resistance state following the completion of a laser anneal tuning (shot) of a previously tuned Josephson junction.

Following expiration of the initial time delay, the adaptive tuning process initiates control operations to cause the microscope unit and the probe unit to perform a focus and alignment process to ensure a proper focus to the focal plane and proper alignment of the target Josephson junction within the FOV of the microscope unit 130 for the purpose of performing an in-situ Josephson junction resistance measurement (block 923). Next, the adaptive tuning process proceeds to perform an in-situ resistance measurement operation to measure the junction resistance of the Josephson junction (block 924) using the same or similar techniques as discussed above.

The tuning process then determines whether the tuning is complete for the given Josephson junction (block 925). For example, in some embodiments, the tuning process determines whether the measured junction resistance R_{current} of the given Josephson junction is at or near the target junction resistance R_{target} for the given Josephson junction. For example, in some embodiments, it is assumed that the given Josephson junction comprises junction resistance which is at the target junction resistance R_{target} or near the target junction resistance R_{target} within some specified threshold percentage of the target junction resistance R_{target}, i.e.,

$$\frac{\vert {R}_{t a r g e t} - {R}_{c u r r e n t} \vert}{{R}_{t a r g e t}} \leq x ( e . g . , x = 0.003 ( or 0.3 \% ) ) .$$

With the Josephson junction having a junction resistance which is at or near its target junction resistance R_{target}, it is assumed that the corresponding superconducting qubit has been tuned successfully and within a corresponding bound of precision to its respective target transition frequency. In this instance, the if the tuning of the given Josephson junction is deemed complete (affirmative determination in block 925), the tuning of the given Josephson junction is marked as complete (block 928), and the process proceed to move to the next Josephson junction (block 929).

On the other hand, if it is determined that the tuning of the given Josephson junction is not yet complete (negative determination in block 925), the tuning process proceeds to prepare a laser anneal operation. For example, the adaptive tuning process initiates control operations to cause the microscope unit 130 and the prober unit 140 to perform a focus and alignment process to ensure a proper focus to the focal plane and proper alignment of the target Josephson junction within the FOV of the microscope unit 130 for the purpose of enabling alignment of a laser beam illumination pattern to the Josephson junction to perform the laser anneal operation. In addition, the adaptive tuning process proceeds to determine the “shot” anneal time and laser power to utilize for laser annealing the given Josephson junction for the given iteration, based on the currently measured junction resistance (block 926). The anneal time (tₛₕₒₜ) for the current “shot” is adaptively determined as discussed above. Moreover, as noted above, in some embodiments, the laser power level and laser beam illumination pattern that is used in each iteration for the given Josephson junction is the laser power level and laser beam illumination pattern that was initially selected to perform the initial laser annealing operation of the given Josephson junction (block 906, FIG. 9A). The laser anneal operation (shot) is performed using the adaptively determined anneal time (tₛₕₒₜ) and same combination of laser power and laser beam illumination pattern (as in previous interactions for the given Josephson junction) to laser anneal the given Josephson junction (block 927).

After completion of the current “shot” (block 927), the tuning process proceeds to select a next Josephson junction for tuning (block 929) and determines whether the tuning of the next Josephson junction is marked complete (block 930). If it is determined that the tuning is not marked complete for the next Josephson junction (negative determination in block 930), the iterative tuning process (blocks 922, 923, 924, 925, 926, and 927) is performed on the next Josephson junction until tuning is deemed complete for that Josephson junction. On the other hand, if it is determined that the tuning is marked complete for the next Josephson junction (affirmative determination in block 930), the tuning process determines if there are any remaining Josephson junctions that need to be tuned (block 931). If it is determined that there is one or more Josephson junctions that need to be tuned (affirmative determination in block 931), the tuning process proceeds to a next Josephson junction for tuning (block 929). If it is determined that there are no remaining Josephson junctions that need to be tuned (negative determination in block 931), the tuning process is terminated (block 932). In this instance, it is assumed that each Josephson junction is tuned to its respective target junction resistance and, consequently, each corresponding qubit has been tuned to its respective target transition frequency.

It is to be noted that FIG. 9C illustrates an exemplary embodiment of an iterative tuning process in a round-robin format, wherein each round-robin involves iterating through all Josephson junctions. For each iteration, a different Josephson junction is measured and “shot” one time to achieve an incremental junction resistance shift, such that each successive iteration is performed on a different Josephson junction on the quantum chip. In other words, the process flow of FIG. 9C is designed such that each round-robin involves the tuning of all incomplete Josephson junctions on the quantum chip, and the round-robin process is repeated until all junction targets are achieved. The exemplary embodiment of FIG. 9C provides a benefit of allowing all junctions to complete tuning within a similar time span, thus mitigating effects of relative aging and drift of junction resistances in cases where such drift is of principal concern.

The exemplary laser tuning methods as shown in FIGS. 9A and 9C are contrasted with conventional tuning methods in which Josephson junctions are tuned to a target junction resistance using a single laser shot, which is unpredictable. The exemplary junction tuning techniques as disclosed herein are configured to perform an initial “shot” on a given Josephson junction to shift the junction resistance (positive shift or negative shift) from the initial resistance (Rᵢₙᵢₜᵢₐₗ) to a junction resistance that is, e.g., about 50% to the target junction resistance (R_{target}), following by iteratively tuning the junction resistance of the given Josephson junction using multiple shots with anneal times that are adaptively determined for each shot to ensure a gradual approach to a target junction resistance, while accounting for relaxation of the junction resistances after laser annealing, which may require a period of time delay to settle closer to their final values.

In an exemplary embodiment of a laser tuning progression after the first shot, the junctions (starting from the first, and progressing to the last) are each shot once in succession, and the process repeats starting at the first junction again. In this manner, the first junction resistance has time to relax and stabilize close to its final value prior to the subsequent shots. In another embodiment of a laser tuning progression after the first shot, each junction may be iteratively annealed to completion prior to annealing the next junction. In this case, a time delay may be implemented in between successive anneal iterations on the same junction, to allow the junction resistances to relax and stabilize near their final values to improve the accuracy of approaching resistance targets.

It is to be appreciated that the exemplary bidirectional tuning techniques discussed herein can be utilized for correcting target resistance overshoot errors and undershoot errors, which may occur when laser tuning Josephson junctions (e.g., LASIQ process). In the description of the process flow of FIG. 9C, it was assumed that each Josephson successfully reached its respective target resistance. However, there can be instances where tuning a given Josephson junction to its target resistance has failed due to either tuning overshoot or a tuning undershoot. A tuning overshoot occurs when the resistance of the given Josephson junction has been tuned past its target resistance. On the other hand, a tuning undershoot occurs when, e.g., when the resistance of the given Josephson junction cannot be tuned to the target resistance due to a tuning range limit of the given Josephson junction. In certain instances, a tuning failure can be corrected using bidirectional tuning techniques.

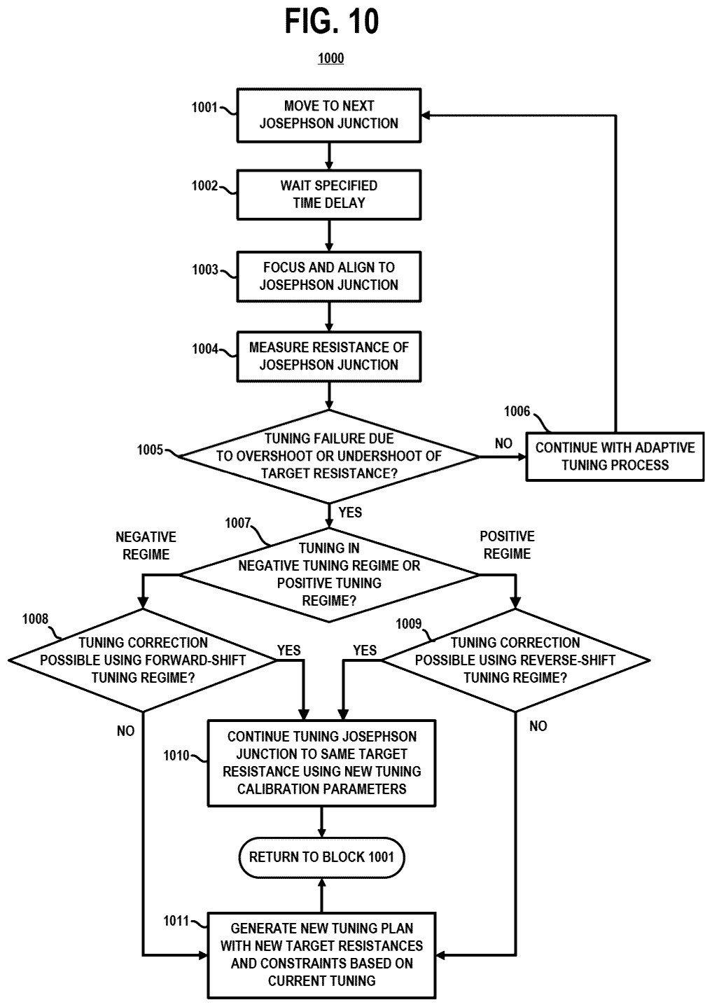

For example, FIG. 10 illustrates a flow diagram of a method for utilizing bidirectional tuning during a laser tuning process to correct for tuning errors in reaching target resistances of Josephson junctions, according to an exemplary embodiment of the disclosure. In some embodiments, FIG. 10 illustrates a tuning process 1000 which can be incorporated as part of the adaptive tuning process of FIG. 9C. In such embodiments, as discussed above, for a given laser tuning iteration, the tuning process 1000 selects and moves to a next Josephson junction of a qubit (block 1001), waits for a specified delay time before proceeding with an in-situ junction resistance measurement and laser tuning operation for the selected Josephson junction to provide sufficient time for the junction resistances of the Josephson junctions to settle to a stable resistance state (block 1002), initiates control operations to cause the microscope unit and the probe unit to perform a focus and alignment process to ensure a proper focus to the focal plane and proper alignment of the target Josephson junction within the FOV of the microscope unit 130 for the purpose of performing an in-situ Josephson junction resistance measurement (block 1003), and then performs an in-situ resistance measurement operation to measure the junction resistance of the Josephson junction (block 1004), using the same or similar techniques as discussed above.

The tuning process then determines whether the tuning is complete for the given Josephson junction and if tuning is not complete, whether there is a tuning failure due to an overshoot or undershoot of the target resistance (block 1005). If the tuning process determines that tuning is not yet complete and that no tuning error has occurred (negative determination in block 1005), the tuning process proceeds with laser annealing the Josephson junction using the adaptive tuning process (block 1006), such as discussed above in conjunction with FIG. 9C. On the other hand, if the tuning process determines that a tuning error has occurred (affirmative determination in block 1005), the tuning process will proceed to determine whether the adaptive tuning of the given Josephson junction comprises (i) positive resistance shift tuning in a positive tuning regime or (ii) negative resistance shift tuning in a negative tuning regime (block 1007).

If the adaptive tuning of the given Josephson junction comprises negative resistance shift tuning in a negative tuning regime, the tuning process will determine whether corrective tuning is possible using a forward-shift tuning regime (block 1008). A corrective tuning is possible if there is an overshoot error in the negative resistance shift to target, and there exists tuning calibration parameters of a forward-shift tuning regime, which can be used to increase the junction resistance back towards the target junction resistance. If the tuning process determines that corrective tuning is possible using a forward-shift tuning regime (affirmative determination in block 1008), the tuning process will recalibrate the tuning process with new tuning calibration parameters to perform corrective tuning via forward-shift tuning, and continue tuning the Josephson junction to the same target junction resistance but using the new tuning calibration parameters (block 1010).

On the other hand, if the adaptive tuning of the given Josephson junction comprises positive resistance shift tuning in a positive tuning regime, the tuning process will determine whether corrective tuning is possible using a reverse-shift tuning regime (block 1009). A corrective tuning is possible if there is an overshoot error in the positive resistance shift to target, and there exists tuning calibration parameters of a reverse-shift tuning regime, which can be used to decrease the junction resistance back towards the target junction resistance. If the tuning process determines that corrective tuning is possible using a reverse-shift tuning regime (affirmative determination in block 1009), the tuning process will recalibrate the tuning process with new tuning calibration parameters to perform corrective tuning via reverse-shift tuning, and continue tuning the Josephson junction to the same target junction resistance but using the new tuning calibration parameters (block 1010).

There can be instances where the tuning process determines that tuning correction is not possible (negative determination in block 1008 or block 1009). For example, an undershoot tuning error resulting from an unanticipated tuning range limit of the given Josephson junction cannot be corrected via a forward-shift tuning regime or reverse-shift tuning regime. In addition, as noted above, there may be instances where there are no calibration parameters corresponding to a forward-shift tuning regime or reverse-shift tuning regime for a given power level setting and illumination pattern that can be used for corrective tuning the given Josephson junction to target. In such instances, if tuning correction is not possible (negative determination in block 1008 or block 1009), the tuning process can proceed to generate a new tuning plan with new target resistances for the Josephson junctions and new constraints based on the current tuning states of the Josephson junctions (block 1011).

It is to be appreciated that the exemplary bidirectional tuning techniques as discussed herein allow for more precise tuning of target resistances of Josephson junctions and, thus, more precise tuning of transition frequencies of qubits as specified in a given frequency tuning plan to minimize frequency collisions and gate errors. The bidirectional tuning of junction resistances of Josephson junctions allows for the correction of junction resistance overshoot and undershoot errors, provided that such errors are within correction tuning ranges of the Josephson junctions. The bidirectional correction tuning, in turn, allows a LASIQ process to achieve a final tuning that is close to the specified targets of the given frequency tuning plan.

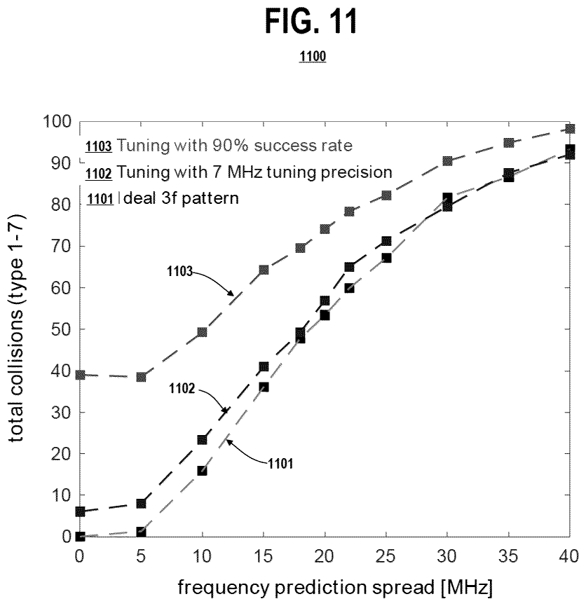

FIG. 11 graphically depicts Monte Carlo simulations which illustrate an improvement in qubit frequency tuning that can be achieved using bidirectional correction tuning of Josephson junctions, according to an exemplary embodiment of the disclosure. In particular, FIG. 11 is a graph 1100 which shows a plurality of curves 1101, 1102, and 1103 that represent a total number of frequency collisions (Y-axis) as a function of frequency prediction spread in MHZ (X-axis). In particular, the X-axis represents a predicted frequency spread of qubit frequencies. While qubit transition frequencies of qubits can be estimated based on respective target resistances of the Josephson junctions of the qubits, such estimations are imprecise, and the actual transition frequency of given qubit (when tested in a cryogenic environment) can vary by some amount. In this regard, the frequency spread values (e.g., 20 MHZ) on the X-axis represent the amount (e.g., ±20 MHZ) by which actual qubit frequency deviates from the predicted qubit frequency. The Y-axis represents a total number of frequency collisions as a function frequency prediction spread, wherein the total number of frequency collisions is based on a plurality of different types of frequency collisions that can occur within a given qubit lattice or array based on the given qubit lattice architecture. In the particular case depicted in 1100, all 7 collision types are included in the total collision determination. However, in some implementations, a subset or superset of these collisions may be considered depending on the desired application of the quantum processor.

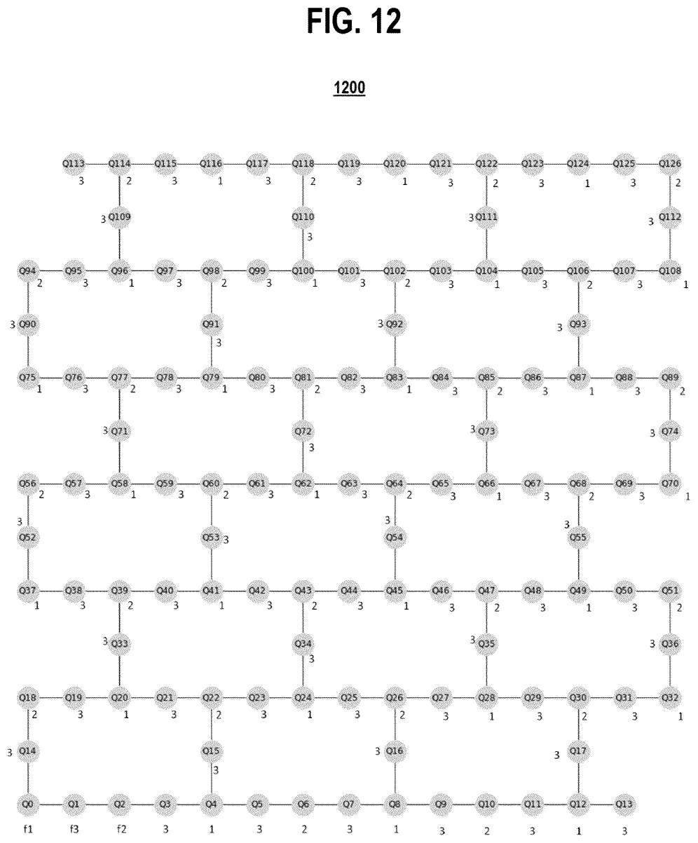

For example, FIG. 12 schematically illustrates an exemplary qubit lattice comprising a heavy-hexagonal qubit lattice, according to an exemplary embodiment of the disclosure. In particular, FIG. 12 schematically illustrates an exemplary qubit lattice 1200 having 127 qubits Q0, Q1, Q2, . . . , Q126 (e.g., fixed-frequency transmon qubits) arranged in a heavy-hexagonal array and comprising a three-frequency (3f) pattern wherein the qubits are assigned one of three different frequencies f1, f2, and f3, where f3>f2>f1 (as denoted by the corresponding numbers 1, 2, and 3 as shown in FIG. 12). The 3f pattern is configured to avoid/mitigate frequency collisions (e.g., 7 types of frequency collisions) by between qubits by properly assigning nearest-neighbor and next-nearest neighbor qubit frequency detuning to achieve low gate error regimes. However, frequency collision avoidance is challenging given tuning range constraints (typically 15% resistance), and as-fabricated spread (4-5% resistance), which result in deviations from the ideal 3f pattern for tuning plans, since ideal 3f tuning plans are not typically achievable in practice.

Referring back to FIG. 11, the curve 1101 represents the tuning that is achieved based on an ideal 3f pattern with a 65 MHz frequency level spacing, which in practice is not completely achievable. However, we may still use such a 3f pattern as a reference tuning pattern, to demonstrate the utility of bidirectional tuning correction. On the other hand, the curve 1102 represents a successful tuning (which is close to the ideal tuning represented by the curve 1101) that can be practically achieved assuming that the tuning can be achieved with 7 MHz precision of qubit frequency based on a minimal imprecision in the resistance tuning of Josephson junctions to their target resistances. The curve 1103 represents a simulated tuning that is achieved with a 90% success rate in Josephson junction tuning, e.g., about 13 qubits of the 127 qubits in the exemplary qubit lattice 1200 of FIG. 12 are assumed to have corresponding Josephson junctions with respective junction resistances that have overshot or undershot the target junction resistance. Thus, curve 1103 shows the impact of 10% of junctions not reaching their tuning success band. Notably, as-tuned, there are 40 total type-1 through 7 collisions (as seen at 0 MHz frequency spread), and this value increases with increasing frequency prediction spread. However, by utilizing bidirectional tuning correction method as discussed herein, the resistance tuning errors can be corrected in a matter such that the curve 1103 converges closer to the curve 1102, which is desirable given the significantly lower as-tuned collision counts, and subsequently lower collision counts for all frequency spread values. The curve 1102 also converges to curve 1101, demonstrating that with bidirectional frequency control and tuning correction, the improved tuning yield of the chip directly results in increased functional yield by reducing overall collision counts, thereby increasing gate-fidelities.

When generating a frequency tuning plan, a goal is to arrange the qubit transition frequencies into a pattern where there are no frequency collisions among neighboring qubits. Typically, such neighboring qubits may, for example, be nearest-neighbor qubits which are in direct connection with each other, or next-nearest-neighbor qubits which are separated by a connecting qubit. Higher degrees of neighbor separation may be considered depending on the specific use case of the processor. In other words, the frequency tuning plan is designed to mitigate frequency crowding by tuning the transition frequency f₀₁ of a given superconducting qubit in some target frequency range where transition frequency f₀₁ of the given superconducting qubit does not conflict (e.g., collide) with the |0 [symbol] to |1 [symbol] transition frequency f₀₁ or higher-energy transitions (e.g., with the |0 [symbol] and second excited state |2 [symbol] , or f₀₂) of a neighboring superconducting qubit. In doing so, the frequency tuning plan generation process utilizes the initial measured junction resistances (Rᵢₙᵢₜᵢₐₗ) of the Josephson junctions, together with the tuning range calibration data (e.g., the maximum tuning range ΔR % data) to know the tuning constraints for laser tuning the junction resistances of the Josephson junctions which, in turn, places constraints on the frequency tuning of the superconducting qubits. This data allows the frequency tuning plan generation process to know how much the transition frequencies of the qubits can be trimmed, and thereby generate a suitable frequency tuning plan based on such tuning constraints.

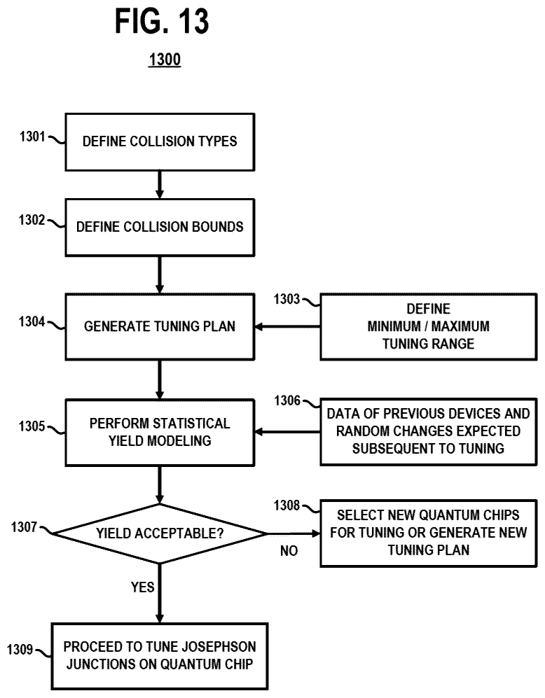

FIG. 13 illustrates a flow diagram of a method 1300 for generating a frequency tuning plan, according to an exemplary embodiment of the disclosure. As noted above, a frequency tuning plan is generated to perform LASIQ tuning of the transition frequencies of superconducting qubits to avoid frequency collisions in the qubit lattice when performing gate operations (e.g., single gate operations, multi-gate operations (e.g., two-qubit gate entanglement operations, etc.) on a quantum chip (e.g., quantum processor). The method 1300 involves defining/determining a plurality of key constraints for a given frequency tuning plan including defining various types of frequency collisions that may occur based on a given qubit lattice architecture (block 1301), defining bounds of such collisions (block 1302), and defining tuning ranges, e.g., minimum and maximum tuning ranges (block 1303). In some embodiments, the maximum tuning ranges are derived from the tuning range calibration data (e.g., maximum negative tuning ranges and maximum positive tuning ranges) by analyzing the calibration data obtained from laser annealing calibration tests performed on the groups of test Josephson junctions, using the exemplary techniques as discussed above.

The process proceeds to generate an initial frequency tuning plan (block 1304) based on, e.g., the defined collision types, the frequency collision bounds for each collision type, the maximum/minimum tuning ranges, etc. In some embodiments, the tuning plan generation process determines respective target junction resistances (R_{target}) for the Josephson junctions of the superconducting qubits to achieve frequency collision avoidance. More specifically, in some embodiments, the tuning plan generation process determines the respective target junction resistances (R_{target}) for the Josephson junctions of the qubits based on initial measured junction resistances (Rᵢₙᵢₜᵢₐₗ) of the Josephson junctions and the tuning range calibration data associated with the Josephson junctions of the qubits. The target junction resistances (R_{target}) of the respective Josephson junctions of the qubits are utilized to predict the target transition frequencies of the respective qubits.

After generating a frequency tuning plan, the process performs a yield estimate process to analyze the frequency tuning plan (block 1305). In some embodiments, the yield estimate process is performed using Monte Carlo simulations to statistically determine how many frequency collisions are expected based on the given frequency tuning plan, and performing other analytical processes for gamma computations, gate error modeling, etc. In some embodiments, a statistical yield modeling process is performed using historical data (1306) comprising historical frequency spreads associated with previous devices and random changes expected subsequent to tuning. As noted above, typically, an ideal frequency tuning plan cannot be achieved, but for a given qubit lattice architecture (e.g., heavy hexagonal lattice, square lattice, etc.), there is an ideal frequency pattern that can be utilized to minimize the number of frequency collisions, but nevertheless, an ideal frequency tuning plan is difficult to achieve because of the limited tuning ranges of Josephson junctions. However, having a priori knowledge of expected maximum junction resistance tuning ranges (via the tuning range calibration data) provides useful information that enables the frequency tuning plan generation process to determine an optimal frequency tuning plan for the given qubit lattice with qubit Josephson junctions with the added constraint of anticipated tuning ranges correspond to the calibration data. The tuning range of the Josephson junction therefore poses an additional practical constraint that must be satisfied in any tuning plan that is used to mitigate frequency collisions.

After analyzing the frequency tuning plan, a determination is made as to whether the yield estimate of the frequency tuning plan is acceptable (block 1307). If the yield estimate of the frequency tuning plan is deemed unacceptable (negative determination in block 1307), either a new quantum chip can be selected for tuning, or a new frequency tuning plan can be generated using a new set of tuning plan parameters and analyzed (block 1308). On the other hand, if the yield estimate of the frequency tuning plan is deemed acceptable (affirmative determination in block 1307), the frequency tuning plan will be used to proceed with a process for tuning Josephson junctions of the superconducting qubits on the quantum chip (block 1309).

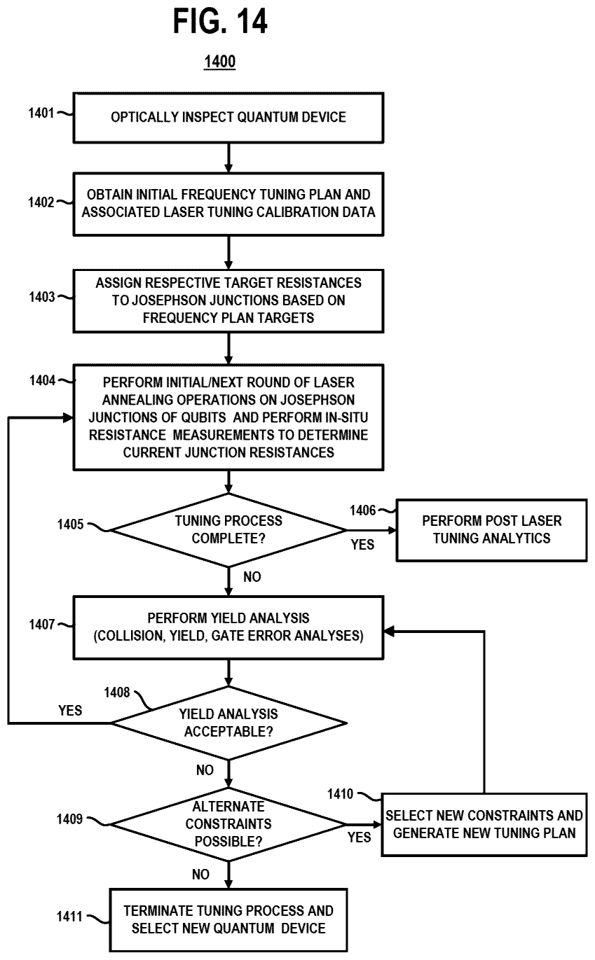

In some embodiments, an initial frequency tuning plan, which is generated using the process 1300 of FIG. 13, can be utilized to configure a LASIQ process, and the frequency tuning plan can be modified during the LASIQ process, as needed, based on the progression of the laser tuning process to ensure that the yield rate remains acceptable. For example, FIG. 14 illustrates a flow diagram of a method for tuning Josephson junctions of qubit devices of a qubit lattice based on a tuning plan, according to an exemplary embodiment of the disclosure. In particular, FIG. 14 illustrates a process 1400 to tune the transition frequencies of the superconducting qubits of a given qubit lattice (via a LASIQ tuning process), based on a frequency tuning plan that is generated and updated to eliminate or otherwise minimize the potential for frequency collisions in the given qubit lattice. The process 1400 is configured to enable in-situ, real-time adaptive modification of frequency tuning plans to mitigate collisions (from tuning imperfections), using bidirectional frequency control.

The process 1400 comprises an initial step of placing a quantum device (e.g., quantum chip or quantum wafer) on the X-Y-Z stage of the electrical characterization system (e.g., probe unit) and optically inspecting the quantum device using the optical system (e.g., modular microscope unit) for physical defects or damage (block 1401). In an exemplary embodiment, the quantum device comprises a lattice of superconducting qubits that are to be laser tuned, post fabrication, to trim the transition frequencies of the superconducting quits according to an initial frequency tuning plan generated for the lattice of superconducting qubits. If the optical inspection is deemed acceptable, the process 1400 proceeds to obtain an initially generated frequency tuning plan and associated laser tuning calibration data (block 1402). The process 1400 assigns respective target resistances to the Josephson junction (that are to be laser tuned) based on the targets specified in the frequency plan (block 1403).

The process 1400 then proceeds to perform an initial round of laser annealing operations on the Josephson junctions of the superconducting qubits (e.g., using calibrated initial shots) to shift the junction resistances of respective Josephson junctions to respective target junction resistances, and performs in-situ resistance measurements between laser annealing operations to determine the current junction resistances of the Josephson junctions (block 1404). As noted above, the laser annealing is performed in an iterative manner whereby the junction resistances of the Josephson junctions are progressively shifted toward their respective target junction resistances by performing iterative annealing operations. After a given round of laser annealing operations, a determination is made as to whether the laser tuning is complete (block 1405). When the laser tuning process is deemed complete (affirmative determination in block 1405), the process 1400 can proceed to perform post laser tuning analytics (block 1406). On the other hand, the laser tuning process will be deemed incomplete (negative determination in block 1405) if, for example, the in-situ resistance measurements indicate that some or all of the Josephson junctions are not at their respective target junction resistance.

In some embodiments, after the completion of a given round of laser annealing operations on the Josephson junctions, a yield analysis is performed (block 1407) to quantify how well the LASIQ tuning process is proceeding by quantifying collisions and zero-collision probability and gate fidelity comparing against pre-defined acceptance thresholds. In particular, in some embodiments, the yield analysis comprises performing collision analysis for nearest-neighbor and next nearest-neighbor degeneracies. In addition, a statistical analysis (e.g., Monte Carlo) is performed to identify an expected number of collisions given a frequency prediction imprecision, or set of frequency prediction imprecisions (e.g., a range from 0 MHz to 40 MHZ, such as shown in FIG. 11.). In addition, a collision yield is computed to obtain a zero-collision probability, and a gate error analysis is performed to estimate gate fidelities (error yield). The in-situ yield analysis (block 1407) allows to the tuning progress to quantified, e.g., how many frequency collisions are expected based on the current junction resistances of the Josephson junctions (and thus the corresponding current transition frequencies of the superconducting qubits) based on the given frequency tuning plan.

If the results of the yield analysis are acceptable (affirmative determination in block 1408), the current tuning plan is deemed to be acceptable and the process 1400 proceeds to perform the next round of laser annealing operations and in-situ Josephson junction resistance measurements (return to block 1401). On the other hand, if the results of the yield analysis are deemed to be unacceptable (negative determination in block 1408), the current tuning plan is deemed to be unacceptable given the existing tuning state of the Josephson junctions. As a result, the process 1400 proceeds to determine if alternate constraints are possible for revising the tuning plan to achieve a favorable yield analysis (block 1409). For example, in some embodiments, alternate constraints include, e.g., increasing the tuning range, changing frequency collision weights or collision bounds, etc.

If alternate constraints are possible (affirmative determination in bock 1409), the process 1400 proceeds to select new constraints and generate a new frequency tuning plan based on the new constraints (block 1410), and then perform a yield analysis (block 1408) based on the new frequency tuning plan and the existing tuning state of the Josephson junctions (return to block 1407). If the yield analysis for the new frequency tuning plan is deemed acceptable (affirmative determination in block 1408), the process 1400 proceeds to the next LASIQ round (return to block 1404). On the other hand, if the yield analysis for the new frequency tuning plan is deemed unacceptable (negative determination in block 1408), the tuning plan modification and yield analysis process (blocks 1408, 1409, and 1410) iterates until an acceptable frequency tuning plan is generated, and the next LASIQ tuning round is performed. If there exists a given circumstance in which no alternate constraints are possible for generating new tuning plan (negative determination in block 1409), the LASIQ process terminates for the given quantum device, and a new quantum device is selected for tuning (block 1411).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1500 of FIG. 15 contains an example of an environment for the execution of at least some of the computer code (block 1526) comprising data processing and control algorithms for performing various operations such as laser annealing operations, imaging operations, machine learning pattern recognition operations, junction resistance measurement operations, tunning calibration operations, generating tuning plans (e.g., frequency tuning plans) and other computer automated control and data processing operations as discussed herein for performing the exemplary methods shown or otherwise explained in conjunction with, e.g., FIGS. 1, 2A-2D, 3A-3G, 4, 5A-5F, 6A-6D, 7A, 7B, 8A, 8B, 9A-9C, 10, 11, 13, and 14. In addition to block 1526, computing environment 1500 includes, for example, computer 1501, wide area network (WAN) 1502, end user device (EUD) 1503, remote server 1504, public cloud 1505, and private cloud 1506. In this embodiment, computer 1501 includes processor set 1510 (including processing circuitry 1520 and cache 1521), communication fabric 1511, volatile memory 1512, persistent storage 1513 (including operating system 1522 and block 1526, as identified above), peripheral device set 1514 (including user interface (UI), device set 1523, storage 1524, and Internet of Things (IoT) sensor set 1525), and network module 1515. Remote server 1504 includes remote database 1530. Public cloud 1505 includes gateway 1540, cloud orchestration module 1541, host physical machine set 1542, virtual machine set 1543, and container set 1544.

Computer 1501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1530. As is well understood in the art of computer technology, and depending upon the technology, performance of a computer-implemented method may be distributed among multiple computers and/or between multiple locations. On the other hand, in this presentation of computing environment 1500, detailed discussion is focused on a single computer, specifically computer 1501, to keep the presentation as simple as possible. Computer 1501 may be located in a cloud, even though it is not shown in a cloud in FIG. 15. On the other hand, computer 1501 is not required to be in a cloud except to any extent as may be affirmatively indicated.

Processor set 1510 includes one, or more, computer processors of any type now known or to be developed in the future. Processing circuitry 1520 may be distributed over multiple packages, for example, multiple, coordinated integrated circuit chips. Processing circuitry 1520 may implement multiple processor threads and/or multiple processor cores. Cache 1521 is memory that is located in the processor chip package(s) and is typically used for data or code that should be available for rapid access by the threads or cores running on processor set 1510. Cache memories are typically organized into multiple levels depending upon relative proximity to the processing circuitry. Alternatively, some, or all, of the cache for the processor set may be located “off chip.” In some computing environments, processor set 1510 may be designed for working with qubits and performing quantum computing.

Computer readable program instructions are typically loaded onto computer 1501 to cause a series of operational steps to be performed by processor set 1510 of computer 1501 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1521 and the other storage media discussed below. The program instructions, and associated data, are accessed by processor set 1510 to control and direct performance of the inventive methods. In computing environment 1500, at least some of the instructions for performing the inventive methods may be stored in block 1526 in persistent storage 1513.

Communication fabric 1511 comprises the signal conduction paths that allow the various components of computer 1501 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1512 is any type of volatile memory now known or to be developed in the future. Examples include dynamic type random access memory (RAM) or static type RAM. Typically, the volatile memory is characterized by random access, but this is not required unless affirmatively indicated. In computer 1501, the volatile memory 1512 is located in a single package and is internal to computer 1501, but, alternatively or additionally, the volatile memory may be distributed over multiple packages and/or located externally with respect to computer 1501.

Persistent storage 1513 is any form of non-volatile storage for computers that is now known or to be developed in the future. The non-volatility of this storage means that the stored data is maintained regardless of whether power is being supplied to computer 1501 and/or directly to persistent storage 1513. Persistent storage 1513 may be a read only memory (ROM), but typically at least a portion of the persistent storage allows writing of data, deletion of data and re-writing of data. Some familiar forms of persistent storage include magnetic disks and solid-state storage devices. Operating system 1522 may take several forms, such as various known proprietary operating systems or open source Portable Operating System Interface type operating systems that employ a kernel. The code included in block 1526 typically includes at least some of the computer code involved in performing the inventive methods.

Peripheral device set 1514 includes the set of peripheral devices of computer 1501. Data communication connections between the peripheral devices and the other components of computer 1501 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1523 may include components such as a display screen, speaker, microphone, wearable devices (such as goggles and smart watches), keyboard, mouse, printer, touchpad, game controllers, and haptic devices. Storage 1524 is external storage, such as an external hard drive, or insertable storage, such as an SD card. Storage 1524 may be persistent and/or volatile. In some embodiments, storage 1524 may take the form of a quantum computing storage device for storing data in the form of qubits. In embodiments where computer 1501 is required to have a large amount of storage (for example, where computer 1501 locally stores and manages a large database) then this storage may be provided by peripheral storage devices designed for storing very large amounts of data, such as a storage area network (SAN) that is shared by multiple, geographically distributed computers. IoT sensor set 1525 is made up of sensors that can be used in Internet of Things applications. For example, one sensor may be a thermometer and another sensor may be a motion detector.

Network module 1515 is the collection of computer software, hardware, and firmware that allows computer 1501 to communicate with other computers through WAN 1502. Network module 1515 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1515 are performed on the same physical hardware device. In other embodiments (for example, embodiments that utilize software-defined networking (SDN)), the control functions and the forwarding functions of network module 1515 are performed on physically separate devices, such that the control functions manage several different network hardware devices. Computer readable program instructions for performing the exemplary inventive methods can typically be downloaded to computer 1501 from an external computer or external storage device through a network adapter card or network interface included in network module 1515.

WAN 1502 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1503 is any computer system that is used and controlled by an end user (for example, a customer of an enterprise that operates computer 1501), and may take any of the forms discussed above in connection with computer 1501. EUD 1503 typically receives helpful and useful data from the operations of computer 1501. For example, in a hypothetical case where computer 1501 is designed to provide a recommendation to an end user, this recommendation would typically be communicated from network module 1515 of computer 1501 through WAN 1502 to EUD 1503. In this way, EUD 1503 can display, or otherwise present, the recommendation to an end user. In some embodiments, EUD 1503 may be a client device, such as thin client, heavy client, mainframe computer, desktop computer and so on.

Remote server 1504 is any computer system that serves at least some data and/or functionality to computer 1501. Remote server 1504 may be controlled and used by the same entity that operates computer 1501. Remote server 1504 represents the machine(s) that collect and store helpful and useful data for use by other computers, such as computer 1501. For example, in a hypothetical case where computer 1501 is designed and programmed to provide a recommendation based on historical data, then this historical data may be provided to computer 1501 from remote database 1530 of remote server 1504.

Public cloud 1505 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 1505 is performed by the computer hardware and/or software of cloud orchestration module 1541. The computing resources provided by public cloud 1505 are typically implemented by virtual computing environments that run on various computers making up the computers of host physical machine set 1542, which is the universe of physical computers in and/or available to public cloud 1505. The virtual computing environments (VCEs) typically take the form of virtual machines from virtual machine set 1543 and/or containers from container set 1544. It is understood that these VCEs may be stored as images and may be transferred among and between the various physical machine hosts, either as images or after instantiation of the VCE. Cloud orchestration module 1541 manages the transfer and storage of images, deploys new instantiations of VCEs and manages active instantiations of VCE deployments. Gateway 1540 is the collection of computer software, hardware, and firmware that allows public cloud 1505 to communicate through WAN 1502.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1506 is similar to public cloud 1505, except that the computing resources are only available for use by a single enterprise. While private cloud 1506 is depicted as being in communication with WAN 1502, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1505 and private cloud 1506 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
performing laser annealing calibration operations on first Josephson junctions using different combinations of at least laser power settings and anneal times;
determining junction resistance shifts of the first Josephson junctions as a result of the laser annealing calibration operations; and
utilizing the determined junction resistance shifts of the first Josephson junctions to determine calibration data for configuring laser annealing operations for bidirectional laser tuning of second Josephson junctions corresponding to the first Josephson junctions.

2. The method of claim 1, wherein performing the laser annealing calibration operations on the first Josephson junctions using different combinations of at least laser power settings and anneal times comprises using different combinations of laser power settings, anneal times, and laser beam illumination patterns.

3. The method of claim 1, wherein the determined junction resistance shifts of the first Josephson junctions are utilized to determine calibration data which corresponds to a first tuning profile for configuring a laser annealing operation to decrease a resistance of at least one of the second Josephson junctions, and to determine calibration data which corresponds to a second tuning profile for configuring a laser annealing operation to increase a resistance of at least another of the second Josephson junctions.

4. The method of claim 3, wherein the determined junction resistance shifts of the first Josephson junctions are utilized to determine a negative tuning range for the first tuning profile, and to determine a positive tuning range for the second tuning profile.

5. The method of claim 3, wherein the determined junction resistance shifts of the first Josephson junctions are utilized to determine a negative tuning rate for the first tuning profile, and to determine a positive tuning rate for the second tuning profile.

6. The method of claim 3, wherein the determined junction resistance shifts of the first Josephson junctions are utilized to determine calibration data which corresponds to a third tuning profile for configuring a laser annealing operation to forward-shift a resistance of at least one of the second Josephson junctions following a decrease of the resistance of the at least one of the second Josephson junctions using the first tuning profile.

7. The method of claim 3, wherein the determined junction resistance shifts of the first Josephson junctions are utilized to determine calibration data which corresponds to a fourth tuning profile for configuring a laser annealing operation to reverse-shift a resistance of at least one of the second Josephson junctions following an increase of the resistance of the at least one of the second Josephson junctions using the second tuning profile.

8. The method of claim 1, wherein determining the junction resistance shifts of the first Josephson junctions as a result of the laser annealing calibration operations comprises:
for each of the first Josephson junctions, determining an initial junction resistance of the first Josephson junction, prior to laser annealing the first Josephson junction;
for each of the first Josephson junctions, determining a current junction resistance of the first Josephson junction, subsequent to laser annealing the first Josephson junction; and
for each of the first Josephson junctions, determining one of a positive junction resistance shift and a negative junction resistance shift, as a difference between of the current junction resistance and the initial junction resistance of the first Josephson junction.

9. The method of claim 1, wherein performing the laser annealing calibration operations on the first Josephson junctions using different combinations of at least laser power settings and anneal times, comprises:
partitioning the first Josephson junctions into multiple groups of first Josephson junctions; and
for each group of first Josephson junctions, performing laser annealing calibration operations on the Josephson junctions in the group using a respective different combination of at least a laser power setting and an anneal time.

10. The method of claim 1, wherein the first Josephson junctions and the second Josephson junctions are fabricated using at least a similar fabrication process and reside on one of the same quantum chip and different quantum chips.

11. A system, comprising:
a laser annealing apparatus; and
a control system operatively coupled to the laser annealing apparatus;
wherein the control system is configured to control the laser annealing apparatus to perform a calibration process, which comprises:
performing laser annealing calibration operations on first Josephson junctions using different combinations of at least laser power settings and anneal times;
determining junction resistance shifts of the first Josephson junctions as a result of the laser annealing calibration operations; and
utilizing the determined junction resistance shifts of the first Josephson junctions to determine calibration data for configuring laser annealing operations for bidirectional laser tuning of second Josephson junctions corresponding to the first Josephson junctions.

12. The system of claim 11, wherein the control system is configured to control the laser annealing apparatus to perform the laser annealing calibration operations on the first Josephson junctions using different combinations of laser power settings, anneal times, and laser beam illumination patterns.

13. The system of claim 11, wherein the control system is configured to utilize the determined junction resistance shifts of the first Josephson junctions to determine calibration data which corresponds to a first tuning profile for configuring a laser annealing operation to decrease a resistance of at least one of the second Josephson junctions, and to determine calibration data which corresponds to a second tuning profile for configuring a laser annealing operation to increase a resistance of at least another of the second Josephson junctions.

14. The system of claim 13, wherein the control system is configured to utilize the determined junction resistance shifts of the first Josephson junctions to determine a negative tuning rate and a negative tuning range for the first tuning profile, and to determine a positive tuning rate and a positive tuning range for the second tuning profile.

15. The system of claim 13, wherein the control system is configured to utilize the determined junction resistance shifts of the first Josephson junctions to determine calibration data which corresponds to a third tuning profile for configuring a laser annealing operation to forward-shift a resistance of at least one of the second Josephson junctions following a decrease of the resistance of the at least one of the second Josephson junctions using the first tuning profile.

16. The system of claim 13, wherein the control system is configured to utilize the determined junction resistance shifts of the first Josephson junctions to determine calibration data which corresponds to a fourth tuning profile for configuring a laser annealing operation to reverse-shift a resistance of at least one of the second Josephson junctions following an increase of the resistance of the at least one of the second Josephson junctions using the second tuning profile.

17. A system, comprising:
a laser annealing apparatus; and
a control system operatively coupled to the laser annealing apparatus;
wherein the control system is configured to control the laser annealing apparatus to perform a laser annealing process to tune Josephson junctions on a quantum chip, wherein in performing the laser annealing process, the control system is configured to:
calibrate the laser annealing apparatus to perform a first laser annealing process based on a first combination of at a laser power setting and an anneal time, to laser tune a first Josephson junction to decrease a resistance of the first Josephson junction below an initial resistance of the first Josephson junction; and
calibrate the laser annealing apparatus to perform a second laser annealing process based on a second combination of at least a laser power setting and an anneal time, to laser tune a second Josephson junction to increase a resistance of the second Josephson junction above an initial resistance of the second Josephson junction.

18. The system of claim 17, wherein in performing the laser annealing process, the control system is configured to calibrate the laser annealing apparatus to perform a third laser annealing process based on a third combination of at least a laser power setting and an anneal time, to laser tune the first Josephson junction to forward-shift a resistance of the first Josephson junction in a direction towards the initial resistance of the first Josephson junction.

19. The system of claim 17, wherein in performing the laser annealing process, the control system is configured to calibrate the laser annealing apparatus to perform a fourth laser annealing process based on a fourth combination of at least a laser power setting and an anneal time, to laser tune the second Josephson junction to reverse-shift a resistance of the second Josephson junction in a direction towards the initial resistance of the second Josephson junction.

20. The system of claim 17, wherein:
the first combination of at least a laser power setting and an anneal time comprises a first combination of a laser power setting, an anneal time, and a laser beam illumination pattern; and
the second combination of at least a laser power setting and an anneal time comprises second combination of a laser power setting, an anneal time, and a laser beam illumination pattern, which differs from the first combination.
